(19) United States
(12) Patent Application Publication
(10) Pub. No.: US 2025/0311629 A1
(43) Pub. Date: Oct. 2, 2025

(54) ORGANIC LIGHT EMITTING DEVICE

(71) Applicant: LG CHEM, LTD., Seoul (KR)

(72) Inventors: Jungha LEE, Daejeon (KR); Min Woo JUNG, Daejeon (KR); Miyeon HAN, Daejeon (KR); Joongsuk OH, Daejeon (KR); Hoon Jun KIM, Daejeon (KR); Hye Min CHO, Daejeon (KR); Hojung LEE, Daejeon (KR); Jeonghoe HEO, Daejeon (KR)

(21) Appl. No.: 18/864,403

(22) PCT Filed: Feb. 2, 2024
(86) PCT No.: PCT/KR2024/001592

§ 371 Date: Nov. 8, 2024

(30) Foreign Application Priority Data
Feb. 3, 2023 (KR) 10-2023-0015014

(51) Int. Cl. H10K 85/60; H10K 50/12; H10K 101/00

(52) U.S. Cl. CPC H10K 85/6576; H10K 85/654; H10K 85/6572; H10K 85/6574; H10K 50/121; H10K 2101/90

(57) ABSTRACT

An organic light-emitting device that includes an anode; a cathode opposite the anode; and a light emitting layer between the anode and the cathode, wherein the light emitting layer includes a first compound of Chemical Formula 1, and a second compound of Chemical Formula 2:

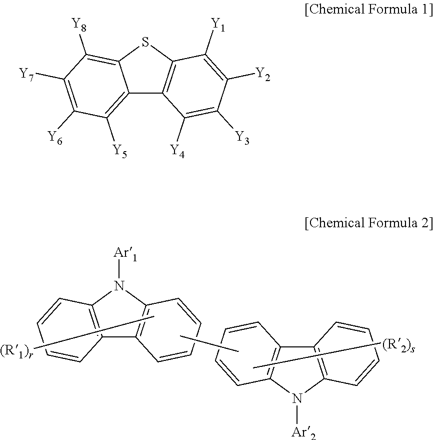

where one of Y₁, Y₃, Y₆ and Y₈ is -(L)ₙ-A, and the remaining are each independently hydrogen, deuterium, or a substituted or unsubstituted C₆₋₆₀ aryl, at least one of which is deuterium; A is at least one N-containing 6-membered heteroaryl which is substituted or unsubstituted, provided that A is not substituted with carbazolyl or indolocarbazolyl, and at least one of Y₂ and Y₇ is hydrogen, and the other substituents are as defined in the specification, provided that at least one of R′₁ and R′₂ is deuterium or at least one of Ar′₁ and Ar′₂ is substituted with deuterium.

### CROSS-REFERENCE TO RELATED APPLICATION(S)

This application is a National Stage Application of International Application No. PCT/KR2024/001592 filed on Feb. 2, 2024, which claims the benefit of and priority to Korean Patent Application No. 10-2023-0015014, filed on Feb. 3, 2023, the entire contents of which are incorporated herein by reference.

### TECHNICAL FIELD

The present disclosure relates to an organic light emitting device.

### BACKGROUND ART

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer may be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

There is a continuous need to develop a new material for the organic material used in the organic light emitting device as described above.

### PRIOR ART LITERATURE

### Patent Literature

(Patent Literature 0001) Korean Unexamined Patent Publication No. 10-2000-0051826

### DETAILED DESCRIPTION OF THE INVENTION

### Technical Problem

It is an object of the present disclosure to provide an organic light emitting device.

### Technical Solution

According to the present disclosure, there is provided the following organic light emitting device:

An organic light emitting device comprising:
an anode;
a cathode which is provided opposite to the anode; and
a light emitting layer which is interposed between the anode and the cathode, wherein the light emitting layer includes a first compound represented by the following Chemical Formula 1, and a second compound represented by the following Chemical Formula 2:

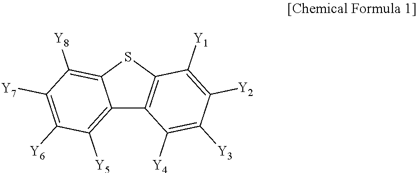

wherein, in Chemical Formula 1,
one of Y₁, Y₃, Y₆ and Y₈ is -(L)ₙ-A, wherein Y₁, Y₃, Y₆ and Y₈, which are not -(L)ₙ-A, are each independently hydrogen, deuterium, or a substituted or unsubstituted C₆₋₆₀ aryl, at least one of which is deuterium,
wherein L is a substituted or unsubstituted phenylene,
n is an integer from 0 to 3,
A is at least one N-containing 6-membered heteroaryl which is substituted or unsubstituted,
with the proviso that A is not substituted with carbazolyl or indolocarbazolyl, and
Y₂, Y₄, Y₅ and Y₇ are each independently hydrogen, deuterium, a substituted or unsubstituted C₆₋₆₀ aryl, wherein at least one of Y₂ and Y₇ is hydrogen,
with the proviso that when Y₁ is -(L)ₙ-A and Y₈ is phenyl substituted with deuterium, Y₂ is deuterium,

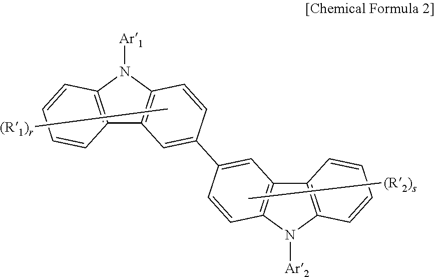

wherein, in Chemical Formula 2,
Ar′₁ and Ar′₂ are each independently a substituted or unsubstituted C₆₋₆₀ aryl; or a substituted or unsubstituted C₂₋₆₀ heteroaryl containing at least one heteroatom of N, O and S,

R′₁ and R′₂ are each independently deuterium; cyano; halogen; a substituted or unsubstituted C₁₋₆₀ alkyl; a substituted or unsubstituted C₆₋₆₀ aryl; or a substituted or unsubstituted C₂₋₆₀ heteroaryl containing at least one heteroatom of N, O and S, and
r and s are each independently an integer from 0 to 7,
with the proviso that at least one of R′₁ and R′₂ is deuterium; or at least one of Ar′₁ and Ar′₂ is substituted with deuterium.

### Advantageous Effects

The above-mentioned organic light emitting device includes two types of host compounds in the light emitting layer, and thus can improve efficiency, driving voltage and/or lifetime characteristics in the organic light emitting device.

### BRIEF DESCRIPTION OF THE DRAWINGS

FIG. 1 shows an example of an organic light emitting device comprising a substrate 1, an anode 2, a light emitting layer 3, and a cathode 4.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron transport layer 9, a hole injection layer 10, and a cathode 4.

### DETAILED DESCRIPTION OF THE EMBODIMENTS

Hereinafter, embodiments of the present disclosure will be described in more detail to help understanding of the invention.

In the present disclosure, the notation [symbol] or [symbol] means a bond linked to another substituent group, and “D” means deuterium.

In the present disclosure, the term “substituted or unsubstituted” means being unsubstituted or substituted with one or more substituents selected from the group consisting of deuterium; a halogen group; a cyano group; a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and a heterocyclic group containing at least one of N, O and S atoms, or being unsubstituted or substituted with a substituent group to which two or more substituent groups of the above-exemplified substituent groups are linked. For example, “a substituent in which two or more substituents are linked” may be a biphenylyl group. Namely, a biphenylyl group may be an aryl group, or it may be interpreted as a substituent formed by linking two phenyl groups. In one example, the term “substituted or unsubstituted” may be understood as meaning “being unsubstituted or substituted with one or more substituents selected from the group consisting of deuterium, halogen, cyano, a C₁₋₁₀ alkyl, a C₁₋₁₀ alkoxy and a C₆₋₂₀ aryl”, or “being unsubstituted or substituted with one or more substituents selected from the group consisting of deuterium, halogen, cyano, methyl, ethyl, phenyl and naphthyl”. Further, the term “substituted with one or more substituents” as used herein may be understood as meaning “being substituted with mono to the maximum number of substitutable hydrogens”. Alternatively, the term “substituted with one or more substituents” as used herein may be understood as meaning “being substituted with 1 to 5 substituents”, or “being substituted with one or two substituents”.

In the present disclosure, “linking two or more substituents of the above-exemplified substituents” refers to substituting hydrogen of any one substituent with another substituent.

In the present disclosure, “when a substituent is not indicated in the chemical formula or compound structure” may mean that hydrogen and deuterium mixedly exist in the chemical formula or compound structure unless deuterium is explicitly excluded, such as “the content of deuterium is 0%” or “the content of hydrogen is 100%,”.

In the present disclosure, the carbon number of a carbonyl group is not particularly limited, but is preferably 1 to 40. Specifically, the carbonyl group may be a substituent having the following structural formulas, but is not limited thereto.

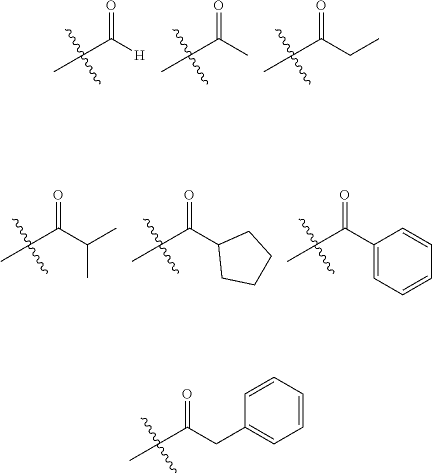

In the present disclosure, an ester group may have a structure in which oxygen of the ester group may be substituted by a straight-chain, branched-chain, or cyclic alkyl group having 1 to 25 carbon atoms, or an aryl group having 6 to 25 carbon atoms. Specifically, the ester group may be a substituent having the following structural formulas, but is not limited thereto.

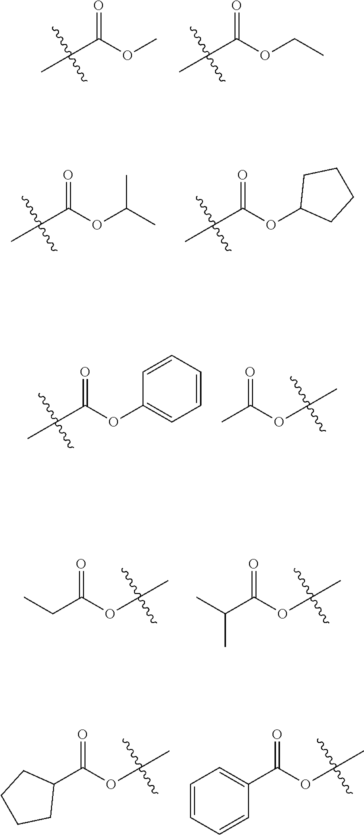

In the present disclosure, the carbon number of an imide group is not particularly limited, but is preferably 1 to 25. Specifically, the imide group may be a substituent group having the following structural formulas, but is not limited thereto.

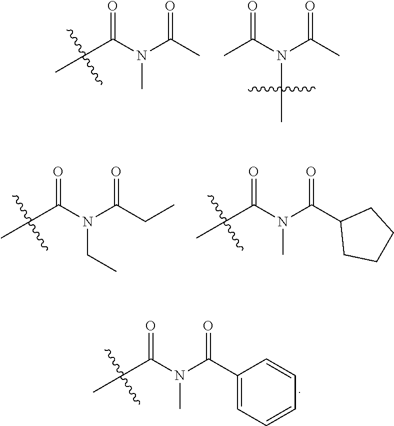

In the present disclosure, a substituted or unsubstituted silyl group means —Si(Z₁)(Z₂)(Z₃), wherein Z₁, Z₂ and Z₃ are each independently hydrogen, deuterium, a substituted or unsubstituted C₁₋₆₀ alkyl, a substituted or unsubstituted C₁₋₆₀ haloalkyl, a substituted or unsubstituted C₂₋₆₀ alkenyl, a substituted or unsubstituted C₂₋₆₀ haloalkenyl, or a substituted or unsubstituted C₆₋₆₀ aryl. According to one embodiment, Z₁, Z₂ and Z₃ may be each independently hydrogen, deuterium, a substituted or unsubstituted C₁₋₁₀ alkyl, a substituted or unsubstituted C₁₋₁₀ haloalkyl, a substituted or unsubstituted C₁₋₁₀ haloalkyl, or a substituted or unsubstituted C₆₋₂₀ aryl. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but are not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluoro, chloro, bromo, or iodo.

In the present disclosure, the alkyl group may be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, 1-ethyl-propyl, 1,1-dimethylpropyl, hexyl, n-hexyl, 1-methylpentyl, 2-methylpentyl, 4-methyl-2-pentyl, 3,3-dimethylbutyl, 2-ethylbutyl, heptyl, n-heptyl, isohexyl, 1-methylhexyl, 2-methylhexyl, 3-methylhexyl, 4-methylhexyl, 5-methylhexyl, cyclopentylmethyl, cyclohexylmethyl, octyl, n-octyl, tert-octyl, 1-methylheptyl, 2-ethylhexyl, 2,4,4-trimethyl-1-pentyl, 2,4,4-trimethyl-2-pentyl, 2-propylpentyl, n-nonyl, 2,2-dimethylheptyl, and the like, but are not limited thereto.

In the present disclosure, the alkenyl group may be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, the alicyclic group means a monovalent substituent derived from a saturated or unsaturated hydrocarbon ring compound that contains only carbon as a ring-forming atom, but does not have aromaticity, which is understood to encompass both monocyclic and fused polycyclic compounds. According to one embodiment, the carbon number of the alicyclic group is 3 to 60. According to another embodiment, the carbon number of the alicyclic group is 3 to 30. According to another embodiment, the carbon number of the alicyclic group is 3 to 20. Examples of the alicyclic group include a monocyclic group such as a cycloalkyl group, a bridged hydrocarbon group, a spiro hydrocarbon group, a substituent derived from hydrogenated derivatives of aromatic hydrocarbon compound.

Specifically, examples of the cycloalkyl group include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

Further, examples of the bridged hydrocarbon group include bicyclo[1.1.0]butyl, bicyclo[2.2.1]heptyl, bicyclo[4.2.0]octa-1,3,5-trienyl, adamantyl, decalinyl, and the like, but are not limited thereto.

Further, examples of the spiro hydrocarbon group include spiro[3.4]octyl, spiro[5.5]undecanyl, and the like, but are not limited thereto.

Further, a substituent derived from a hydrogenated derivative of the aromatic hydrocarbon compound means a substituent derived from a monocyclic or polycyclic aromatic hydrocarbon compound in which a part of the compound is hydrogenated. Examples of such a substituent include 1H-indenyl, 2H-indenyl, 4H-indenyl, 2,3-dihydro-1H-indenyl, 1,4-dihydronaphthalenyl, 1,2,3,4-tetrahydronaphthalenyl, 6,7,8,9-tetrahydro-5H-benzo[7]annulenyl, 6,7-dihydro-5H-benzocycloheptenyl, and the like, but are not limited thereto.

In the present disclosure, an aryl group is understood to mean a substituent derived from a monocyclic or fused polycyclic compound containing only carbon as a ring-forming atom and also having aromaticity, and the carbon number thereof is not particularly limited, but is preferably 6 to 60. According to one embodiment, the carbon number of the aryl group is 6 to 30. According to one embodiment, the carbon number of the aryl group is 6 to 20. The aryl group may be a phenyl group, a biphenylyl group, a terphenylyl group or the like as the monocyclic aryl group, but is not limited thereto. The polycyclic aryl group includes a naphthyl group, an anthracenyl group, a phenanthryl group, a pyrenyl group, a perylenyl group, a chrysenyl group, or the like, but is not limited thereto.

In the present disclosure, the fluorenyl group may be substituted, and two substituent groups may be linked with each other to form a spiro structure. In the case where the fluorenyl group is substituted,

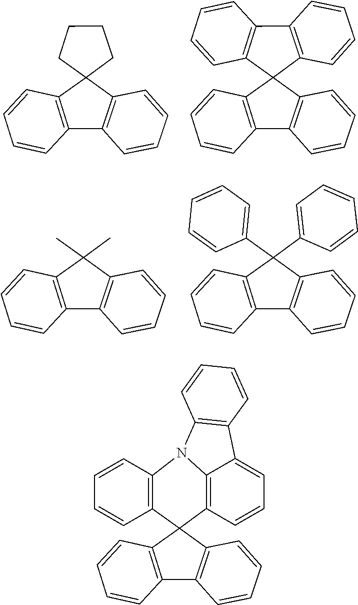

and the like can be formed. However, the structure is not limited thereto.

In the present disclosure, a heterocyclic group means a monovalent substituent derived from a monocyclic or fused polycyclic compound that further contains at least one heteroatom selected from O, N, Si, and S in addition to carbon as a ring-forming atom, and is understood to encompass both substituents with aromaticity and substituents without aromaticity. According to one embodiment, the carbon number of the heterocyclic group is 2 to 60 carbon atoms. According to another embodiment, the carbon number of the heterocyclic group is 2 to 30. According to another embodiment, the carbon number of the heterocyclic group is 2 to 20. Examples of such a heterocyclic group include a heteroaryl group, a substituent derived from a hydrogenated derivative of the heteroaromatic compound, and the like.

Specifically, the heteroaryl group means a substituent derived from a monocyclic or fused polycyclic compound which further contains at least one heteroatom selected from N, O and S in addition to carbon as a ring forming atom, and refers to a substituent having aromaticity. According to one embodiment, the carbon number of the heteroaryl group is 2 to 60. According to another embodiment, the carbon number of the heteroaryl group is 2 to 30. According to another embodiment, the carbon number of the heteroaryl group is 2 to 20. Examples of the heteroaryl group include a thiophenyl group, a furanyl group, a pyrrole group, an imidazolyl group, a thiazolyl group, an oxazolyl group, an oxadiazolyl group, a triazolyl group, a pyridinyl group, a bipyridinyl group, a pyrimidinyl group, a triazinyl group, an acridinyl group, a pyridazinyl group, a pyrazinyl group, a quinolinyl group, a quinazolinyl group, a quinoxalinyl group, a phthalazinyl group, a pyridopyrimidinyl group, a pyridopyrazinyl group, an isoquinolinyl group, an indolyl group, a carbazolyl group, a benzoxazolyl group, a benzoimidazolyl group, a benzothiazolyl group, a benzocarbazolyl group, a benzothiophenyl group, a dibenzothiophenyl group, a benzofuranyl group, a dibenzofuranyl group, a phenanthrolinyl group, an isoxazolyl group, a thiadiazolyl group, a phenothiazinyl group, and the like, but are not limited thereto.

Further, a substituent derived from a hydrogenated derivative of a heteroaromatic compound means a substituent derived from a monocyclic or polycyclic heteroaromatic compound in which a part of the unsaturated bond of the compound is hydrogenated. Examples of such substituents include 1,3-dihydroisobenzofuranyl, 2,3-dihydrobenzofuranyl, 1,3-dihydrobenzo[c]thiophenyl, 2,3-dihydro[b]thiophenyl, and the like, but are not limited thereto.

In the present disclosure, the aryl group in the aralkyl group, the aralkenyl group, the alkylaryl group, the arylamine group and the arylsilyl group is the same as the examples of the aryl group as defined above. In the present disclosure, the alkyl group in the aralkyl group, the alkylaryl group and the alkylamine group is the same as the examples of the alkyl group as defined above. In the present disclosure, the heteroaryl in the heteroarylamine can be applied to the description of the heteroaryl as defined above. In the present disclosure, the alkenyl group in the aralkenyl group is the same as the examples of the alkenyl group as defined above. In the present disclosure, the description of the aryl group as defined above may be applied except that the arylene is a divalent group. In the present disclosure, the description of the heteroaryl as defined above can be applied except that the heteroarylene is a divalent group. In the present disclosure, the description of the aryl group or cycloalkyl group as defined above can be applied except that the hydrocarbon ring is not a monovalent group but formed by combining two substituent groups. In the present disclosure, the description of the heteroaryl as defined above can be applied, except that the heterocycle is not a monovalent group but formed by combining two substituent groups.

In the present disclosure, the term “deuterated or substituted with deuterium” means that at least one of the substitutable hydrogens in a compound, a divalent linking group, or a monovalent substituent has been substituted with deuterium.

Further, the term “unsubstituted or substituted with deuterium” or “substituted or unsubstituted with deuterium” means that “mono to the maximum number of unsubstituted or substitutable hydrogens have been substituted with deuterium.” In one example, the term “phenanthryl unsubstituted or substituted with deuterium” may be understood as meaning “phenanthryl unsubstituted or substituted with 1 to 9 deuterium atoms”, considering that the maximum number of hydrogen that can be substituted with deuterium in the phenanthryl structure is 9.

Further, “deuterated structure” means to include compounds, divalent linking groups, or monovalent substituents of all structures in which at least one hydrogen is substituted with deuterium. As an example, the deuterated structure of phenyl can be understood to refer to monovalent substituents of all structures in which at least one substitutable hydrogen in the phenyl group is substituted with deuterium, as follows.

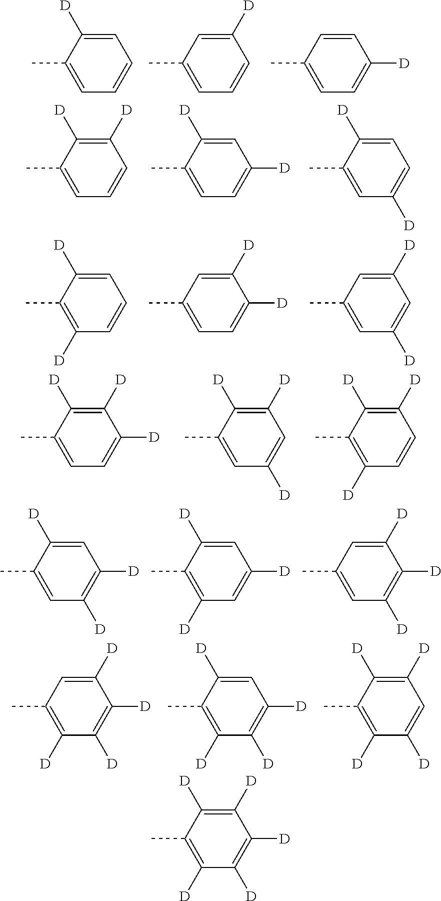

In addition, the “deuterium substitution rate” or “degree of deuteration” of a compound means that the ratio of the number of substituted deuterium atoms to the total number of hydrogen atoms (the sum of the number of hydrogen atoms substitutable with deuterium and the number of substituted deuterium atoms in a compound) that can exist in the compound is calculated as a percentage. Therefore, when the “deuterium substitution rate” or “degree of deuteration” of a compound is “K %”, it means that K % of the hydrogen atoms substitutable with deuterium in the compound are substituted with deuterium.

At this time, the “deuterium substitution rate” or “degree of deuteration” can be determined according to a commonly known method using MALDI-TOF MS (Matrix-Assisted Laser Desorption/Ionization Time-of-Flight Mass Spectrometer), a nuclear magnetic resonance spectroscopy (¹H NMR), TLC/MS (Thin-Layer Chromatography/Mass Spectrometry), GC/MS (Gas Chromatography/Mass Spectrometry), or the like.

More specifically, when using MALDI-TOF MS, the “deuterium substitution rate” or “degree of deuteration” may be obtained by determining the number of substituted deuterium in the compound through MALDI-TOF MS analysis, and then calculating the ratio of the number of substituted deuterium to the total number of hydrogen atoms that can exist in the compound as a percentage.

In addition, when analyzing the “deuterium substitution rate” or “degree of deuteration” through TLC/MS (thin-layer chromatography/mass spectrometry), the substitution rate can be calculated based on the maximum value (max. value) of distribution that molecular weights form at the end of the reaction.

Further, when analyzing the “deuterium substitution rate” or “degree of deuteration” using nuclear magnetic resonance (¹H NMR), the deuterium substitution rate or degree of deuteration can be calculated from the integration quantity of total peaks through the integration ratio in ¹H NMR.

Meanwhile, in the present disclosure, “deuterium does not exist at a specific position” means that the deuterium substitution rate at that position is 10% or less, and does not mean that the deuterium substitution rate is 0%. In addition, in the present disclosure, “deuterium exists at a specific position” means that the deuterium substitution rate at that position is more than 10%, and does not mean that the deuterium substitution rate at that position is 100%. In this way, the “deuterium substitution rate at a specific position” may be calculated by comparing the ¹H NMR spectrum of a compound not substituted with deuterium with the ¹H NMR spectrum of a compound substituted with deuterium, and confirming the rate at which the integration quantity of the peak for each hydrogen (proton) position decreases.

The organic light emitting device according to the present disclosure simultaneously contains two types of compounds having a specific structure as host materials in the light emitting layer, and thus can improve efficiency, driving voltage, and/or lifetime characteristics in the organic light emitting device.

Hereinafter, the present disclosure will be described in detail for each configuration.

### Anode and Cathode

As the anode material, generally, a material having a large work function is preferably used so that holes can be smoothly injected into the organic material layer. Specific examples of the anode material include metals such as vanadium, chrome, copper, zinc, and gold, or an alloy thereof; metal oxides such as zinc oxides, indium oxides, indium tin oxides (ITO), and indium zinc oxides (IZO); a combination of metals and oxides, such as ZnO:Al or SnO₂:Sb; conductive polymers such as poly(3-methylthiophene), poly[3,4-(ethylene-1,2-dioxy)thiophene](PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof; a multilayered structure material such as LiF/Al or LiO₂/Al, and the like, but are not limited thereto.

### Hole Injection Layer

The organic light emitting device according to the present disclosure may include a hole injection layer between an anode and a hole transport layer described hereinafter, if necessary.

The hole injection layer is a layer that is located on the anode and injects holes from the anode, which includes a hole injection material. The hole injection material is preferably a compound which has a capability of transporting the holes, a hole injection effect in the anode and an excellent hole injection effect to the light emitting layer or the light emitting material, prevents movement of an exciton generated in the light emitting layer to the electron injection layer or the electron injection material, and has an excellent thin film forming ability. In particular, it is suitable that a HOMO (highest occupied molecular orbital) of the hole injection material is between the work function of the anode material and a HOMO of a peripheral organic material layer.

Specific examples of the hole injection material include metal porphyrin, oligothiophene, an arylamine-based organic material, a hexanitrilehexaazatriphenylene-based organic material, a quinacridone-based organic material, a perylene-based organic material, anthraquinone, polyaniline and polythiophene-based conductive polymer, and the like, but are not limited thereto.

### Hole Transport Layer

The organic light emitting device according to the present disclosure may include a hole transport layer between the anode and the light emitting layer. The hole transport layer is a layer that receives holes from an anode or a hole injection layer formed on the anode and transports the holes to the light emitting layer, which includes a hole transport material. The hole transport material is suitably a material having large mobility to the holes, which may receive holes from the anode or the hole injection layer and transfer the holes to the light emitting layer. Specific examples thereof may include an arylamine-based organic material, a conductive polymer, a block copolymer in which a conjugate portion and a non-conjugate portion are present together, and the like, but are not limited thereto.

### Electron Blocking Layer

The organic light emitting device according to the present disclosure may include an electron blocking layer between the hole transport layer and the light emitting layer, if necessary. The electron blocking layer refers to a layer which is formed on the hole transport layer, preferably provided in contact with the light emitting layer, and serves to adjust the hole mobility, prevent excessive movement of electrons, and increase the probability of hole-electron coupling, thereby improving the efficiency of the organic light emitting device. The electron blocking layer includes an electron blocking material, and examples of such an electron blocking material may include an arylamine-based organic material or the like, but is not limited thereto.

### Light Emitting Layer

The organic light emitting device according to the present disclosure may include a light emitting layer between an anode and a cathode, and the light emitting layer includes the first compound and the second compound as the host material. Specifically, the first compound can function as an N-type host material in which an electron transport capability is superior to a hole transport capability, and the second compound can function as a P-type host material in which a hole transport capability is superior to an electron transport capability, and thus can properly maintain the ratio of holes to electrons in the light emitting layer. Accordingly, excitons emit light evenly throughout the light emitting layer, so that the light emitting efficiency and lifetime characteristics of the organic light emitting device can be improved at the same time.

Hereinafter, the first compound and the second compound will be sequentially described.

### (First Compound)

The first compound is represented by the Chemical Formula 1.

Specifically, the first compound has the characteristics that one of Y₁, Y₃, Y₆ and Y₈ of dibenzothiophene is at least one N-containing 6-membered heteroaryl group, the other is deuterium, and at least one of Y₂ and Y₇ is hydrogen. Such compounds can improve the lifetime characteristics of the organic light emitting device compared to a compound where Y₁, Y₃, Y₆ and Y₈ are all hydrogen, or Y₁ to Yr are all deuterium.

Here, “at least one of Y₂ and Y₇ is hydrogen” means “deuterium does not exist in at least one of the Y₂ and Y₇ positions.” More specifically, the first compound means that the deuterium substitution rate at the Y₂ position is 10% or less, or the deuterium substitution rate at the Y₂ position is 10% or less. The deuterium substitution rate at the Y₂ and Y₇ positions can be determined by comparing the ¹H NMR spectrum of the compound not substituted with deuterium with the ¹H NMR spectrum of the compound substituted with deuterium, as described above.

Generally, the deuterium substitution rate in a compound can be controlled by adjusting the equivalent weight of the reagent for deuteration, the equivalent weight of a catalyst, the reaction temperature and time, and the like.

Specifically, deuterium has a higher mass value than hydrogen, and thus has a low potential energy level and a low zero point energy. As heavier atoms have smaller vibration modes, they have lower vibrational energy levels than hydrogen. Therefore, when hydrogen atoms existing in a compound are substituted with deuterium, the intermolecular van der Waals force decreases, and proton efficiency decrease due to intermolecular collision by vibration can be prevented.

Further, since deuterium lowers the zero point energy with carbon, the bond energy of the C-D bond becomes higher than that of the C—H bond. Therefore, the first compound has a stronger binding energy within the molecule compared to a compound not substituted with deuterium, thereby increasing the material stability.

Further, the first compound has a structure in which deuterium is selectively located only at specific positions, and such a compound has better stability in terms of stereochemistry than a compound in which Y₁, Y₃, Y₆, and Y₈ are all hydrogen, or Y₁ to Y₈ are all deuterium, and thus can efficiently transfer electrons to the dopant material, thereby increasing the recombination probability of electron-hole in the light emitting layer.

In Chemical Formula 1,
Y₁ is -(L)ₙ-A, Y₃, Y₆ and Y₈ are each independently hydrogen, deuterium, or a substituted or unsubstituted C₆₋₆₀ aryl, at least one of which may be deuterium; or
Y₃ is -(L)ₙ-A, Y₁, Y₆ and Y₈ are each independently hydrogen, deuterium, or a substituted or unsubstituted C₆₋₆₀ aryl, at least one of which may be deuterium.
Further, one of Y₁, Y₃, Y₆ and Y₈ is -(L)ₙ-A, wherein Y₁, Y₃, Y₆ and Y₈, which are not -(L)ₙ-A, are each independently hydrogen, or deuterium, at least two of which may be deuterium, or
one of Y₁, Y₃, Y₆ and Y₈ is -(L)ₙ-A, another is a substituted or unsubstituted C₆₋₂₀ aryl, the other one is deuterium, and the remainder may be hydrogen or deuterium.

More specifically,
Y₁ is -(L)ₙ-A, one of Y₃, Y₆ and Y₈ is deuterium, and the remainder are all hydrogen; or
Y₁ is -(L)ₙ-A, one of Y₃, Y₆ and Y₈ is deuterium, the other one is a substituted or unsubstituted C₆₋₆₀ aryl, and the remainder is hydrogen; or
Y₁ is -(L)ₙ-A, two of Y₃, Y₆ and Y₈ are deuterium, and the remainder is hydrogen; or
Y₁ is -(L)ₙ-A, two of Y₃, Y₆ and Y₈ are deuterium, and the remainder is a substituted or unsubstituted C₆₋₆₀ aryl; or
Y₁ is -(L)ₙ-A, and all of Y₃, Y₆ and Y₈ are deuterium; or
Y₃ is -(L)ₙ-A, one of Y₁, Y₆ and Y₈ is deuterium, and the remainder are all hydrogen; or
Y₃ is -(L)ₙ-A, one of Y₁, Y₆ and Y₈ is deuterium, the other one is a substituted or unsubstituted C₆₋₆₀ aryl, and the remainder is hydrogen; or
Y₃ is -(L)ₙ-A, two of Y₁, Y₆ and Y₈ are deuterium, and the remainder is hydrogen; or
Y₃ is -(L)ₙ-A, two of Y₁, Y₆ and Y₈ are deuterium, and the remainder is a substituted or unsubstituted C₆₋₆₀ aryl; or

Y₃ is -(L)ₙ-A, and all of Y₁, Y₆ and Y₈ may be deuterium.

In addition, Y₁, Y₃, Y₆ and Y₈, which are not -(L)ₙ-A, may be each independently hydrogen, or a substituted or unsubstituted C₆₋₂₀ aryl.

More specifically, Y₁, Y₃, Y₆ and Y₈, which are not -(L)ₙ-A, may be each independently hydrogen, phenyl, biphenylyl, phenanthryl, or triphenylenyl,
wherein the phenyl, biphenylyl, phenanthryl and triphenylenyl may be unsubstituted or substituted with at least one deuterium.

Further, L may be phenylene which is unsubstituted or substituted with 1 to 4 deuteriums.

Further, n means the number of L, and when it is 2 or more, two or more L may be the same or different. In one example, n is 0, 1, 2, or 3.

More specifically, n may be 0, 1, or 2.

Further, A is at least one N-containing 6-membered heteroaryl which is substituted or unsubstituted. Here, “at least one N-containing 6-membered heteroaryl” means a monovalent substituent of a 6-membered monocyclic ring containing at least one heteroatom N as a ring-forming atom, the remainder of which being made up of carbon. More specifically, the N-containing 6-membered heteroaryl may include 1 to 3 nitrogen atoms and 3 to 5 carbon atoms as ring forming atoms. Thereby, A may be a substituted or unsubstituted 1˜3 N-containing 6-membered heteroaryl.

In one embodiment, A is a substituted or unsubstituted 1˜3 N-containing 6-membered heteroaryl, wherein the A may be unsubstituted or substituted with one or more substituents selected from the group consisting of deuterium; halogen; cyano; a substituted or unsubstituted C₁₋₁₀ alkyl; a substituted or unsubstituted C₆₋₂₀ aryl; a substituted or unsubstituted C₂₋₂₀ heteroaryl containing O or S; or a substituted or unsubstituted C₂₋₂₀ heteroaryl containing at least one N and at least one O or S.

More specifically, the A may be unsubstituted or substituted with one or more substituents selected from the group consisting of deuterium; halogen; cyano; a C₁₋₁₀ alkyl unsubstituted or substituted with deuterium; a C₆₋₂₀ aryl unsubstituted or substituted with deuterium; a C₂₋₂₀ heteroaryl containing O or S, which is unsubstituted or substituted with deuterium; or a C₂₋₂₀ heteroaryl containing at least one N and at least one O or S, which is unsubstituted or substituted with deuterium.

For example, A may be any one of substituents represented by the following Chemical Formulas 2a to 2j:

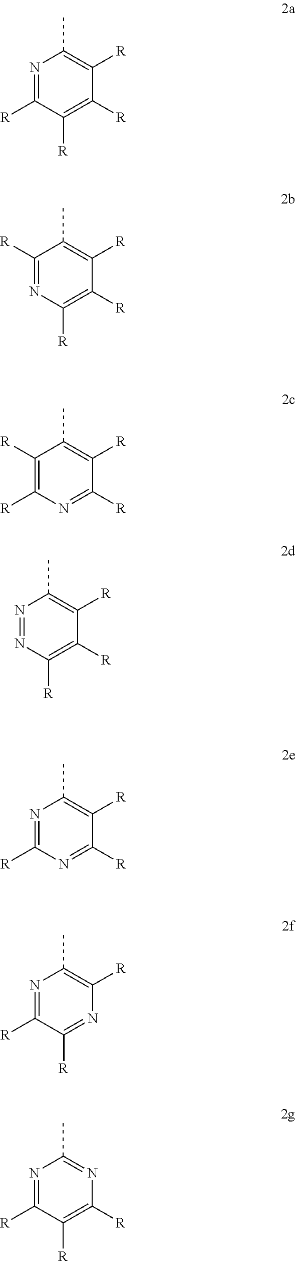

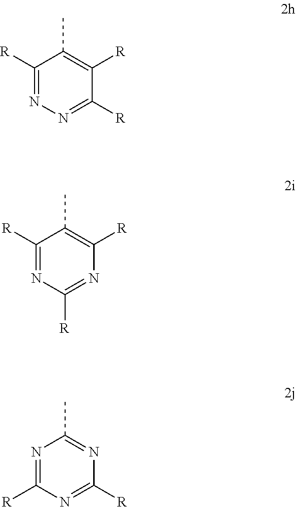

wherein, in Chemical Formulas 2a to 2j,
each R is independently hydrogen, deuterium, a substituted or unsubstituted C₆₋₂₀ aryl, or a substituted or unsubstituted C₂₋₂₀ heteroaryl containing O or S.

In one embodiment, R may be each independently hydrogen; deuterium; a C₆₋₂₀ aryl which is unsubstituted or substituted with one or more substituents selected from the group consisting of deuterium, a C₁₋₁₀ alkyl, and a C₆₋₁₂ aryl; or a C₂₋₂₀ heteroaryl containing O or S, which is unsubstituted or substituted with one or more substituents selected from the group consisting of deuterium, a C₁₋₁₀ alkyl and a C₆₋₁₂ aryl.

In another embodiment,
in each of Chemical Formula 2a to 2i,
R is all hydrogen; or
at least one of R is deuterium, and the remainder is hydrogen or deuterium; or
one or two of R are each independently a C₆₋₂₀ aryl which is unsubstituted or substituted with one or more substituents selected from the group consisting of deuterium, a C₁₋₁₀ alkyl, and a C₆₋₁₂ aryl; or a C₂₋₂₀ heteroaryl containing O or S, which is unsubstituted or substituted with one or more substituents selected from the group consisting of deuterium, a C₁₋₁₀ alkyl and a C₆₋₁₂ aryl, and the remainder are each independently hydrogen or deuterium,
in Chemical Formula 2j,
each R is independently a C₆₋₂₀ aryl which is unsubstituted or substituted with one or more substituents selected from the group consisting of deuterium, a C₁₋₁₀ alkyl, and a C₆₋₁₂ aryl; or a C₂₋₂₀ heteroaryl containing O or S, which is unsubstituted or substituted with one or more substituents selected from the group consisting of deuterium, a C₁₋₁₀ alkyl and a C₆₋₁₂ aryl.

In yet another embodiment, each R is independently hydrogen, deuterium, phenyl, biphenylyl, terphenylyl, phenanthryl, triphenylenyl, dibenzofuranyl, or dibenzothiophenyl,
wherein when R is phenyl, biphenylyl, terphenylyl, phenanthryl, triphenylenyl, dibenzofuranyl and dibenzothiophenyl, they may be unsubstituted or substituted with at least one deuterium.

In another embodiment, two or more R in each Chemical Formula may be the same as each other.

In another embodiment, two or more R in each Chemical Formula can be different.

In another embodiment, A is represented by the Chemical Formula 2j,
wherein R is each independently phenyl, biphenylyl, terphenylyl, phenanthryl, triphenylenyl, dibenzofuranyl, or dibenzothiophenyl,
the R may be unsubstituted or substituted with at least one deuterium.

Further, Y₂ is hydrogen, and Y₇ is deuterium;
Y₂ is deuterium, and Y₇ is hydrogen; or
both Y₂ and Y₇ may be hydrogen.

Further, Y₄ and Y₅ may each independently be hydrogen, deuterium, or a substituted or unsubstituted C₆₋₂₀ aryl.

More specifically, Y₄ and Y₅ are each independently hydrogen, deuterium, phenyl, biphenylyl, phenanthryl, or triphenylenyl,
wherein the phenyl, biphenylyl, phenanthryl and triphenylenyl may be unsubstituted or substituted with at least one deuterium.

For example, one of Y₄ and Y₅ is hydrogen or deuterium, and the other one is hydrogen, deuterium, phenyl, biphenylyl, phenanthryl, or triphenylenyl;
wherein the phenyl, biphenylyl, phenanthryl and triphenylenyl may be unsubstituted or substituted with at least one deuterium.

In one embodiment, Y₂ and Y₈ may be deuterium, and Y₇ may be hydrogen.

In other embodiments, Y₄ and Y₆ may be deuterium, and Y₇ may be hydrogen.

In yet another embodiment, one, two, or three of Y₂, Y₄, Y₅, and Y₇ may be deuterium.

Further, one, two, three, four, five, or six of Y₁ to Y₈ may be deuterium.

For example, three, four, or five of Y₁ to Y₈ may be deuterium.

Further, Y₁, Y₃, Y₆ and Y₈, which are not -(L)ₙ-A; and Y₂, Y₄, Y₅ and Y₇ are each independently hydrogen or deuterium; or
one of Y₁ to Y₈ may be a substituted or unsubstituted C₆₋₆₀ aryl.

Further, when Y₁ is -(L)ₙ-A, Y₈ may be hydrogen, deuterium, or an unsubstituted C₆₋₂₀ aryl.

More specifically, when Y₁ is -(L)ₙ-A, Y₈ may be hydrogen, deuterium, an unsubstituted phenyl, an unsubstituted biphenylyl, or an unsubstituted naphthyl.

Further, the first compound may be represented by the following Chemical Formula 1-1 or 1-2.

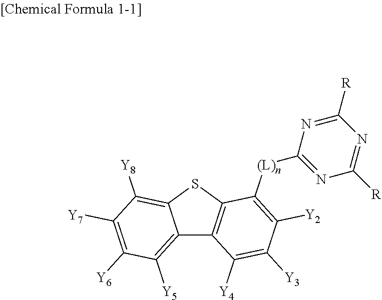

wherein, in Chemical Formula 1-1,
one, two or three of Y₃, Y₆ and Y₈ are deuterium, and the remainder, which is not deuterium, are each independently hydrogen or a substituted or unsubstituted C₆₋₆₀ aryl,
each R is independently hydrogen, deuterium, a substituted or unsubstituted C₆₋₂₀ aryl, or a substituted or unsubstituted C₂₋₂₀ heteroaryl containing O or S, and
Y₂, Y₄, Y₅ and Y₇, L and n are as defined in Chemical Formula 1,

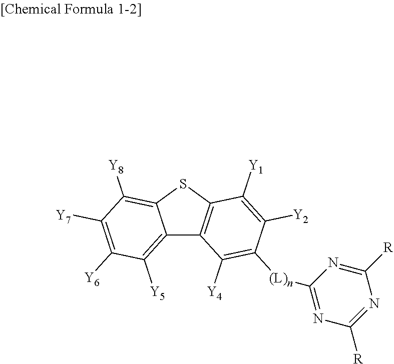

wherein, in Chemical Formula 1-2,
one, two or three of Y₁, Y₆ and Y₈ are deuterium, and the remainder, which is not deuterium, are each independently hydrogen or a substituted or unsubstituted C₆₋₆₀ aryl,
each R is independently hydrogen, deuterium, a substituted or unsubstituted C₆₋₂₀ aryl, or a substituted or unsubstituted C₂₋₂₀ heteroaryl containing O or S, and
Y₂, Y₄, Y₅ and Y₇, L and n are as defined in Chemical Formula 1.

Further, the first compound may contain 1 to 20 deuteriums. More specifically, the first compound may include 1 or more, 2 or more, 3 or more, or 4 or more, and 20 or less, 18 or less, 16 or less, 14 or less, 13 or less, 12 or less, 11 or less, 10 or less, 9 or less, 8 or less, 7 or less, 6 or less, or 5 or less deuteriums.

In one example, when the first compound contains deuterium, the deuterium substitution rate of the compound may be 1% to 40%. Specifically, the deuterium substitution rate of the compound may be 1% or more, 3% or more, 5% or more, 7% or more, 9% or more, 10% or more, 11% or more, 12% or more, or 13% or more, and 40% or less, 35% or less, 40% or less, 35% or less, 30% or less, 25 or less, or 22% or less.

Representative examples of the first compound are as follows:

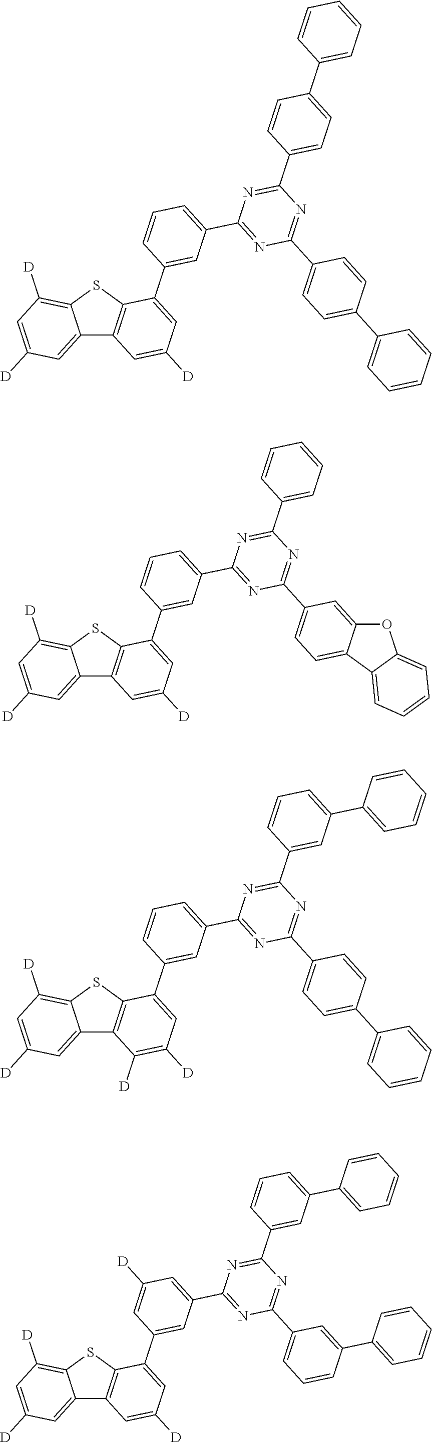 [SMILES: [2H]c1cc([2H])c2sc3c(-c4cccc(-c5nc(-c6ccc(-c7ccccc7)cc6)nc(-c6ccc(-c7ccccc7)cc6)n5)c4)cc([2H])cc3c2c1 ; [2H]c1cc([2H])c2sc3c(-c4cccc(-c5nc(-c6ccccc6)nc(-c6ccc7c(c6)oc6ccccc67)n5)c4)cc([2H])cc3c2c1 ; [2H]c1cc([2H])c2sc3c(-c4cccc(-c5nc(-c6ccc(-c7ccccc7)cc6)nc(-c6cccc(-c7ccccc7)c6)n5)c4)cc([2H])c([2H])c3c2c1 ; [2H]c1cc(-c2nc(-c3cccc(-c4ccccc4)c3)nc(-c3cccc(-c4ccccc4)c3)n2)cc(-c2cc([2H])cc3c2sc2c([2H])cc([2H])cc23)c1]

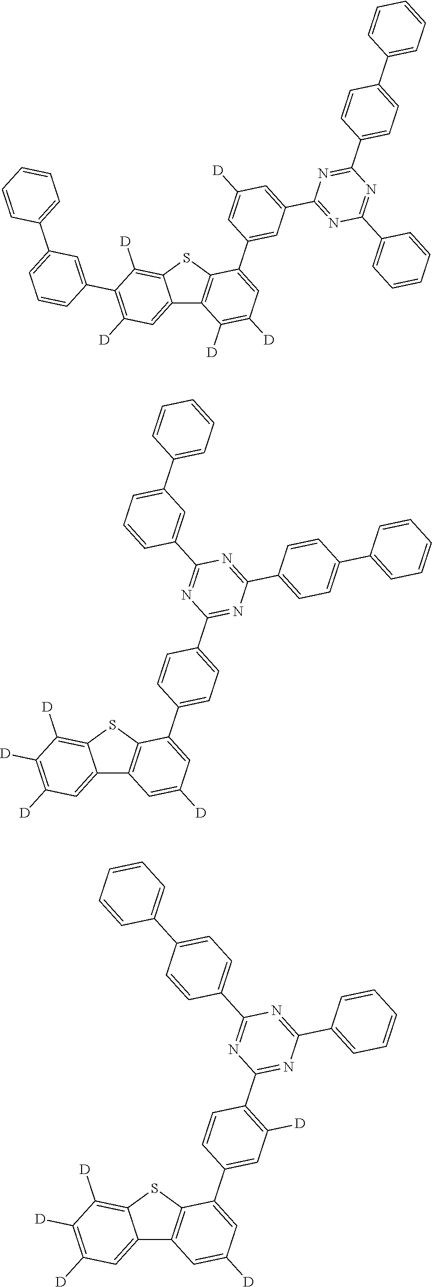 [SMILES: [2H]c1cc(-c2nc(-c3ccccc3)nc(-c3ccc(-c4ccccc4)cc3)n2)cc(-c2cc([2H])c([2H])c3c2sc2c([2H])c(-c4cccc(-c5ccccc5)c4)c([2H])cc23)c1 ; [2H]c1cc(-c2ccc(-c3nc(-c4ccc(-c5ccccc5)cc4)nc(-c4cccc(-c5ccccc5)c4)n3)cc2)c2sc3c([2H])c([2H])c([2H])cc3c2c1 ; [2H]c1cc(-c2ccc(-c3nc(-c4ccccc4)nc(-c4ccc(-c5ccccc5)cc4)n3)c([2H])c2)c2sc3c([2H])c([2H])c([2H])cc3c2c1]

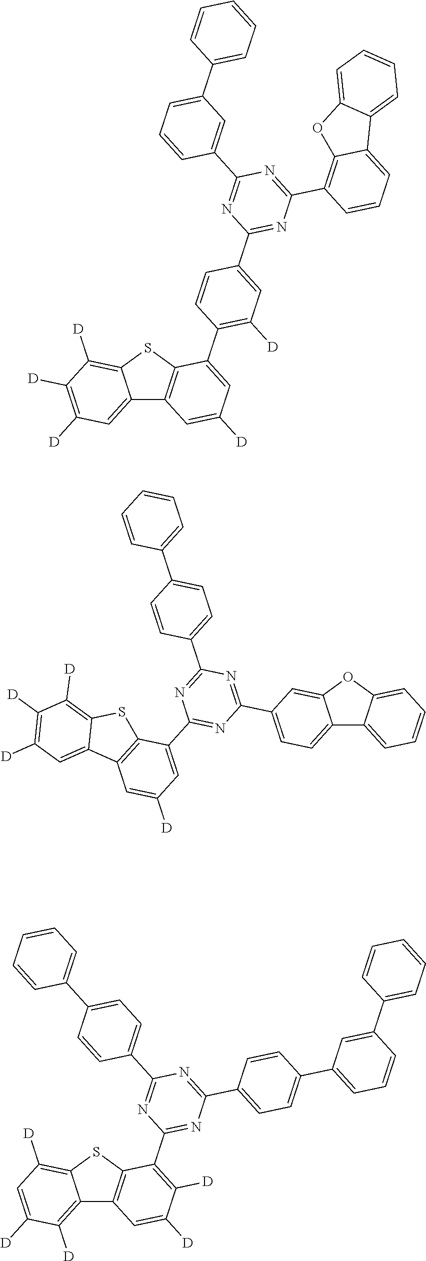 [SMILES: [2H]c1cc(-c2ccc(-c3nc(-c4cccc(-c5ccccc5)c4)nc(-c4cccc5c4oc4ccccc45)n3)cc2[2H])c2sc3c([2H])c([2H])c([2H])cc3c2c1 ; [2H]c1cc(-c2nc(-c3ccc(-c4ccccc4)cc3)nc(-c3ccc4c(c3)oc3ccccc34)n2)c2sc3c([2H])c([2H])c([2H])cc3c2c1 ; [2H]c1cc2c(sc3c([2H])cc([2H])c([2H])c32)c(-c2nc(-c3ccc(-c4ccccc4)cc3)nc(-c3ccc(-c4cccc(-c5ccccc5)c4)cc3)n2)c1[2H]]

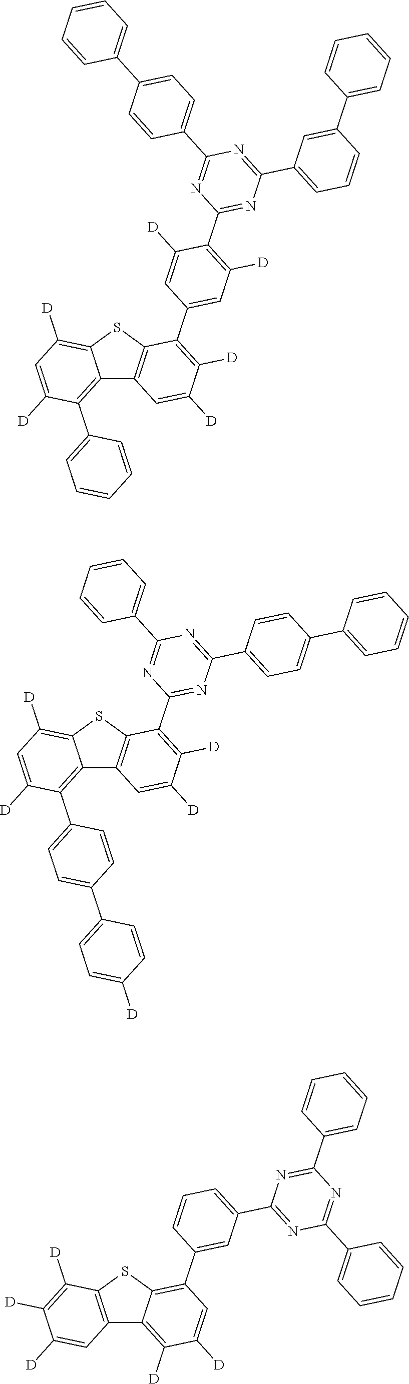 [SMILES: [2H]c1cc2c(sc3c([2H])cc([2H])c(-c4ccccc4)c32)c(-c2cc([2H])c(-c3nc(-c4ccc(-c5ccccc5)cc4)nc(-c4cccc(-c5ccccc5)c4)n3)c([2H])c2)c1[2H] ; [2H]c1ccc(-c2ccc(-c3c([2H])cc([2H])c4sc5c(-c6nc(-c7ccccc7)nc(-c7ccc(-c8ccccc8)cc7)n6)c([2H])c([2H])cc5c34)cc2)cc1 ; [2H]c1cc2c(sc3c(-c4cccc(-c5nc(-c6ccccc6)nc(-c6ccccc6)n5)c4)cc([2H])c([2H])c32)c([2H])c1[2H]]

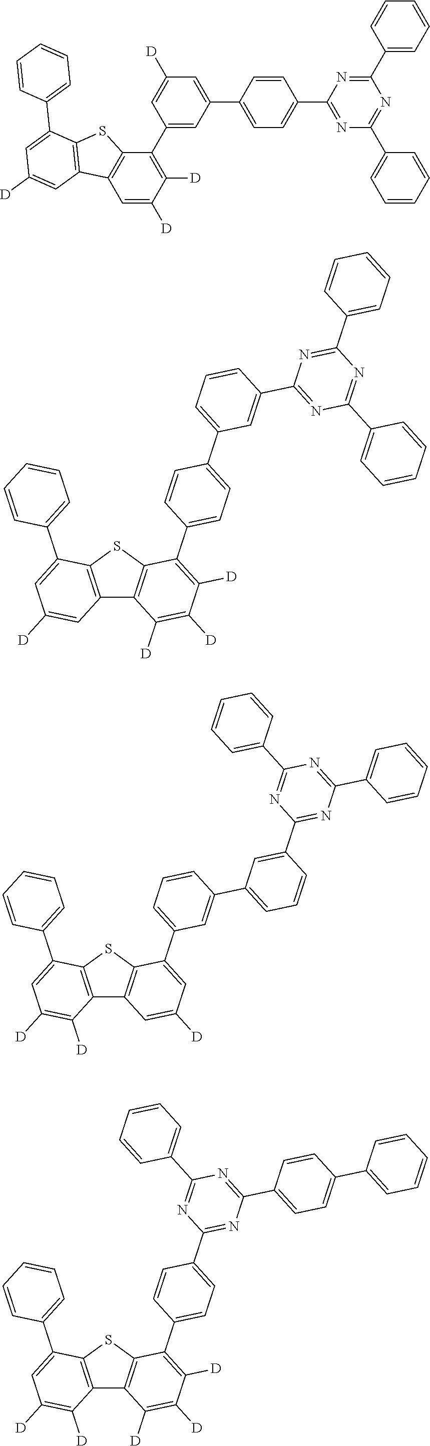 [SMILES: [2H]c1cc(-c2ccc(-c3nc(-c4ccccc4)nc(-c4ccccc4)n3)cc2)cc(-c2c([2H])c([2H])cc3c2sc2c(-c4ccccc4)cc([2H])cc23)c1 ; [2H]c1cc(-c2ccccc2)c2sc3c(-c4ccc(-c5cccc(-c6nc(-c7ccccc7)nc(-c7ccccc7)n6)c5)cc4)c([2H])c([2H])c([2H])c3c2c1 ; [2H]c1cc(-c2cccc(-c3cccc(-c4nc(-c5ccccc5)nc(-c5ccccc5)n4)c3)c2)c2sc3c(-c4ccccc4)cc([2H])c([2H])c3c2c1 ; [2H]c1cc(-c2ccccc2)c2sc3c(-c4ccc(-c5nc(-c6ccccc6)nc(-c6ccc(-c7ccccc7)cc6)n5)cc4)c([2H])c([2H])c([2H])c3c2c1[2H]]

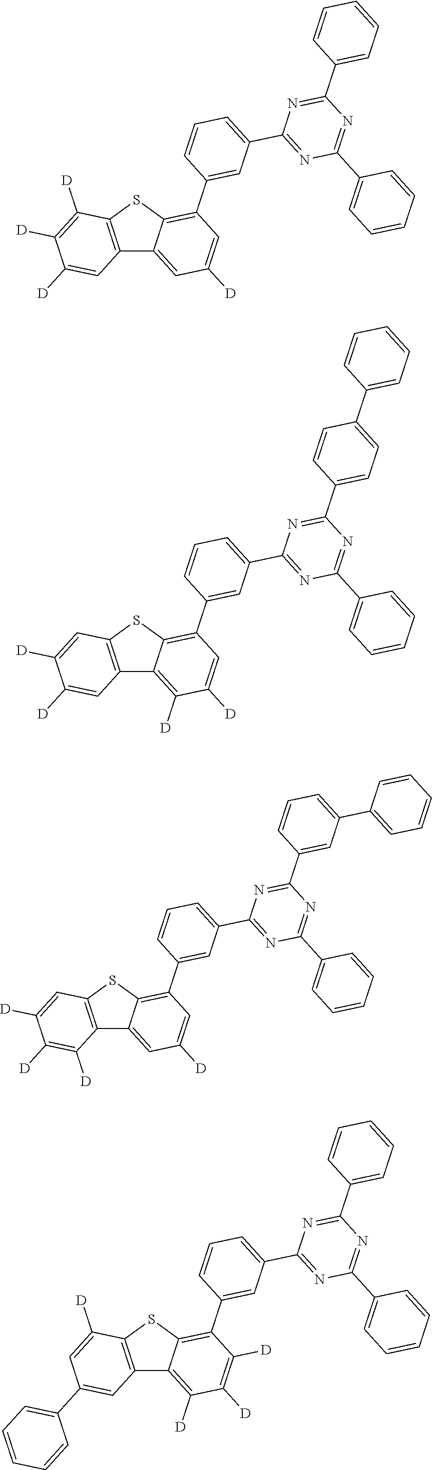 [SMILES: [2H]c1cc(-c2cccc(-c3nc(-c4ccccc4)nc(-c4ccccc4)n3)c2)c2sc3c([2H])c([2H])c([2H])cc3c2c1 ; [2H]c1cc2sc3c(-c4cccc(-c5nc(-c6ccccc6)nc(-c6ccc(-c7ccccc7)cc6)n5)c4)cc([2H])c([2H])c3c2cc1[2H] ; [2H]c1cc(-c2cccc(-c3nc(-c4ccccc4)nc(-c4cccc(-c5ccccc5)c4)n3)c2)c2sc3cc([2H])c([2H])c([2H])c3c2c1 ; [2H]c1c([2H])c([2H])c2c(sc3c([2H])cc(-c4ccccc4)cc32)c1-c1cccc(-c2nc(-c3ccccc3)nc(-c3ccccc3)n2)c1]

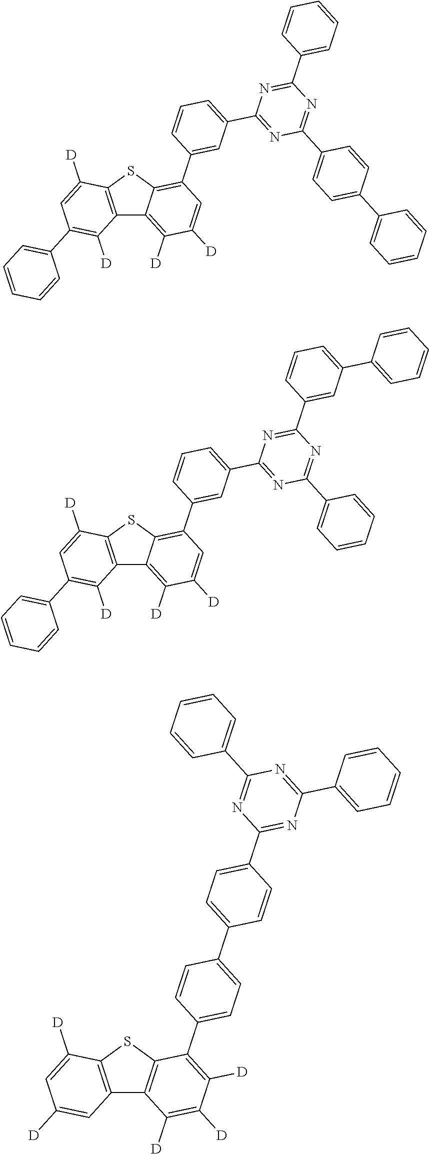 [SMILES: [2H]c1cc(-c2cccc(-c3nc(-c4ccccc4)nc(-c4ccc(-c5ccccc5)cc4)n3)c2)c2sc3c([2H])cc(-c4ccccc4)c([2H])c3c2c1[2H] ; [2H]c1cc(-c2cccc(-c3nc(-c4ccccc4)nc(-c4cccc(-c5ccccc5)c4)n3)c2)c2sc3c([2H])cc(-c4ccccc4)c([2H])c3c2c1[2H] ; [2H]c1cc([2H])c2sc3c(-c4ccc(-c5ccc(-c6nc(-c7ccccc7)nc(-c7ccccc7)n6)cc5)cc4)c([2H])c([2H])c([2H])c3c2c1]

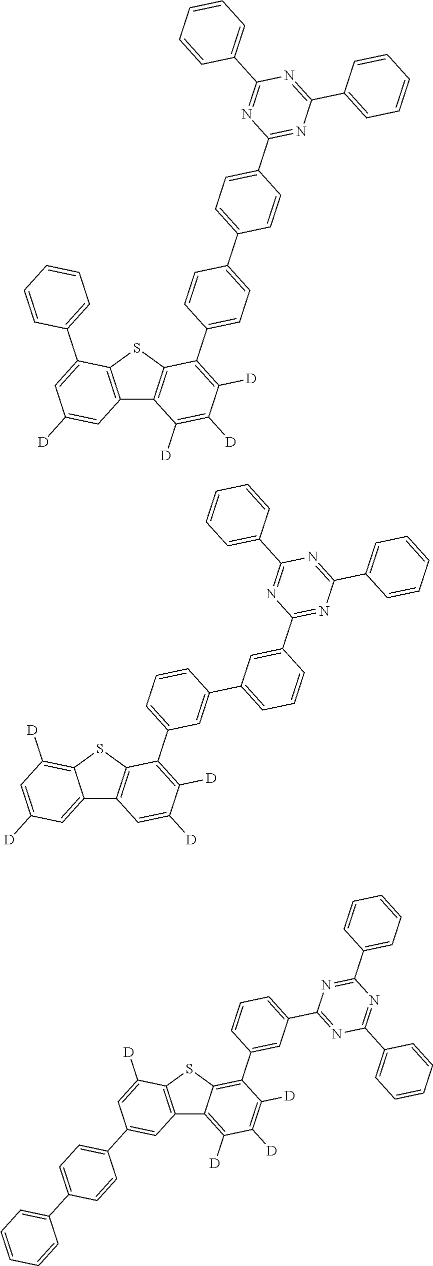 [SMILES: [2H]c1cc(-c2ccccc2)c2sc3c(-c4ccc(-c5ccc(-c6nc(-c7ccccc7)nc(-c7ccccc7)n6)cc5)cc4)c([2H])c([2H])c([2H])c3c2c1 ; [2H]c1cc([2H])c2sc3c(-c4cccc(-c5cccc(-c6nc(-c7ccccc7)nc(-c7ccccc7)n6)c5)c4)c([2H])c([2H])cc3c2c1 ; [2H]c1c([2H])c([2H])c2c(sc3c([2H])cc(-c4ccc(-c5ccccc5)cc4)cc32)c1-c1cccc(-c2nc(-c3ccccc3)nc(-c3ccccc3)n2)c1]

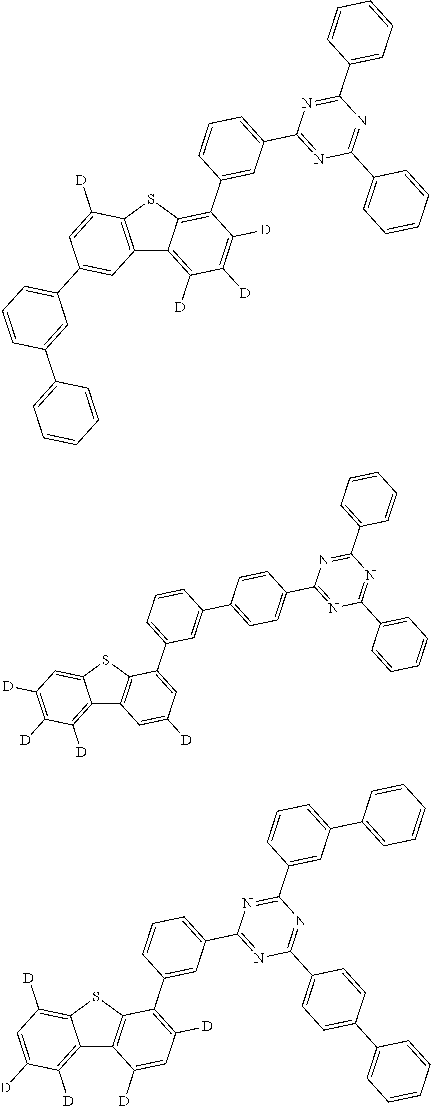 [SMILES: [2H]c1c([2H])c([2H])c2c(sc3c([2H])cc(-c4cccc(-c5ccccc5)c4)cc32)c1-c1cccc(-c2nc(-c3ccccc3)nc(-c3ccccc3)n2)c1 ; [2H]c1cc(-c2cccc(-c3ccc(-c4nc(-c5ccccc5)nc(-c5ccccc5)n4)cc3)c2)c2sc3cc([2H])c([2H])c([2H])c3c2c1 ; [2H]c1cc([2H])c2c(sc3c([2H])cc([2H])c([2H])c32)c1-c1cccc(-c2nc(-c3ccc(-c4ccccc4)cc3)nc(-c3cccc(-c4ccccc4)c3)n2)c1]

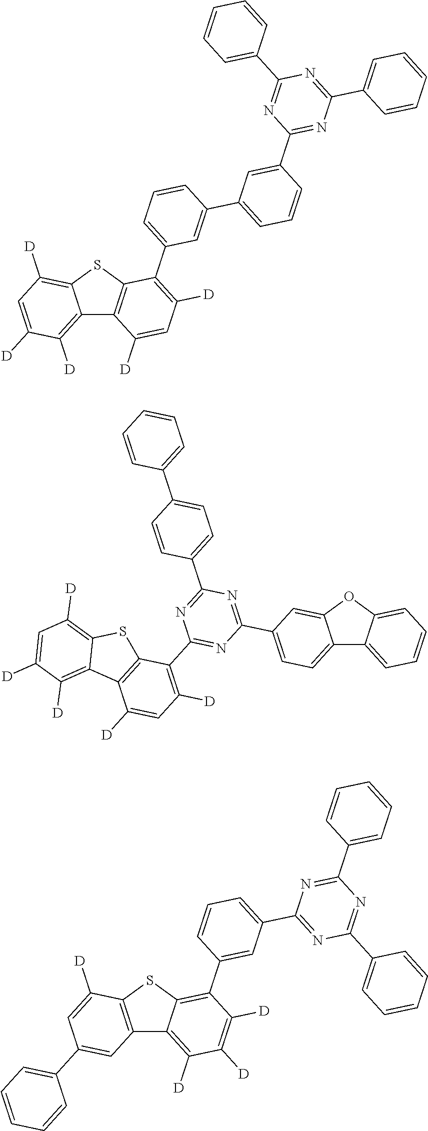

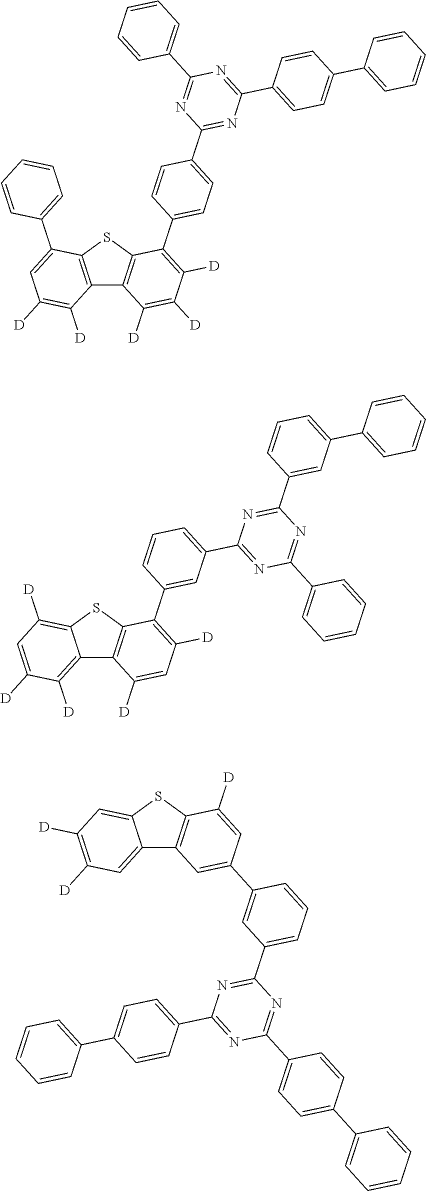 [SMILES: [2H]c1cc(-c2ccccc2)c2sc3c(-c4ccc(-c5nc(-c6ccccc6)nc(-c6ccc(-c7ccccc7)cc6)n5)cc4)c([2H])c([2H])c([2H])c3c2c1[2H] ; [2H]c1cc([2H])c2c(sc3c([2H])cc([2H])c([2H])c32)c1-c1cccc(-c2nc(-c3ccccc3)nc(-c3cccc(-c4ccccc4)c3)n2)c1 ; [2H]c1cc2sc3c([2H])cc(-c4cccc(-c5nc(-c6ccc(-c7ccccc7)cc6)nc(-c6ccc(-c7ccccc7)cc6)n5)c4)cc3c2cc1[2H]]

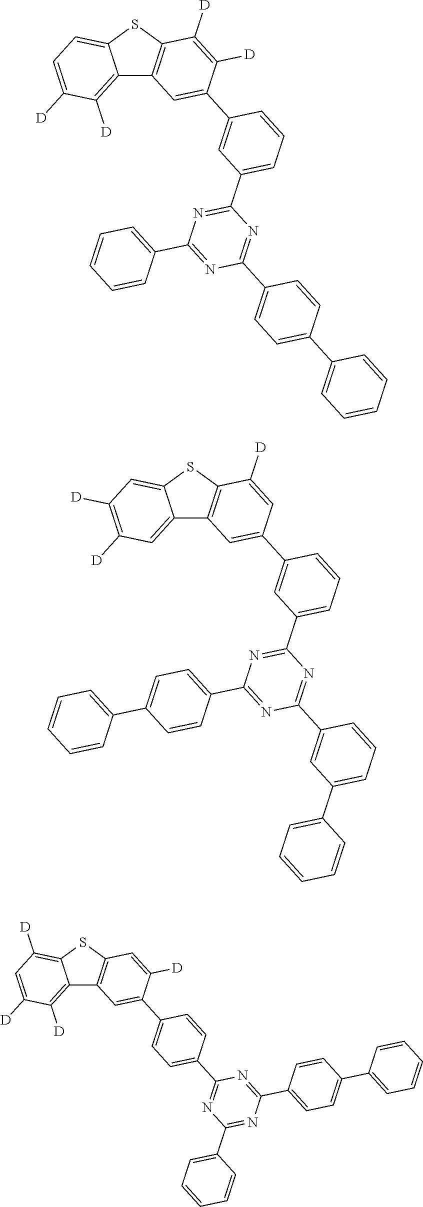 [SMILES: [2H]c1ccc2sc3c([2H])c([2H])c(-c4cccc(-c5nc(-c6ccccc6)nc(-c6ccc(-c7ccccc7)cc6)n5)c4)cc3c2c1[2H] ; [2H]c1cc2sc3c([2H])cc(-c4cccc(-c5nc(-c6ccc(-c7ccccc7)cc6)nc(-c6cccc(-c7ccccc7)c6)n5)c4)cc3c2cc1[2H] ; [2H]c1cc2sc3c([2H])cc([2H])c([2H])c3c2cc1-c1ccc(-c2nc(-c3ccccc3)nc(-c3ccc(-c4ccccc4)cc3)n2)cc1]

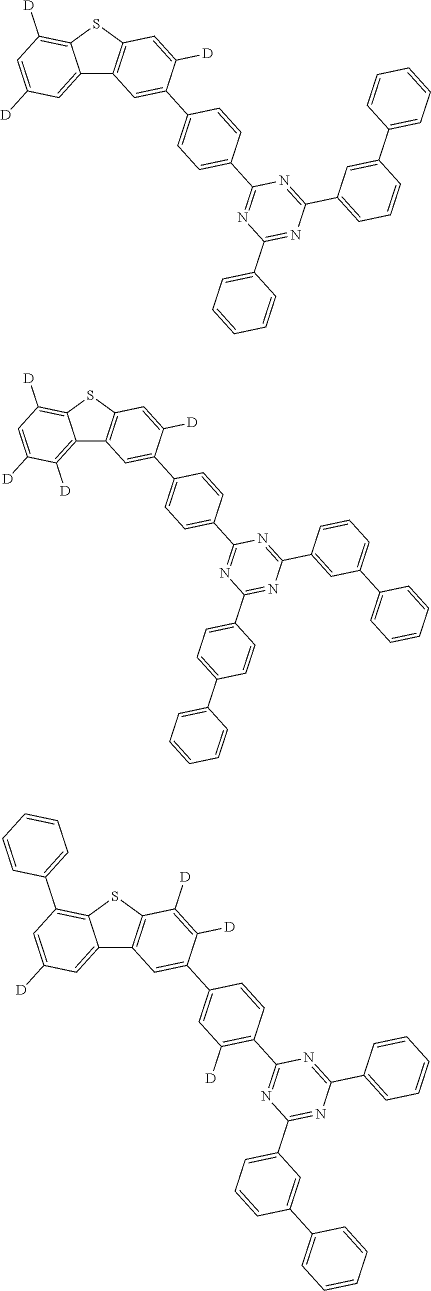 [SMILES: [2H]c1cc([2H])c2sc3cc([2H])c(-c4ccc(-c5nc(-c6ccccc6)nc(-c6cccc(-c7ccccc7)c6)n5)cc4)cc3c2c1 ; [2H]c1cc2sc3c([2H])cc([2H])c([2H])c3c2cc1-c1ccc(-c2nc(-c3ccc(-c4ccccc4)cc3)nc(-c3cccc(-c4ccccc4)c3)n2)cc1 ; [2H]c1cc(-c2ccccc2)c2sc3c([2H])c([2H])c(-c4ccc(-c5nc(-c6ccccc6)nc(-c6cccc(-c7ccccc7)c6)n5)c([2H])c4)cc3c2c1]

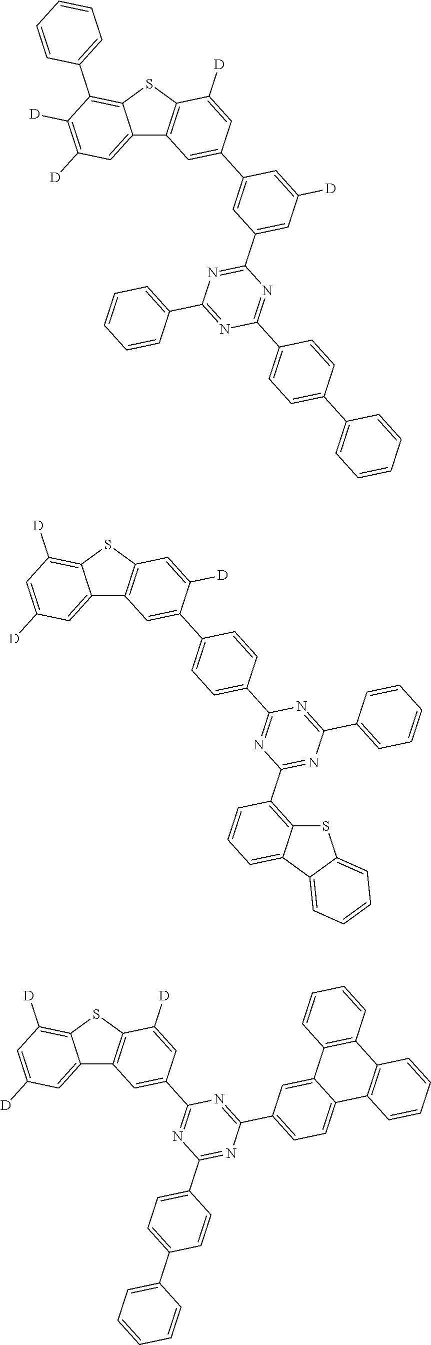 [SMILES: [2H]c1cc(-c2cc([2H])c3sc4c(-c5ccccc5)c([2H])c([2H])cc4c3c2)cc(-c2nc(-c3ccccc3)nc(-c3ccc(-c4ccccc4)cc3)n2)c1 ; [2H]c1cc([2H])c2sc3cc([2H])c(-c4ccc(-c5nc(-c6ccccc6)nc(-c6cccc7c6sc6ccccc67)n5)cc4)cc3c2c1 ; [2H]c1cc([2H])c2sc3c([2H])cc(-c4nc(-c5ccc(-c6ccccc6)cc5)nc(-c5ccc6c7ccccc7c7ccccc7c6c5)n4)cc3c2c1]

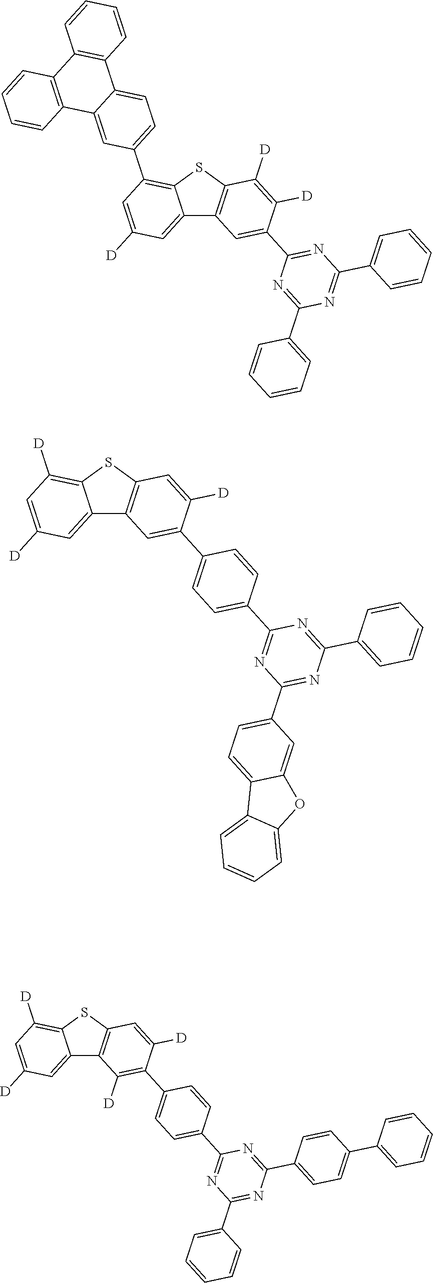 [SMILES: [2H]c1cc(-c2ccc3c4ccccc4c4ccccc4c3c2)c2sc3c([2H])c([2H])c(-c4nc(-c5ccccc5)nc(-c5ccccc5)n4)cc3c2c1 ; [2H]c1cc([2H])c2sc3cc([2H])c(-c4ccc(-c5nc(-c6ccccc6)nc(-c6ccc7c(c6)oc6ccccc67)n5)cc4)cc3c2c1 ; [2H]c1cc([2H])c2sc3cc([2H])c(-c4ccc(-c5nc(-c6ccccc6)nc(-c6ccc(-c7ccccc7)cc6)n5)cc4)c([2H])c3c2c1]

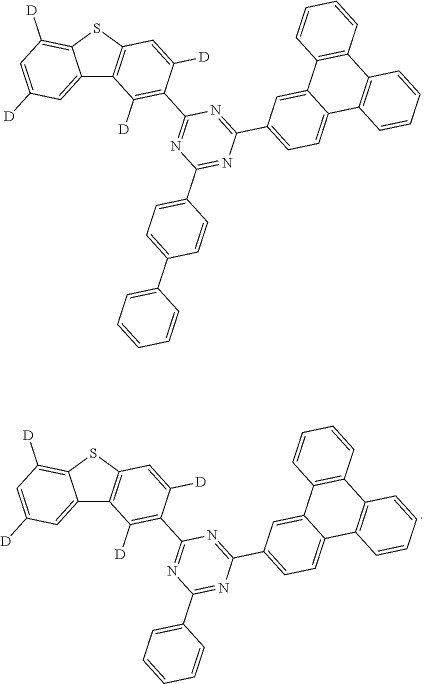 [SMILES: [2H]c1cc([2H])c2sc3cc([2H])c(-c4nc(-c5ccc(-c6ccccc6)cc5)nc(-c5ccc6c7ccccc7c7ccccc7c6c5)n4)c([2H])c3c2c1 ; [2H]c1cc([2H])c2sc3cc([2H])c(-c4nc(-c5ccccc5)nc(-c5ccc6c7ccccc7c7ccccc7c6c5)n4)c([2H])c3c2c1]

Meanwhile, when the first compound is represented by Chemical Formula 1-1, it can be prepared by a preparation method as shown in the following Reaction Scheme 1 as an example:

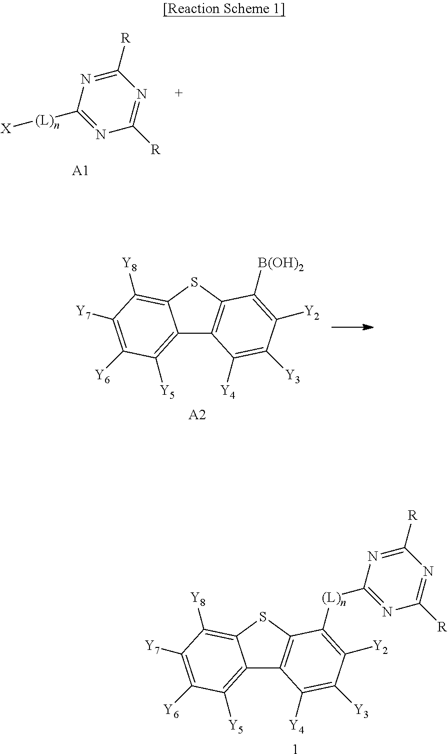

in Reaction Scheme 1, X is halogen, preferably bromo, or chloro, and the definitions of other substituents are the same as described above.

Specifically, the first compound may be prepared by a Suzuki coupling reaction of the starting materials A1 and A2. Such a Suzuki coupling reaction is preferably carried out in the presence of a palladium catalyst and a base, and a reactive group for the Suzuki coupling reaction can be appropriately changed. The preparation method of the first compound can be further embodied in Preparation Examples described hereinafter.

### (Second Compound)

The second compound is represented by Chemical Formula 2 above.

Specifically, the second compound has a biscarbazole structure containing at least one deuterium, and thus can efficiently transport holes to the dopant material, thereby capable of increasing the recombination probability of holes and electrons in the light emitting layer together with the first compound having excellent electron transport capability.

In particular, the second compound has a structure in which at least one of R′₁ and R′₂ is deuterium; or at least one of Ar′₁ and Ar′₂ is substituted with deuterium.

Specifically, the second compound satisfies at least one of the following:
1) at least one of R′₁ is deuterium;
2) at least one of R′₂ is deuterium;
3) a C₆₋₆₀ aryl in which Ar′₁ is substituted with deuterium; or a C₂₋₆₀ heteroaryl containing at least one heteroatom of N, O and S substituted with deuterium; and
4) a C₆₋₆₀ aryl in which Ar′₂ is substituted with deuterium; or a C₂₋₆₀ heteroaryl containing at least one heteroatom of N, O and S substituted with deuterium.

According to one embodiment, the second compound may be represented by the following Chemical Formula 2-1:

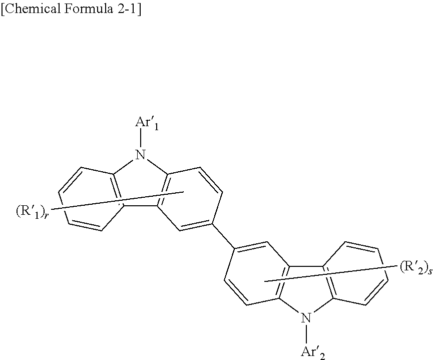

wherein, in Chemical Formula 2-1,
Ar′₁, Ar′₂, R′₁, R′₂, r and s are as defined in Chemical Formula 2.

In addition, Ar′₁ and Ar′₂ are each independently a substituted or unsubstituted C₆₋₂₀ aryl, or a C₂₋₂₀ heteroaryl containing one heteroatom of N, O and S,
wherein Ar′₁ and Ar′₂ may be unsubstituted, or substituted with at least one substituent selected from the group consisting of deuterium and a C₆₋₂₀ aryl substituted or unsubstituted with deuterium.

For example, Ar′₁ and Ar′₂ are each independently phenyl, biphenylyl, terphenylyl, naphthyl, dimethylfluorenyl, dibenzofuranyl, or dibenzothiophenyl,
wherein Ar′₁ may be unsubstituted, or substituted with at least one substituent selected from the group consisting of deuterium and a C₆₋₂₀ aryl substituted or unsubstituted with deuterium.

At this time, at least one of Ar′₁ and Ar′₂ may be phenyl unsubstituted or substituted with deuterium, or biphenylyl unsubstituted or substituted with deuterium.

More specifically, Ar′₁ and Ar′₂ may be each independently phenyl unsubstituted or substituted with 1 to 5 deuteriums; biphenylyl unsubstituted or substituted with 1 to 9 deuteriums; terphenylyl unsubstituted or substituted with 1 to 9 deuteriums; naphthyl unsubstituted or substituted with 1 to 7 deuteriums; dimethylfluorenyl unsubstituted or substituted with 1 to 13 deuteriums; dibenzofuranyl unsubstituted or substituted with 1 to 7 deuteriums; or dibenzothiophenyl unsubstituted or substituted with 1 to 7 deuterium atoms.

At this time, Ar′₁ and Ar′₂ may be the same or different from each other.

Further, R′₁ and R′₂ may be each independently deuterium; or a substituted or unsubstituted C₆₋₂₀ aryl.

In one embodiment, R′₁ and R′₂ may be each independently deuterium; or a C₆₋₂₀ aryl unsubstituted or substituted with deuterium.

In other embodiments, R′₁ and R′₂ may be each independently deuterium; or phenyl unsubstituted or substituted with 1 to 5 deuterium atoms.

Further, r and s, each representing the numbers of R′₁ and R′₂, may each independently be 1, 2, 3, 4, 5, 6, or 7.

At this time, R′₁ and R′₂ may be the same or different from each other.

Further, r+s may be 1 or more, 2 or more, 3 or more, 4 or more, 5 or more, 6 or more, 7 or more, 8 or more, 9 or more, 10 or more, or 11 or more, and 14 or less, 13 or less, or 12 or less.

Further, the second compound may contain 1 to 40 deuterium atoms. More specifically, the compound may include 1 or more, 2 or more, 3 or more, 4 or more, 5 or more, 10 or more, 15 or more, 16 or more, 17 or more, or 18 or more, and 40 or less, 35 or less, 30 or less, 29 or less, 28 or less, 27 or less, 26 or less, 25 or less, 24 or less, 23 or less, 22 or less, 21 or less, or 20 or less deuterium atoms.

Further, the deuterium substitution rate of the second compound may be 50% to 100%. Specifically, the deuterium substitution rate of the compound may be 50% or more, 55% or more, 60% or more, 61% or more, or 62% or more, and 100% or less, 90% or less, 85% or less, 80% or less, and 75% or less, 70% or less, or 65% or less.

Representative examples of the second compounds are as follows:

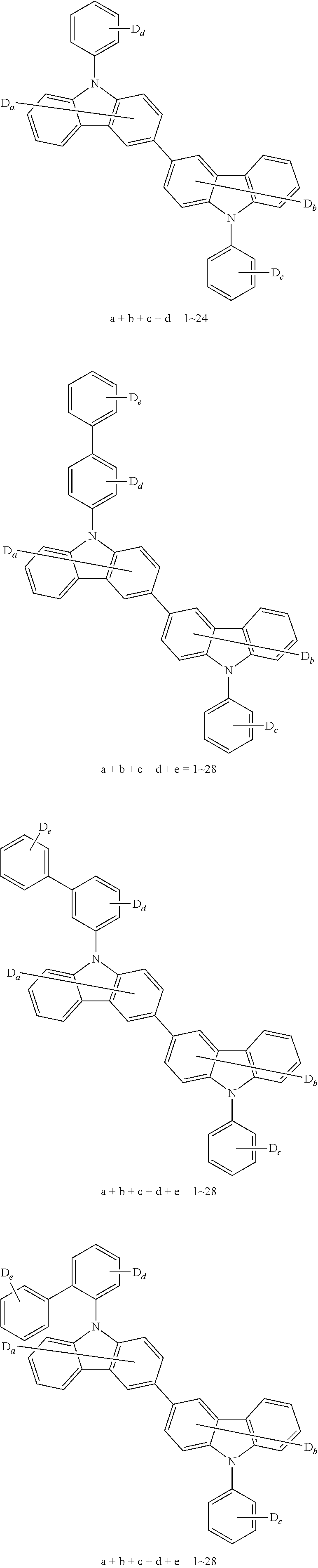

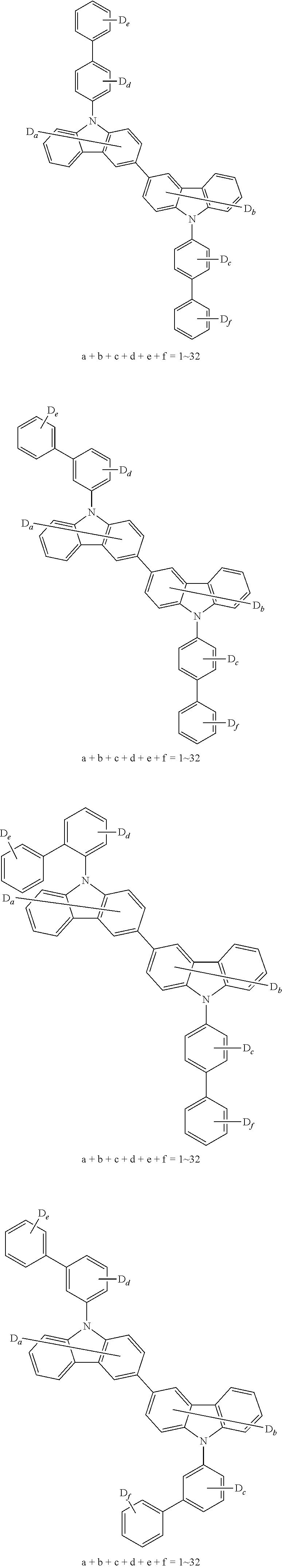

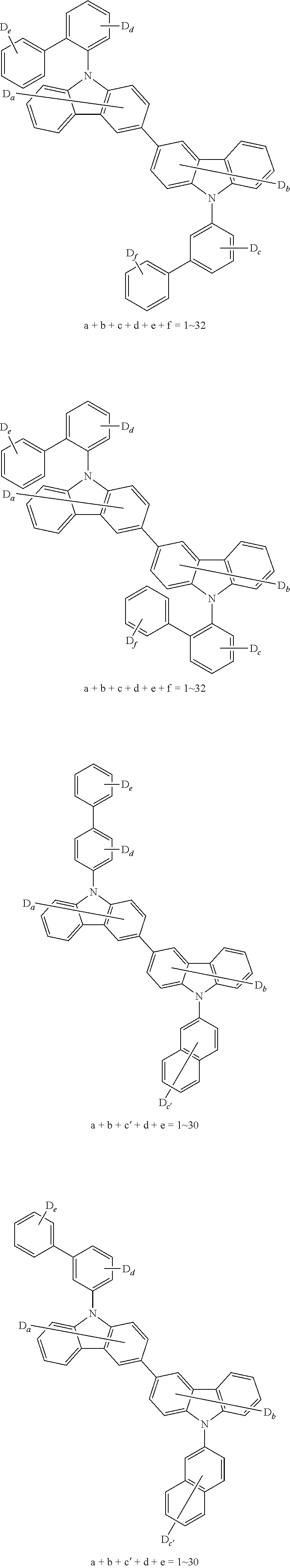

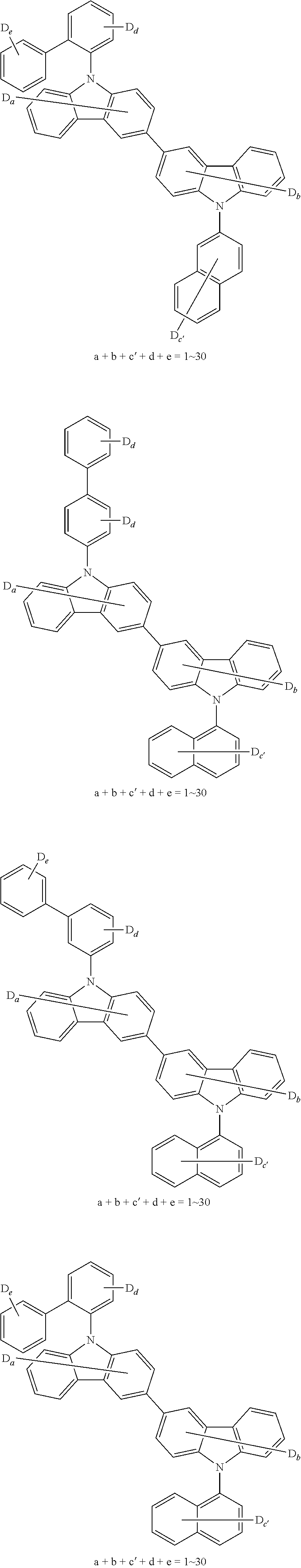

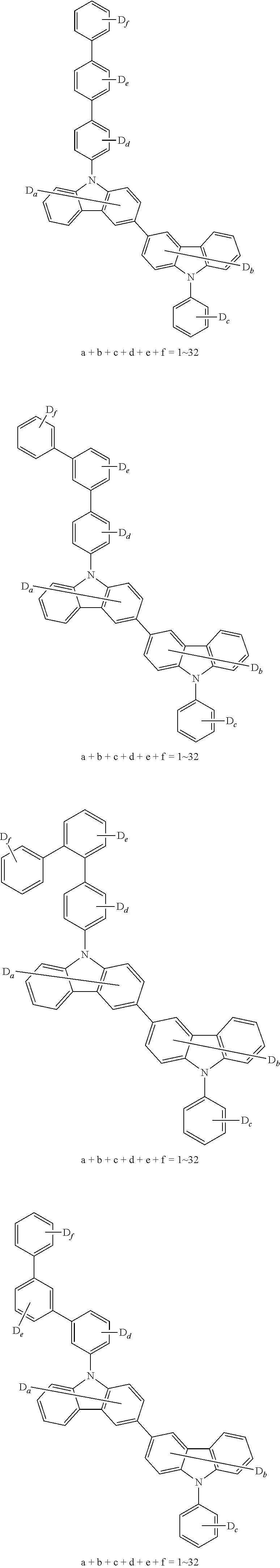

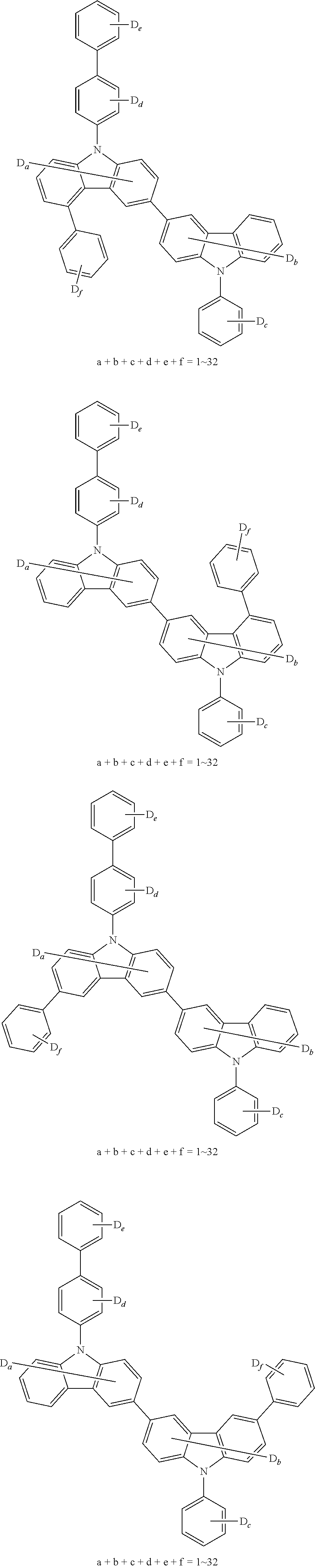

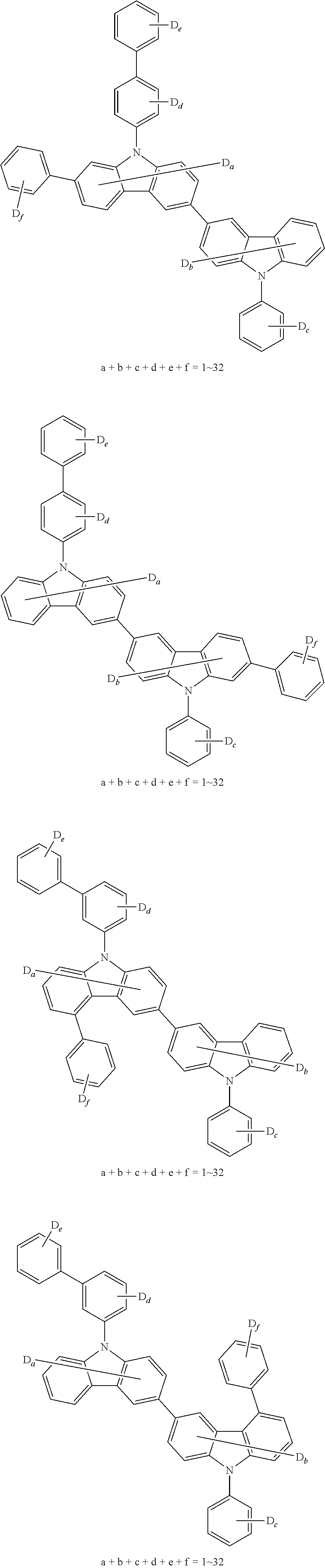

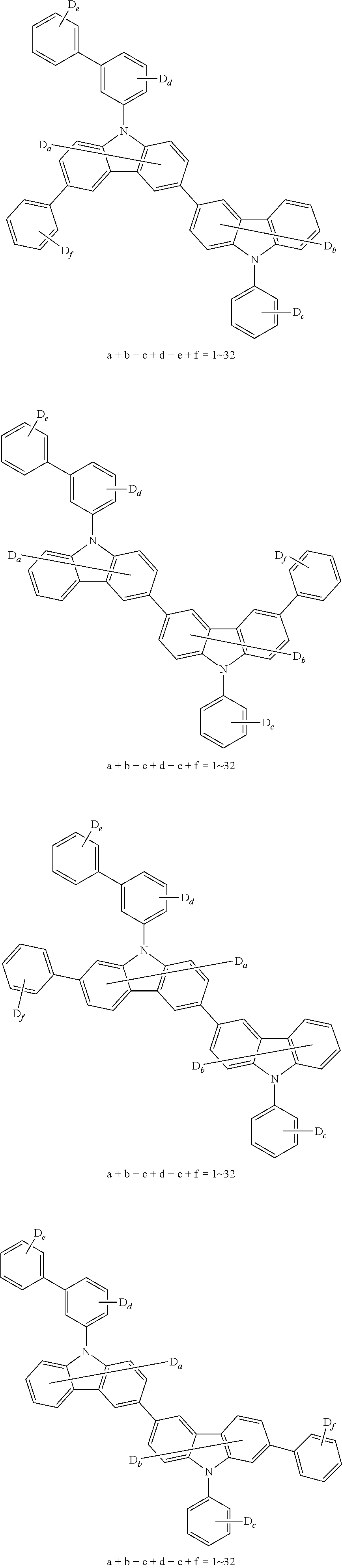

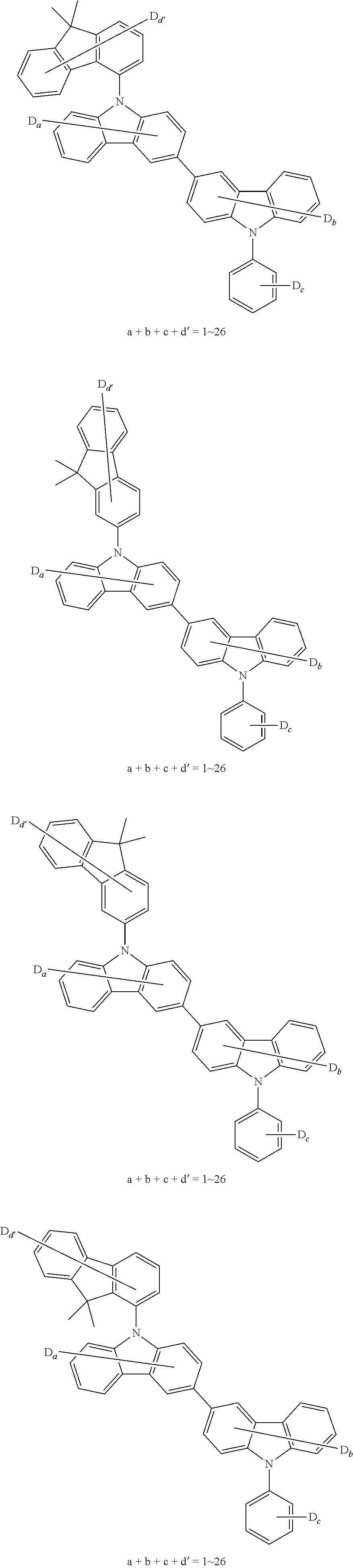

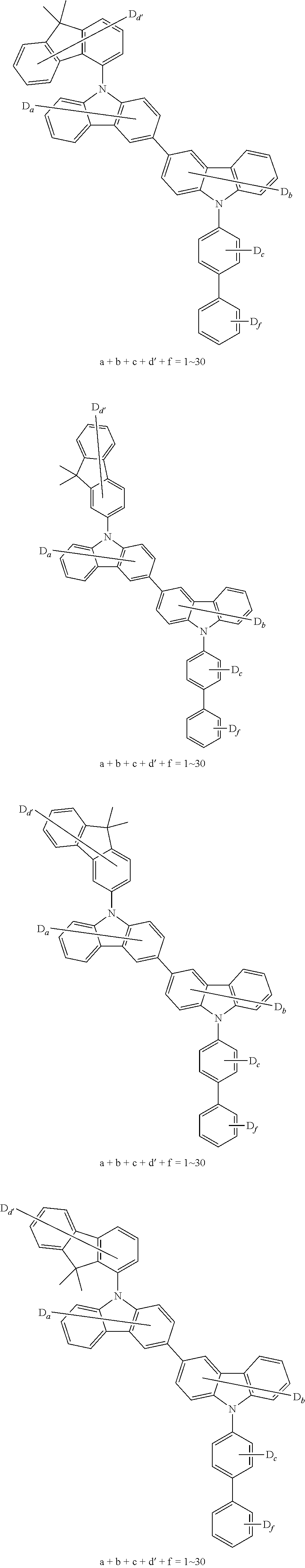

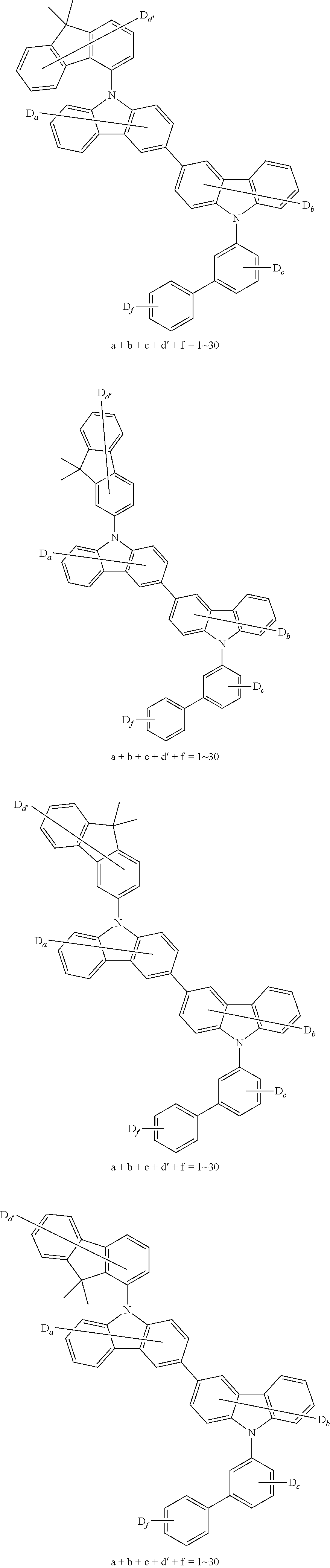

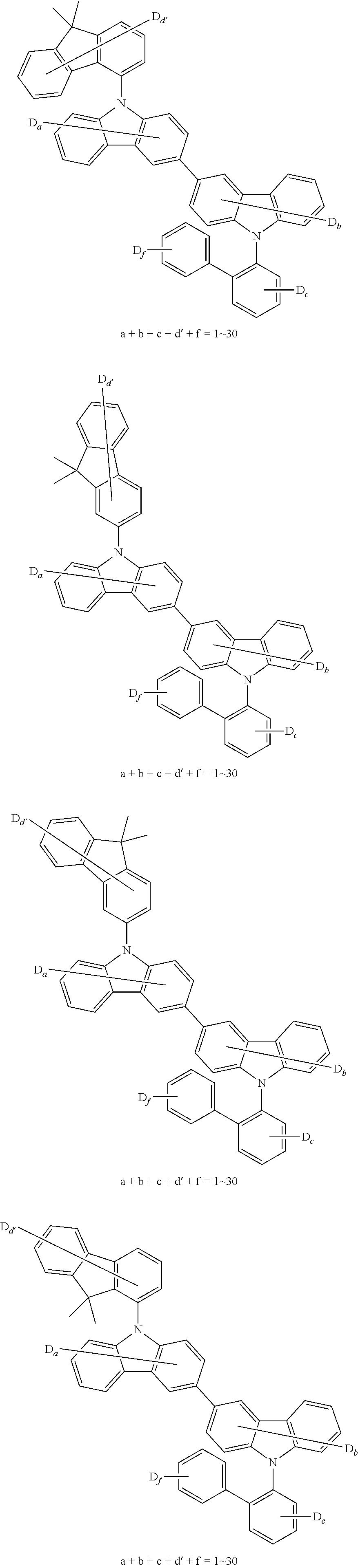

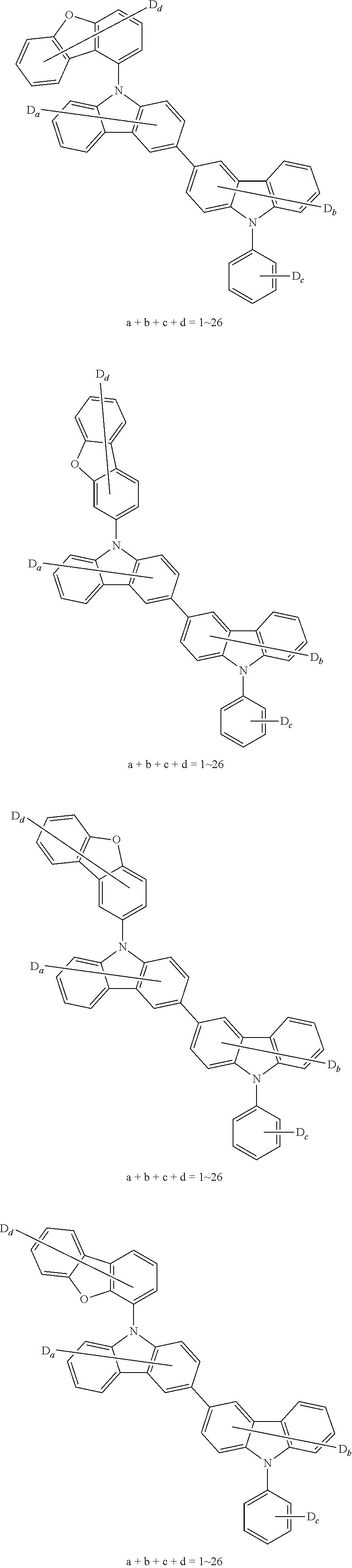

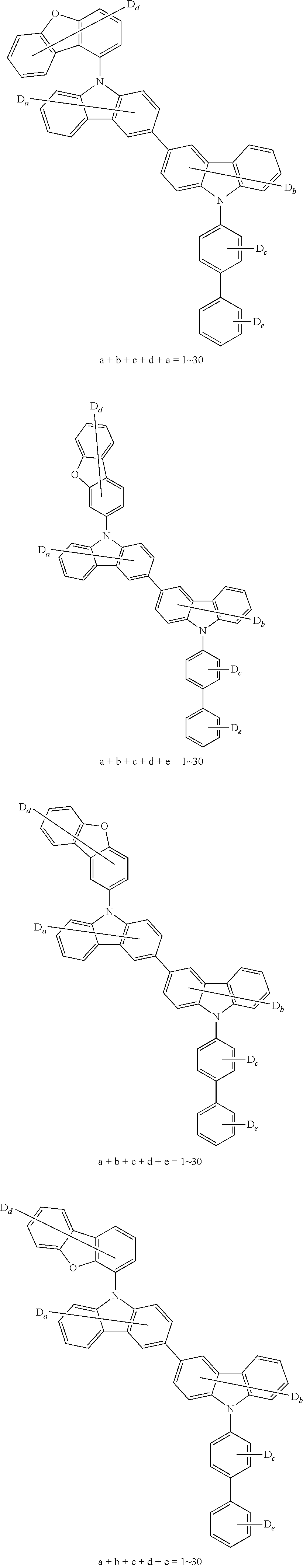

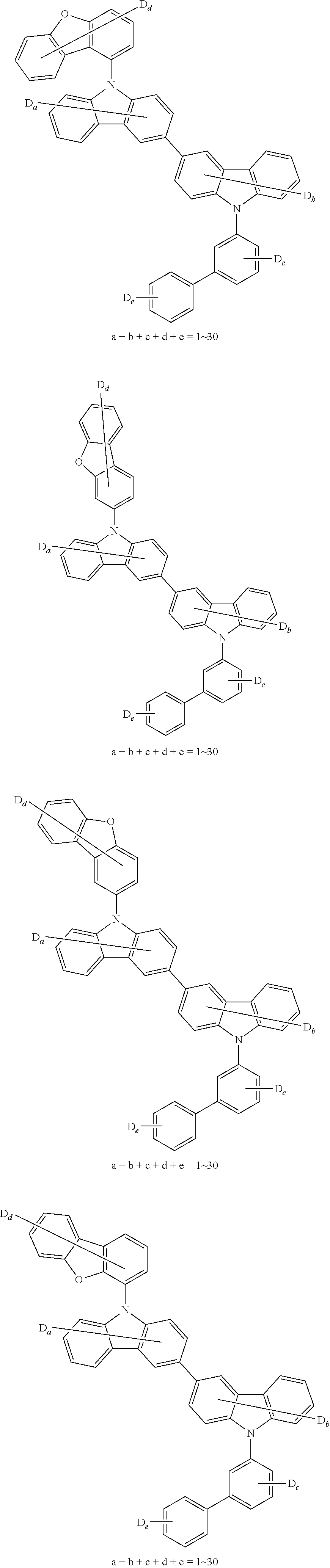

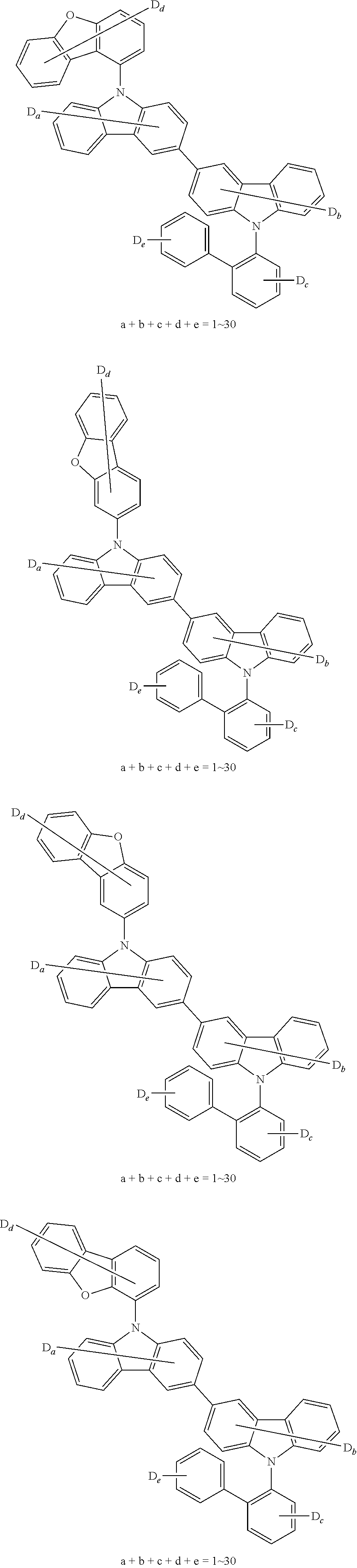

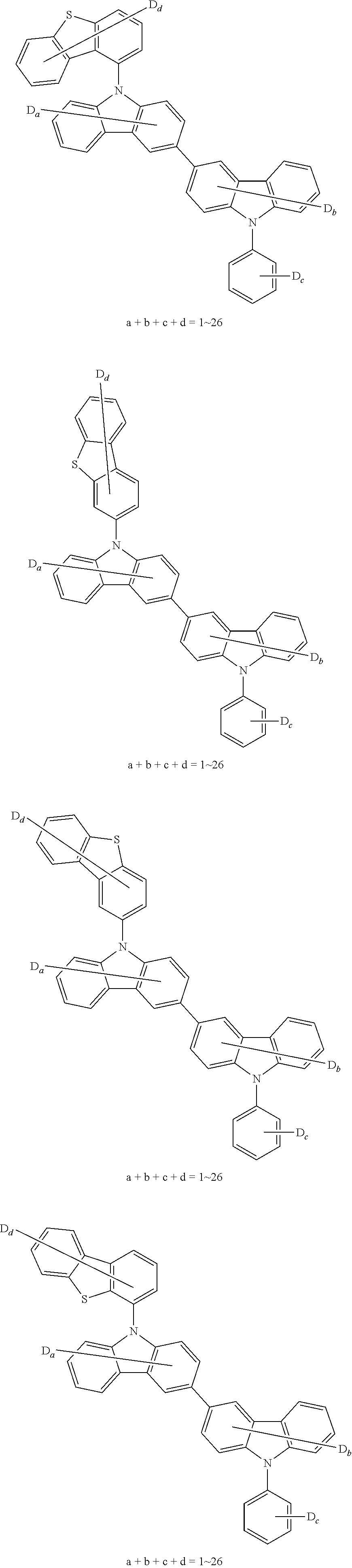

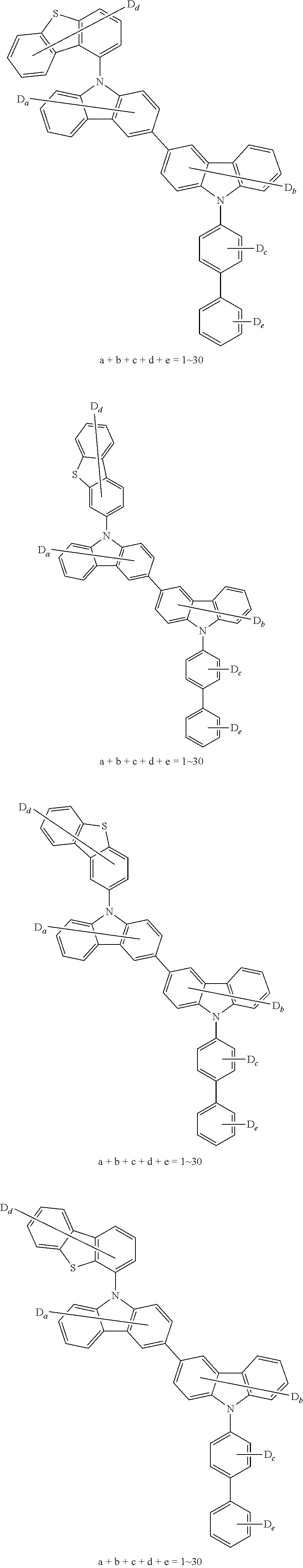

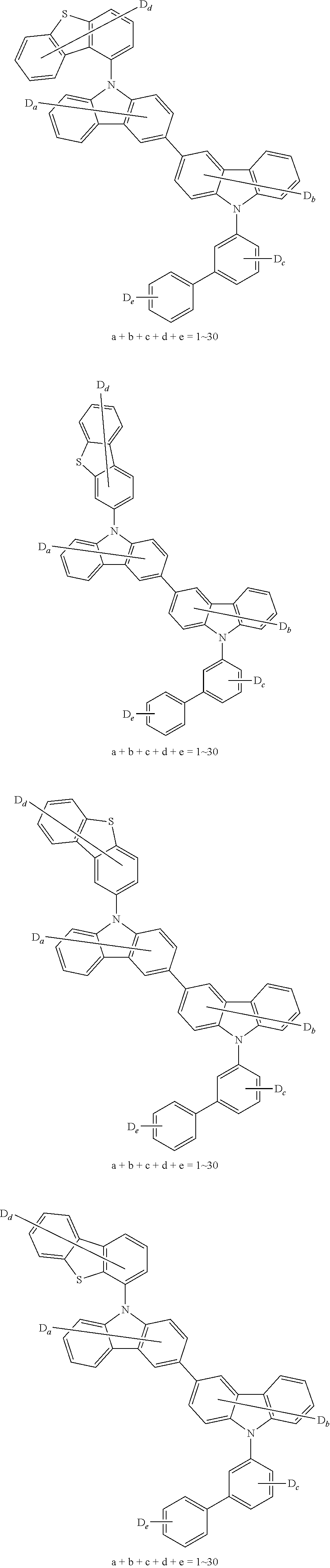

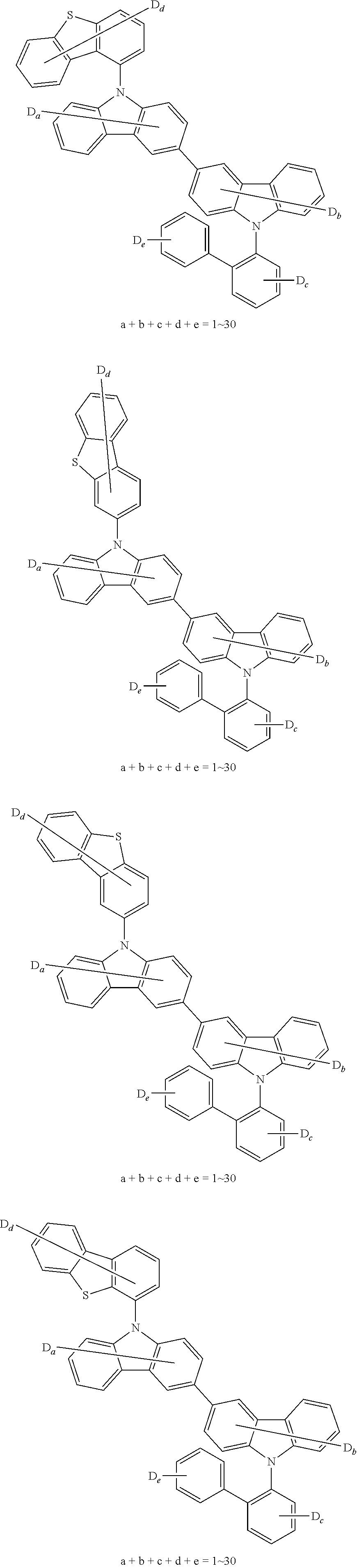

wherein,
a, b, c, d, e and f each means the number of deuterium substitutions at the indicated moiety, and each means an integer from 0 to the maximum number of substitutable hydrogens in the moiety.

As an example, in the following compounds, a is an integer from 0 to 7, b is an integer from 0 to 7, c is an integer from 0 to 4, d is an integer from 0 to 4, and e is an integer from 0 to 5., and f is an integer from 0 to 5.

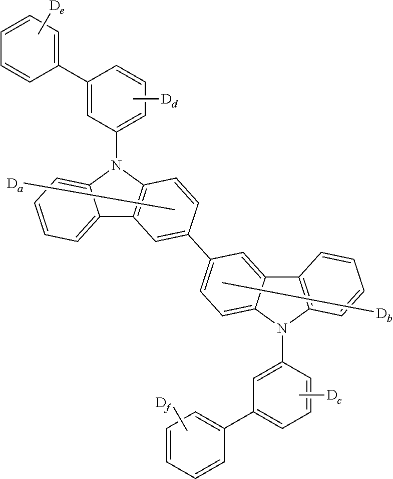

Meanwhile, the second compound can be prepared by a preparation method as shown in the following Reaction Schemes 2-1 and 2-2 as an example:

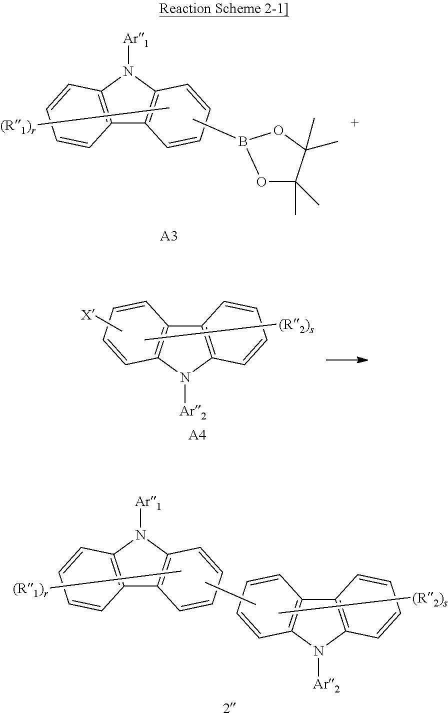

in Reaction Scheme 2-1, X′ is halogen, preferably bromo, or chloro, Ar″₁, Ar″₂, R″₁ and R″₂ mean substituents in which Ar′₁, Ar′₂, R′₁ and R′₂ are not substituted with deuterium, respectively.

Specifically, the 2″nd compound may be prepared by a Suzuki coupling reaction of the starting materials A3 and A4. Such a Suzuki coupling reaction is preferably carried out in the presence of a palladium catalyst and a base, and a reactive group for the Suzuki coupling reaction can be appropriately changed.

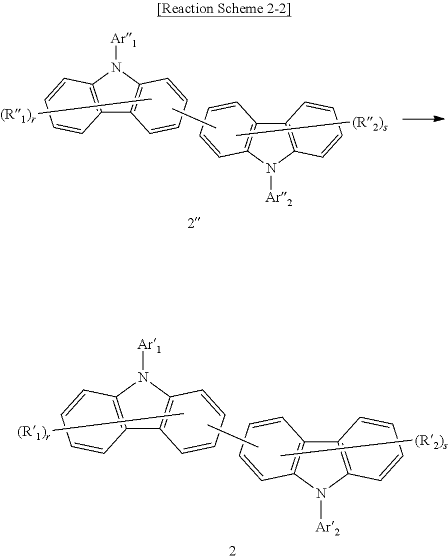

in Reaction Scheme 2-2, the definitions of Ar′₁, Ar′₂, R′₁ and R′₂ are the same as described above. Specifically, the second compound may be prepared by deuterating a 2nd” compound which is not substituted with deuterium. At this time, the deuterium substitution reaction may be performed under high temperature and pressurizing conditions after adding the 2″nd compound not substituted with deuterium to a deuterated solvent such as D₂O under a catalyst such as PtO₂. Here, the degree of deuterium substitution rate can be adjusted by varying reaction conditions such as reaction temperature and pressure.

The preparation method of the second compound can be further embodied in Preparation Examples described hereinafter.

Further, the first compound and the second compound may be contained in the light emitting layer at a weight ratio of 1:99 to 99:1. At this time, in the viewpoint of appropriately maintaining the ratio of holes and electrons in the light emitting layer, the first compound and the second compound are preferably contained at a weight ratio of 10:90 to 50:50, or 20:80 to 40:60. Preferably, the first compound and the second compound may be contained in the light emitting layer at a weight ratio of 30:70.

In one embodiment, both the first compound and the second compound may have a deuterium substitution rate of 3% or more, 5% or more, 7% or more, 9% or more, 10% or more, 12% or more, or 13% or more, and 100% or less, 90% or less, 85% or less, 80% or less, or 75% or less, 70% or less.

In another embodiment, the deuterium substitution rate of the second compound may be higher than the deuterium substitution rate of the first compound. Due to the structural characteristics of the second compound, increasing the deuterium substitution rate compared to the first compound can help improve the lifetime characteristics of the organic light emitting device.

In another embodiment, the second compound may have 5 or more deuterium substitutions relative to the first compound. More specifically, the second compound may have 5 or more, 6 or more, 7 or more, 8 or more, 9 or more, 10 or more, 11 or more, 12 or more, 13 or more, or 14 or more, and 25 or less, 24 or less, 23 or less, 22 or less, 21 or less, or 20 or less deuterium substitutions relative to the first compound.

In another embodiment, the difference between the deuterium substitution rate of the second compound and the deuterium substitution rate of the first compound may be 5% or more. More specifically, the difference between the deuterium substitution rate of the second compound and the deuterium substitution rate of the first compound may be 5% or more, 10% or more, 20% or more, 30% or more, or 40% or more, and 80% or less, 70% or more, 60% or less, or 50% or less.

In this manner, when the first compound and the second compound are respectively represented by Chemical Formula 1 and Chemical Formula 2, and further satisfy the following conditions, the charge balance between hosts in the light emitting layer is appropriate, allowing excitons to be more stable, whereby the voltage, efficiency and/or lifetime characteristics of an organic light emitting device having such a light emitting layer can be further improved:
1) the second compound is contained in the light emitting layer in a higher weight than the first compound;
2) the deuterium substitution rate of the second compound is higher than the deuterium substitution rate of the first compound; and
3) The second compound has 5 or more deuterium substitutions than the first compound.

On the other hand, the light emitting layer may further include a dopant material in addition to the two types of host materials. Such a dopant material includes an aromatic amine derivative, a styrylamine compound, a boron complex, a fluoranthene compound, a metal complex, and the like. Specific examples of the aromatic amine derivative include substituted or unsubstituted fused aromatic ring derivatives having a substituted or unsubstituted arylamino group, examples of which include pyrene, anthracene, chrysene, and periflanthene having the arylamino group, and the like. The styrylamine compound is a compound where at least one arylvinyl group is substituted in a substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto.

### Hole Blocking Layer

The organic light emitting device according to the present disclosure may include a hole blocking layer between the light emitting layer and an electron transport layer described hereinafter, if necessary. The hole blocking layer refers to a layer which is formed on the light emitting layer, preferably provided in contact with the light emitting layer, and serves to adjust the electron mobility, prevent excessive movement of holes, and increase the probability of hole-electron coupling, thereby improving the efficiency of the organic light emitting device. The hole blocking layer includes a hole blocking material, and examples of such hole blocking material may include a compound having an electron withdrawing group introduced therein, such as azine derivatives including triazine; triazole derivatives; oxadiazole derivatives; phenanthroline derivatives; phosphine oxide derivatives, but is not limited thereto.

### Electron Injection and Transport Layer

The electron injection and transport layer is a layer for simultaneously performing the roles of an electron transport layer and an electron injection layer that inject electrons from an electrode and transport the received electrons up to the light emitting layer, and is formed on the light emitting layer or the hole blocking layer. The electron injection and transport material is suitably a material which can receive electrons well from a cathode and transfer the electrons to alight emitting layer, and has a large mobility for electrons. Specific examples of the electron injection and transport material include: an A1 complex of 8-hydroxyquinoline; a complex including Alq3; an organic radical compound; a hydroxyflavone-metal complex, a triazine derivative, and the like, but are not limited thereto. Alternatively, it may be used together with fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto.

The electron injection and transport layer may also be formed as a separate layer such as an electron injection layer and an electron transport layer. In such a case, the electron transport layer is formed on the light emitting layer or the hole blocking layer, and the above-mentioned electron injection and transport material may be used as the electron transport material included in the electron transport layer. In addition, the electron injection layer is formed on the electron transport layer, and examples of the electron injection material included in the electron injection layer include LiF, NaCl, CsF, Li₂O, BaO, fluorenone, anthraquinodimethane, diphenoquinone, thiopyran dioxide, oxazole, oxadiazole, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-hydroxyquinolinato)(2-naphtholato)gallium, and the like, but are not limited thereto.

### Organic Light Emitting Device

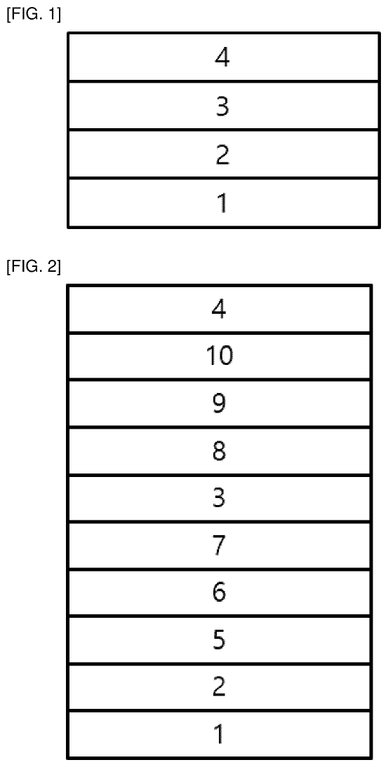

The organic light emitting device according to the present disclosure is illustrated in FIG. 1. FIG. 1 shows an example of an organic light emitting device comprising a substrate 1, an anode 2, a light emitting layer 3, and a cathode 4. In such a structure, the first compound and the second compound can be included in the light emitting layer.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron transport layer 9, a hole injection layer 10, and a cathode 4.

In such a structure, the first compound and the second compound can be included in the light emitting layer.

The organic light emitting device according to the present disclosure can be manufactured by sequentially stacking the above-described structures. In this case, the organic light emitting device may be manufactured by depositing a metal, metal oxides having conductivity, or an alloy thereof on the substrate by using a PVD (physical vapor deposition) method such as a sputtering method or an e-beam evaporation method to form the anode, forming the respective layers described above thereon, and then depositing a material that can be used as the cathode thereon. In addition to such a method, the organic light emitting device can be manufactured by sequentially depositing from the cathode material to the anode material on a substrate. Further, the light emitting layer may be formed by subjecting hosts and dopants to a vacuum deposition method and a solution coating method. Herein, the solution coating method means a spin coating, a dip coating, a doctor blading, an inkjet printing, a screen printing, a spray method, a roll coating, or the like, but is not limited thereto.

In addition to such a method, the organic light emitting device can be manufactured by sequentially depositing a cathode material, an organic material layer and an anode material on a substrate (International Publication WO2003/012890). However, the manufacturing method is not limited thereto.

The organic light emitting device according to the present disclosure may be a bottom emission type device, a top emission type device, or a double side emission type device, and in particular, it may be a bottom emission type light emitting device that requires relatively high luminous efficiency.

The preparation of the compound represented by Chemical Formula 1, the compound represented by Chemical Formula 2 and the organic light emitting device including the same will be specifically described in the following Examples. However, the following Examples are provided for illustrative purposes only, and are not intended to limit the scope of the present disclosure.

### Preparation Example A-1: Synthesis of Intermediate Compound 1-1

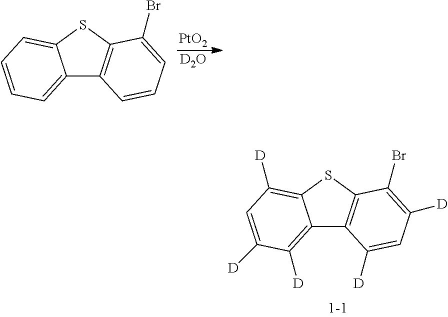

4-Bromo dibenzothiophene (20.0 g, 76.0 mmol), PtO₂ (5.18 g, 22.8 mmol), and D₂O (381 mL) were placed in a shaker tube, and then the tube was sealed and heated at 250° C. and 600 psi for 12 hours. When the reaction was completed, chloroform was added thereto, and the reaction solution was transferred to a separatory funnel, and extracted. The extract was dried over anhydrous magnesium sulfate and concentrated, and then the sample was purified by silica gel column chromatography to prepare Compound 1-1 (16.3 g, 80%, MS: [M+H]⁺=268).

### Preparation Example A-2: Synthesis of Intermediate Compound 1-2

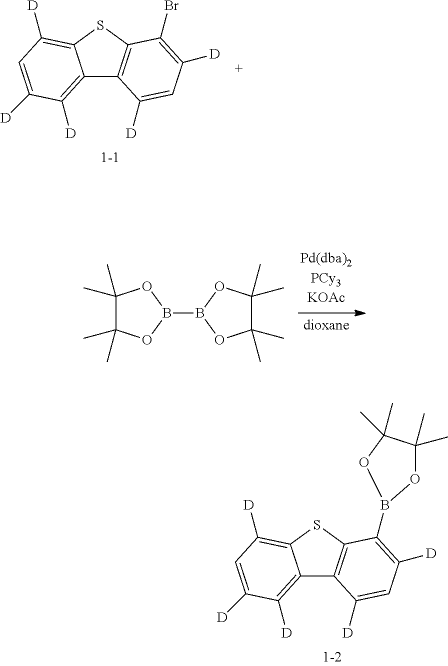

Compound 1-1 (16.3 g, 60.8 mmol) and bis(pinacolato)diborone (18.5 g, 72.9 mmol) were added to 326 mL of Diox under a nitrogen atmosphere, and the mixture was stirred and refluxed. Then, potassium carbonate (17.5 g, 182.3 mmol) was added thereto, and the mixture was sufficiently stirred, and then palladiumdibenzylideneacetonepalladium (1 g, 1.8 mmol) and tricyclohexylphosphine (1 g, 3.6 mmol) were added. After the reaction for 7 hours, the reaction mixture was cooled to room temperature, the organic layer was filtered to remove salt, and then the filtered organic layer was distilled. This was added again to 75 mL of chloroform, dissolved and washed twice with water. The organic layer was then separated, anhydrous magnesium sulfate was added thereto, stirred, then filtered, and the filtrate was distilled under reduced pressure. The concentrated compound was recrystallized from chloroform and ethanol to prepare Compound 1-2 as a solid (17.2 g, 90%, MS: [M+H]⁺=316.3).

### Preparation Example B-1: Synthesis of Intermediate Compound 2-1

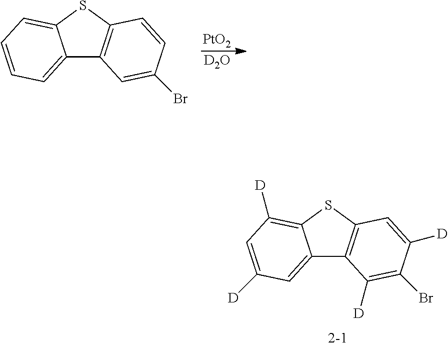

Compound 2-1 (11.7 g, yield: 77%; MS:[M+H]⁺=267) was prepared in the same manner as in the preparation method of Intermediate Compound 1-1, except that 2-bromo dibenzothiophene (15.0 g, 57.0 mmol) was used instead of 4-bromo dibenzothiophene.

### Preparation Example B-2: Synthesis of Intermediate Compound 2-2

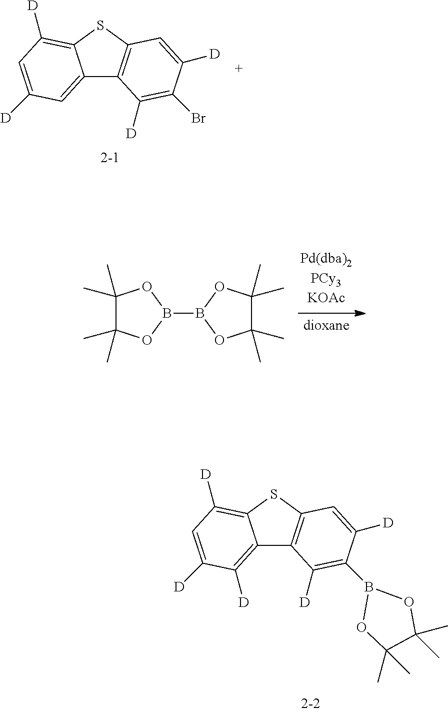

Compound 2-2 (11.6 g, yield: 84%; MS:[M+H]⁺=315) was prepared in the same manner as in the preparation method of Intermediate Compound 1-2, except that Compound 2-1 (11.7 g, 43.8 mmol) was used instead of Compound 1-1.

### Preparation Example C-1: Synthesis of Intermediate Compound 3-2

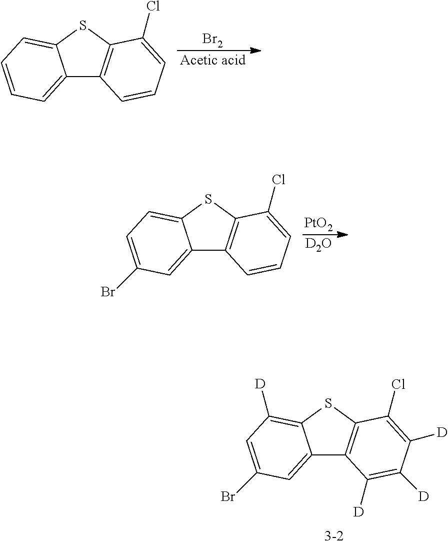

### Step 1) Preparation of Compound 3-1

Under a nitrogen atmosphere, 4-chloro dibenzothiophene (10 g, 0.05 mol) and 30 mL of acetic acid were placed in a 1000 mL round bottom flask, and bromine (7.3 g, 0.05 mol) was slowly added to the mixture at low temperature using a dropping funnel, and then stirred at room temperature for 15 hours. Then, the solid obtained by filtration was dissolved in tetrahydrofuran, washed with water and sodium thiosulfate solution, and the organic layer was separated and recrystallized from ethanol to obtain Intermediate Compound 3-1. (8.5 g, yield: 62%, MS:[M+H]⁺=296).

### Step 2) Preparation of Compound 3-2

Compound 3-2 (7.0 g, yield: 81%; MS:[M+H]⁺=301) was prepared in the same manner as in the preparation method of Intermediate Compound 1-1, except that Intermediate Compound 3-1 (8.5 g, 28.5 mmol) was used instead of 4-bromo dibenzothiophene.

### Preparation Example C-2: Synthesis of Intermediate Compound 3-4

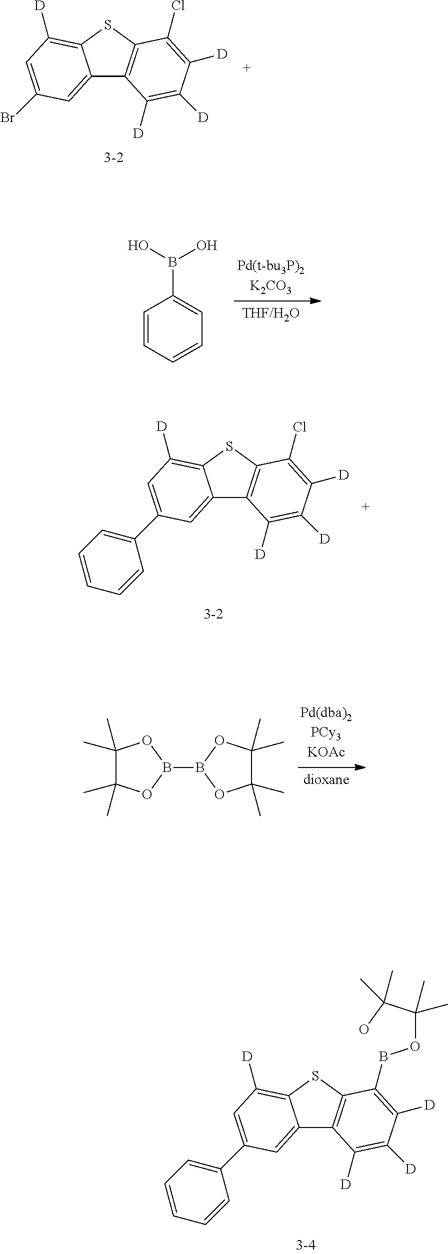

### Step 1) Preparation of Compound 3-3

Compound 3-2 (7 g, 23.2 mmol) and phenylboronic acid (5.5 g, 23.2 mmol) were added to 175 mL of tetrahydrofuran under a nitrogen atmosphere, and the mixture was stirred and refluxed. Then, potassium carbonate (9.6 g, 69.6 mmol) was dissolved in 10 mL of water, added thereto, sufficiently stirred, and then bis(tri-butylphosphine)palladium (0.4 g, 0.7 mmol) was added. After the reaction for 7 hours, the reaction mixture was cooled to room temperature and the resulting solid was filtered. The solid was added to and dissolved in 347 mL of tetrahydrofuran, washed twice with water, and the organic layer was separated. Anhydrous magnesium sulfate was added thereto, stirred, filtered, and the filtrate was distilled under reduced pressure. The concentrated compound was recrystallized from tetrahydrofuran and ethyl acetate to prepare a white solid compound 3-3 (5.4 g, 78%, MS: [M+H]⁺=299.8).

### Step 2) Preparation of Compound 3-4

Compound 3-4 (6.3 g, yield: 90%; MS:[M+H]⁺=391) was prepared in the same manner as in the preparation method of Compound 1-2, except that Compound 3-3 (5.4 g, 18.1 mmol) was used instead of Compound 1-1.

### Preparation Example D-1: Synthesis of Intermediate Compound 4-1

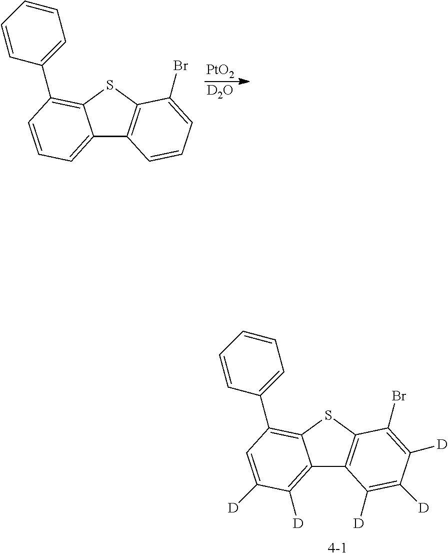

Compound 4-1 (8.3 g, yield: 82%; MS: [M+H]⁺=344) was prepared in the same manner as in the preparation method of Intermediate Compound 1-1, except that 4-bromo-6-phenyldibenzothiophene (10 g, 29.5 mmol) was used instead of 4-bromo dibenzothiophene, and the results of analyzing the ¹H NMR spectrum of the prepared Compound 4-1 were as follows.

¹H NMR: 7.46 (1H, tdd, J=7.6, 2.5, 1.2 Hz), 7.54 (2H, dddd, J=8.0, 7.6, 1.6, 0.5 Hz), 7.75-7.98 (0.9H, 7.82 (dd, J=7.9, 2.5 Hz), 7.87 (2H, dddd, J=8.0, 2.3, 1.8, 0.5 Hz)

Meanwhile, in order to confirm the presence or absence of deuterium substitution of Compound 4-1 prepared in Preparation Example D-1, the ¹H NMR spectrum of 4-bromo-6-phenyldibenzothiophene, which is the starting material of Preparation Example D-1, was further analyzed, and the results are as follows.

¹H NMR: b 7.33-7.70 (1H, 7.40 (dd, J=8.2, 1.9 Hz), 7.46 (1H, tdd, J=7.6, 2.5, 1.2 Hz), 7.50 (1H, dd, J=8.2, 7.2 Hz), 7.54 (2H, dddd, J=8.0, 7.6, 1.6, 0.5 Hz), 7.64 (1H, t, J=7.9 Hz)), 7.75-7.98 (1H, 7.82 (dd, J=7.9, 2.5 Hz), 7.87 (2H, dddd, J=8.0, 2.3, 1.8, 0.5 Hz), 7.92 (1H, ddd, J=8.0, 2.5, 0.4 Hz)), 8.14 (1H, ddd, J=7.2, 1.9, 0.4 Hz).

Comparing this with the ¹H NMR spectrum of Compound 4-1, it can be seen that Compound 4-1 in which deuterium was substituted at a specific position was prepared. Furthermore, the hydrogen peak at the Y₇ position in Compound 4-1 corresponding to the Y₇ position of Chemical Formula 1 appears at 7.75-7.98 ppm, but comparing the peak values of 4-bromo-6-phenyldibenzothiophene and Compound 4-1 at 7.75-7.98 ppm, it can be seen that the deuterium substitution rate at the Y₇ position is 10%. Considering that 10% or less of deuterium substitution at a specific position is an unintended substitution during manufacturing, it can be seen that deuterium is not substituted at the Y₇ position of Compound 4-1.

### Preparation Example D-2: Synthesis of Intermediate Compound 4-2

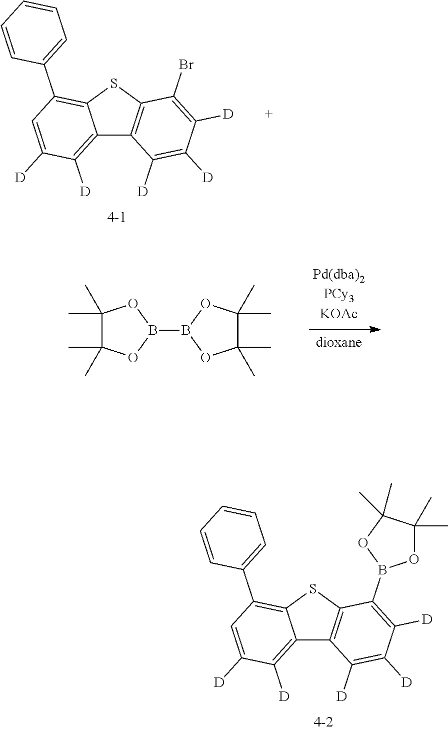

Compound 4-2 (7.7 g, yield: 82%; MS: [M+H]⁺=392) was prepared in the same manner as in the preparation method of Intermediate Compound 1-2, except that Compound 4-1 (8.3 g, 24.1 mmol) was used instead of Compound 1-1.

### Preparation Example 1: Synthesis of Compound 1

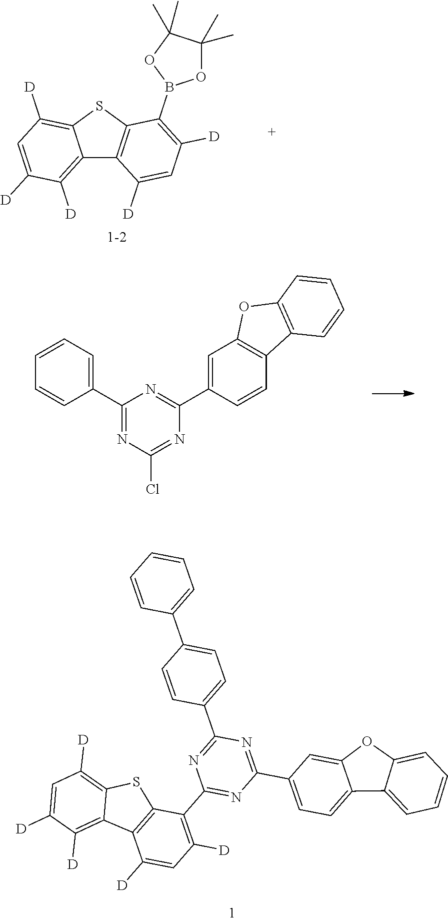 [SMILES: [2H]c1cc([2H])c2c(sc3c([2H])cc([2H])c([2H])c32)c1B1OC(C)(C)C(C)(C)O1 ; Clc1nc(-c2ccccc2)nc(-c2ccc3c(c2)oc2ccccc23)n1 ; [2H]c1cc([2H])c2c(sc3c([2H])cc([2H])c([2H])c32)c1-c1nc(-c2ccc(-c3ccccc3)cc2)nc(-c2ccc3c(c2)oc2ccccc23)n1]

Compound 1-2 (4 g, 12.7 mmol) and 2-chloro-4-(dibenzofuran-3-yl)-6-phenyl-1,3,5-triazine (4.5 g, 12.7 mmol) were added to 100 mL of tetrahydrofuran under a nitrogen atmosphere, and the mixture was stirred and refluxed. Then, potassium carbonate (5.3 g, 38.1 mmol) was dissolved in 5 mL of water, added thereto, sufficiently stirred, and then bis(tri-tertiary-butylphosphine)palladium (0.2 g, 0.4 mmol) was added. After the reaction for 7 hours, the reaction mixture was cooled to room temperature, and then the resulting solid was filtered. The solid was added to and dissolved in 521 mL of tetrahydrofuran, and washed twice with water. The organic layer was then separated, anhydrous magnesium sulfate was added thereto, stirred, then filtered, and the filtrate was distilled under reduced pressure. The concentrated compound was recrystallized from dichlorobenzene and ethyl acetate to prepare Compound 1 as a solid (5.7 g, 76%, MS: [M+H]⁺=587.7).

### Preparation Example 2: Preparation of Compound 2

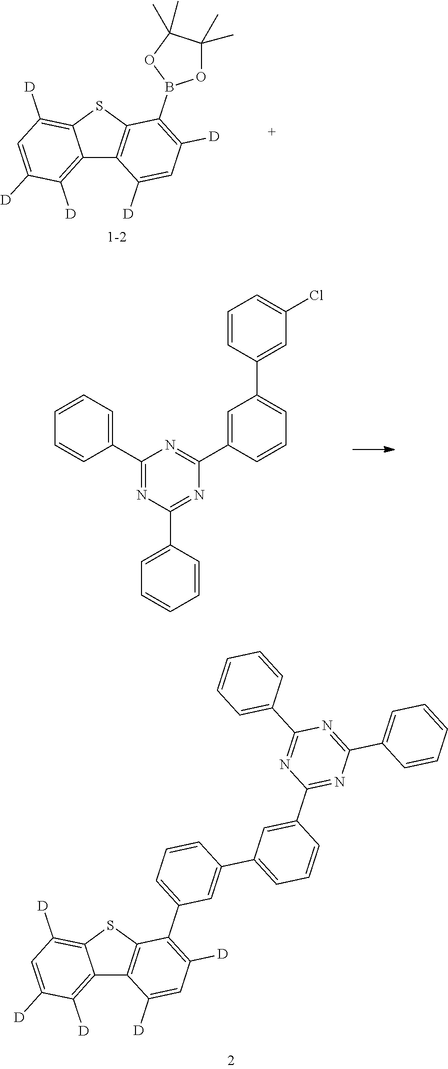 [SMILES: [2H]c1cc([2H])c2c(sc3c([2H])cc([2H])c([2H])c32)c1B1OC(C)(C)C(C)(C)O1 ; Clc1cccc(-c2cccc(-c3nc(-c4ccccc4)nc(-c4ccccc4)n3)c2)c1 ; [2H]c1cc([2H])c2c(sc3c([2H])cc([2H])c([2H])c32)c1-c1cccc(-c2cccc(-c3nc(-c4ccccc4)nc(-c4ccccc4)n3)c2)c1]

Compound 1-2 (4 g, 12.7 mmol) and 2-(3′-chloro-[1,1′-biphenyl]-3-yl)-4,6-diphenyl-1,3,5-triazine (5.3 g, 12.7 mmol) were added to 80 mL of dioxane under a nitrogen atmosphere, and the mixture was stirred and refluxed. Then, potassium phosphate tribasic (8.1 g, 38.1 mmol) was dissolved in 8 mL of water, added thereto, sufficiently stirred, and then dibenzylideneacetonepalladium (0.2 g, 0.4 mmol) and tricyclohexylphosphine (0.2 g, 0.8 mmol) were added. After the reaction for 9 hours, the reaction mixture was cooled to room temperature, and then the resulting solid was filtered. The solid was added to and dissolved in 218 mL of dichlorobenzene, and washed twice with water. The organic layer was then separated, anhydrous magnesium sulfate was added thereto, stirred, then filtered, and the filtrate was distilled under reduced pressure. The concentrated compound was recrystallized from dichlorobenzene and ethyl acetate to prepare a solid Compound 2 (5.5 g, 75%, MS: [M+H]⁺=573.7)

### Preparation Example 3: Preparation of Compound 3

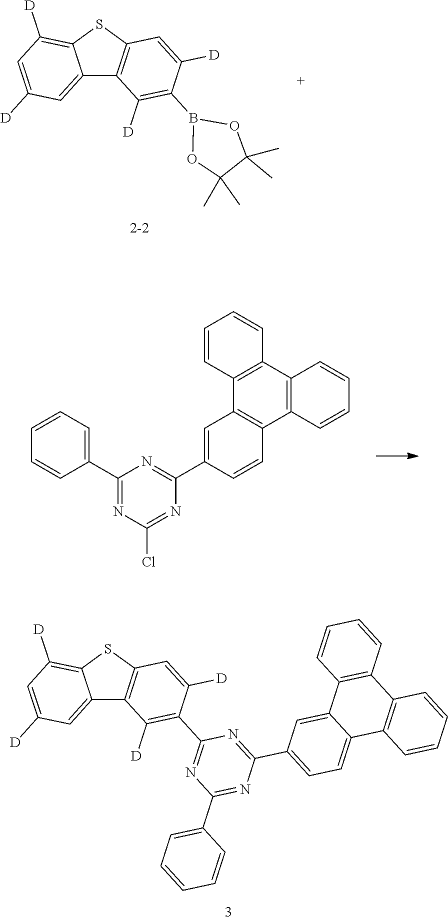 [SMILES: [2H]c1cc([2H])c2sc3cc([2H])c(B4OC(C)(C)C(C)(C)O4)c([2H])c3c2c1 ; Clc1nc(-c2ccccc2)nc(-c2ccc3c4ccccc4c4ccccc4c3c2)n1 ; [2H]c1cc([2H])c2sc3cc([2H])c(-c4nc(-c5ccccc5)nc(-c5ccc6c7ccccc7c7ccccc7c6c5)n4)c([2H])c3c2c1]

Compound 3 (5.4 g, yield: 75%, MS: [M+H]⁺=570) was prepared in the same manner as in the preparation method of Compound 1 of Preparation Example 1, except that Compound 2-2 and 2-chloro-4-phenyl-6-(triphenylen-2-yl)-1,3,5-triazine were used instead of Compound 1-2 and 2-chloro-4-(dibenzofuran-3-yl)-6-phenyl-1,3,5-triazine.

### Preparation Example 4: Preparation of Compound 4

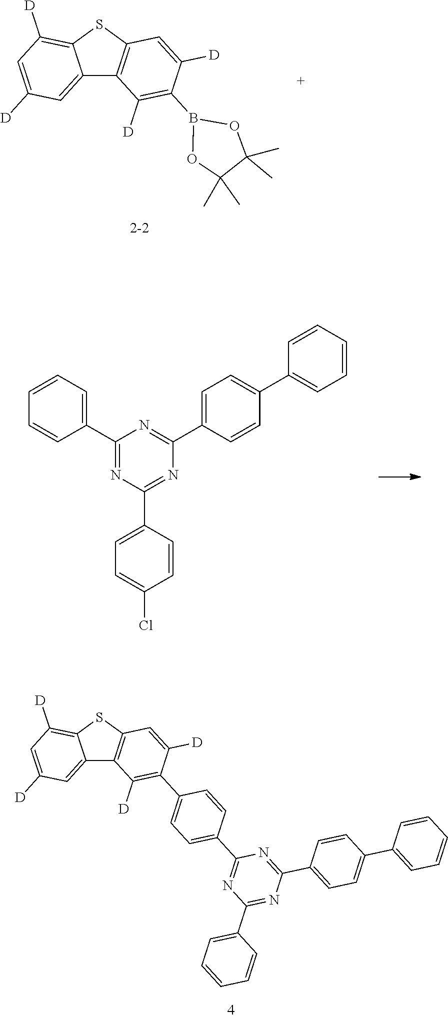 [SMILES: [2H]c1cc([2H])c2sc3cc([2H])c(B4OC(C)(C)C(C)(C)O4)c([2H])c3c2c1 ; Clc1ccc(-c2nc(-c3ccccc3)nc(-c3ccc(-c4ccccc4)cc3)n2)cc1 ; [2H]c1cc([2H])c2sc3cc([2H])c(-c4ccc(-c5nc(-c6ccccc6)nc(-c6ccc(-c7ccccc7)cc6)n5)cc4)c([2H])c3c2c1]

Compound 4 (5.8 g, yield: 80%, MS:[M+H]⁺=572) was prepared in the same manner as in the preparation method of Compound 2 of Preparation Example 2, except that Compound 2-2 and 2-([1,1′-biphenyl]-4-yl)-4-(4-chlorophenyl)-6-phenyl-1,3,5-triazine were used instead of Compound 1-2 and 2-(3′-chloro-[1,1′-biphenyl]-3-yl)-4,6-diphenyl-1,3,5-triazine.

### Preparation Example 5: Preparation of Compound 5

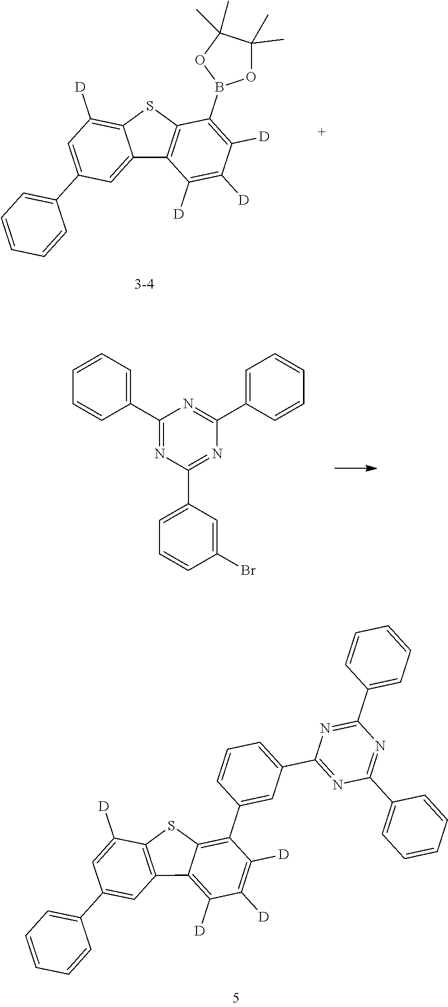 [SMILES: [2H]c1c([2H])c([2H])c2c(sc3c([2H])cc(-c4ccccc4)cc32)c1B1OC(C)(C)C(C)(C)O1 ; Brc1cccc(-c2nc(-c3ccccc3)nc(-c3ccccc3)n2)c1 ; [2H]c1c([2H])c([2H])c2c(sc3c([2H])cc(-c4ccccc4)cc32)c1-c1cccc(-c2nc(-c3ccccc3)nc(-c3ccccc3)n2)c1]

Compound 5 (5.0 g, yield: 86%, MS: [M+H]⁺=572) was prepared in the same manner as in the preparation method of Compound 1 of Preparation Example 1, except that Compound 3-4 and 2-(3-bromophenyl)-4,6-diphenyl-1,3,5-triazine were used instead of Compound 1-2 and 2-chloro-4-(dibenzofuran-3-yl)-6-phenyl-1,3,5-triazine.

### Preparation Example 6: Preparation of Compound 6

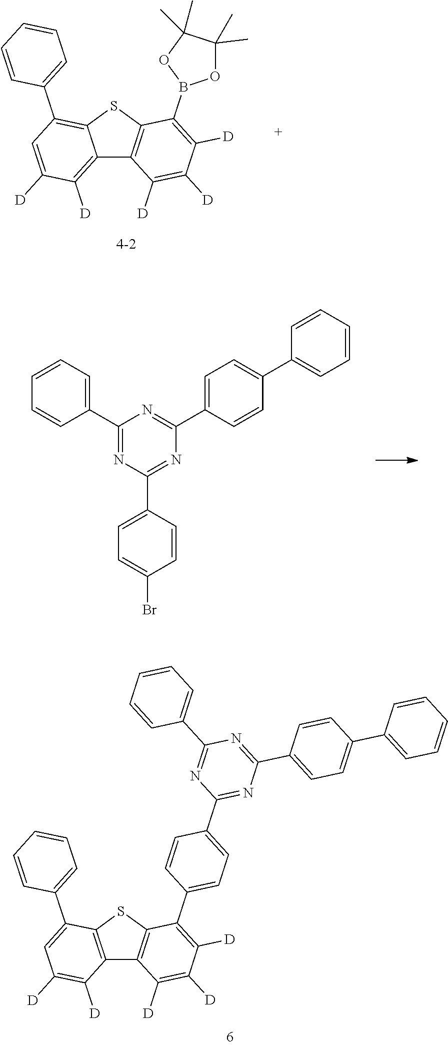 [SMILES: [2H]c1cc(-c2ccccc2)c2sc3c(B4OC(C)(C)C(C)(C)O4)c([2H])c([2H])c([2H])c3c2c1[2H] ; Brc1ccc(-c2nc(-c3ccccc3)nc(-c3ccc(-c4ccccc4)cc3)n2)cc1 ; [2H]c1cc(-c2ccccc2)c2sc3c(-c4ccc(-c5nc(-c6ccccc6)nc(-c6ccc(-c7ccccc7)cc6)n5)cc4)c([2H])c([2H])c([2H])c3c2c1[2H]]

Compound 6 (4.0 g, yield: 60%, MS:[M+H]⁺=649) was prepared in the same manner as in the preparation method of Compound 1 of Preparation Example 1, except that Compound 4-2 and 2-([1,1′-biphenyl]-4-yl)-4-(4-bromophenyl)-6-phenyl-1,3,5-triazine were used instead of Compound 1-2 and 2-chloro-4-(dibenzofuran-3-yl)-6-phenyl-1,3,5-triazine.

### Preparation Example 7: Preparation of Compound 7

### Step 1) Synthesis of Compound 2-1-a

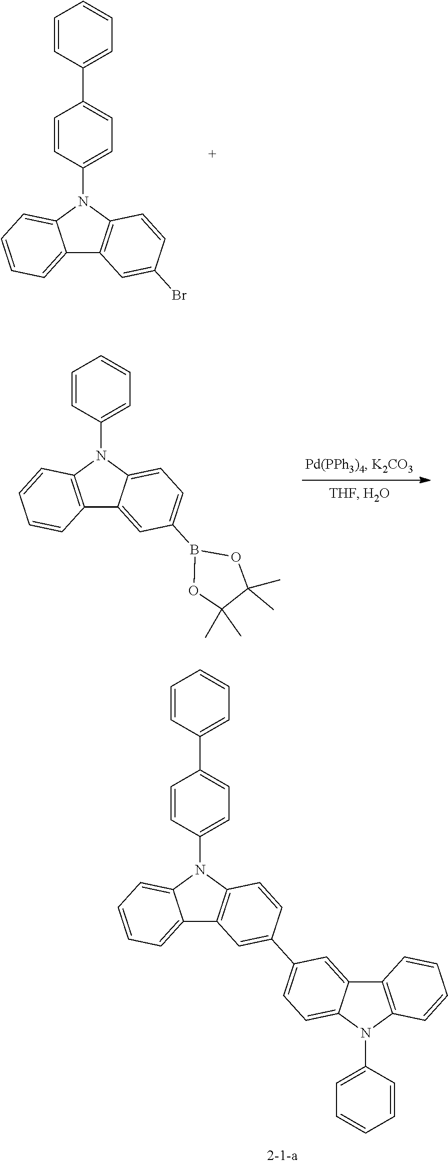

9-([1,1′-Biphenyl]-4-yl)-3-bromo-9H-carbazole (15.0 g, 37.7 mmol) and 9-phenyl-3-(4,4,5,5-tetramethyl-1,3,2-dioxabororan-2-yl)-9H-carbazole (15.3 g, 41.4 mmol) were added to 300 mL of THE under a nitrogen atmosphere, and the mixture was stirred and refluxed. Then, potassium carbonate (20.8 g, 150.6 mmol) was dissolved in 62 ml of water, added thereto, sufficiently stirred, and then tetrakis(triphenylphosphine)palladium(0) (1.3 g, 1.1 mmol) was added. After the reaction for 9 hours, the reaction mixture was cooled to room temperature, the organic layer and the aqueous layer were separated, and the organic layer was distilled. This was dissolved again in chloroform and washed twice with water. The organic layer was then separated, anhydrous magnesium sulfate was added thereto, stirred, then filtered, and the filtrate was distilled under reduced pressure. The concentrated compound was purified by a silica gel column chromatography to prepare 13.5 g of Compound 2-1-a. (yield: 64%, MS: [M+H]⁺=562)

### Step 2) Synthesis of Compound 7

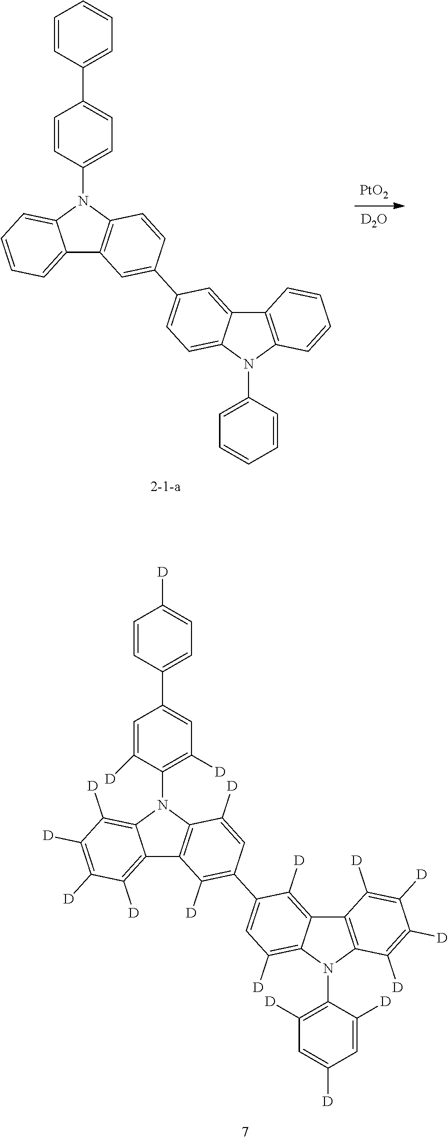 [SMILES: c1ccc(-c2ccc(-n3c4ccccc4c4cc(-c5ccc6c(c5)c5ccccc5n6-c5ccccc5)ccc43)cc2)cc1 ; "PtO2" ; "D2O" ; [2H]c1ccc(-c2cc([2H])c(-n3c4c([2H])cc(-c5cc([2H])c6c(c5[2H])c5c([2H])c([2H])c([2H])c([2H])c5n6-c5c([2H])cc([2H])cc5[2H])c([2H])c4c4c([2H])c([2H])c([2H])c([2H])c43)c([2H])c2)cc1]

Compound 2-1-a (10.0 g, 17.8 mmol), PtO₂ (1.2 g, 5.4 mmol), and D₂O (89 mL) were placed in a shaker tube, and then the tube was sealed and heated at 250° C. and 600 psi for 12 hours. When the reaction was completed, chloroform was added thereto, and the reaction solution was transferred to a separatory funnel, and extracted. The extract was dried over anhydrous magnesium sulfate and concentrated, and then the sample was purified by silica gel column chromatography, and then subjected to sublimation purification to prepare Compound 7 (yield: 38%, MS: [M+H]⁺=580)

### Preparation Example 8: Synthesis of Compound 8

### Step 1) Synthesis of Compound 2-2-a

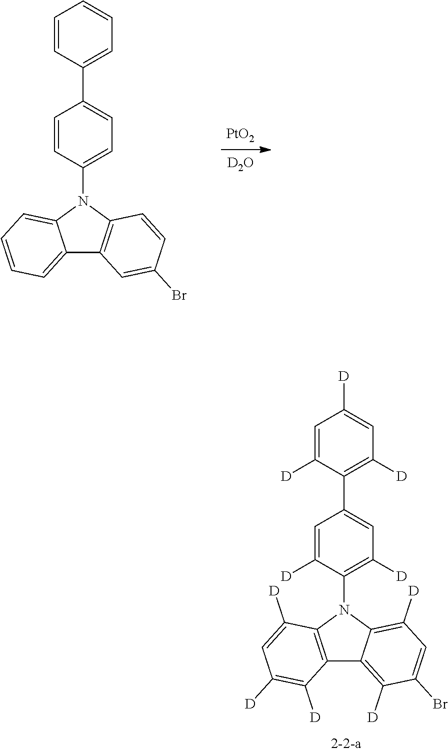 [SMILES: Brc1ccc2c(c1)c1ccccc1n2-c1ccc(-c2ccccc2)cc1 ; "PtO2" ; "D2O" ; [2H]c1cc([2H])c(-c2cc([2H])c(-n3c4c([2H])cc([2H])c([2H])c4c4c([2H])c(Br)cc([2H])c43)c([2H])c2)c([2H])c1]

9-([1,1′-Biphenyl]-4-yl)-3-bromo-9H-carbazole (10 g, 25.1 mmol), PtO₂ (1.7 g, 7.5 mmol), and D₂O (126 mL) were placed in a shaker tube, and then the tube was sealed and heated at 250° C. and 600 psi for 12 hours. When the reaction was completed, chloroform was added thereto, and the reaction solution was transferred to a separatory funnel, and extracted. The extract was dried over anhydrous magnesium sulfate and concentrated, and then the sample was purified by silica gel column chromatography to prepare 7.9 g of Compound 2-2-a. (yield: 77%, MS: [M+H]⁺=409).

### Step 2) Synthesis of Compound 2-2-b

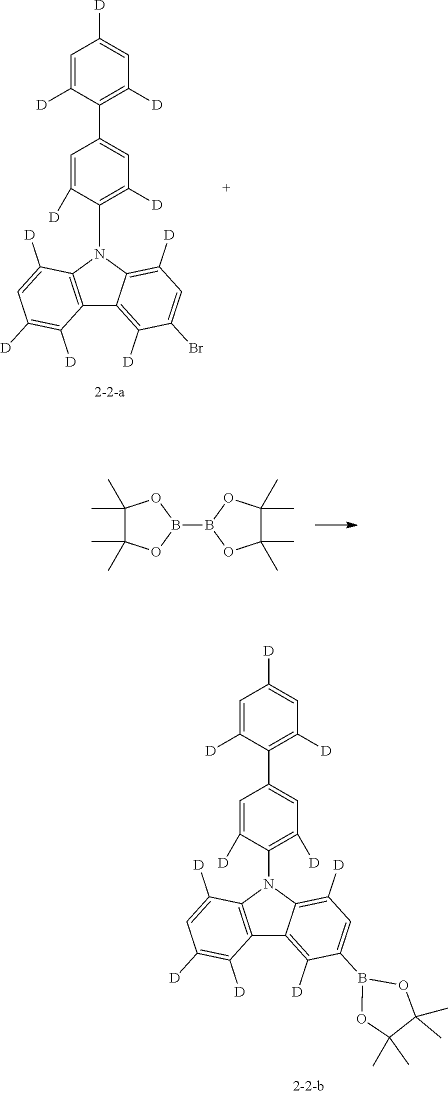

2-2-a (11 g, 26.9 mmol) and bis(pinacolato)diboron (8.2 g, 32.3 mmol) were added to 220 mL of Diox under a nitrogen atmosphere, and the mixture was stirred and refluxed. Then, potassium acetate (7.8 g, 80.8 mmol) was added thereto, sufficiently stirred, and then palladiumdibenzylideneacetonepalladium (0.5 g, 0.8 mmol) and tricyclohexylphosphine (0.5 g, 1.6 mmol) were added. After the reaction for 6 hours, the reaction mixture was cooled to room temperature, and then the resulting solid was filtered. The solid was added to and dissolved in 368 mL of chloroform, and washed twice with water. The organic layer was then separated, anhydrous magnesium sulfate was added thereto, stirred, then filtered, and the filtrate was distilled under reduced pressure. The concentrated compound was recrystallized from dichlorobenzene and ethanol to prepare Compound 2-2-b as a white solid (9.7 g, 79%, MS: [M+H]⁺=456.4).

### Step 3) Synthesis of Compound 8

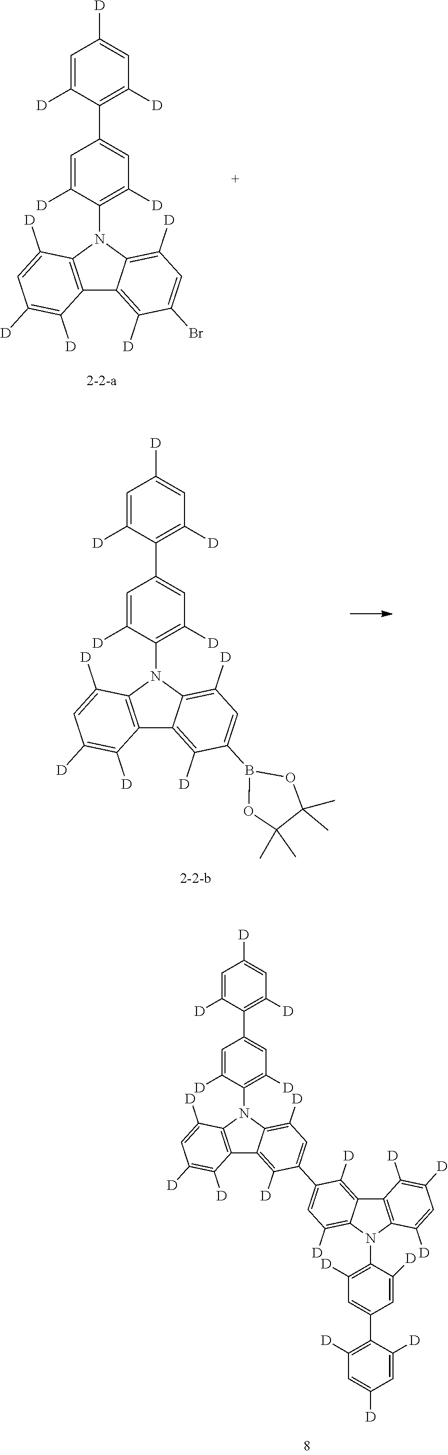 [SMILES: [2H]c1cc([2H])c(-c2cc([2H])c(-n3c4c([2H])cc([2H])c([2H])c4c4c([2H])c(Br)cc([2H])c43)c([2H])c2)c([2H])c1 ; [2H]c1cc([2H])c(-c2cc([2H])c(-n3c4c([2H])cc([2H])c([2H])c4c4c([2H])c(B5OC(C)(C)C(C)(C)O5)cc([2H])c43)c([2H])c2)c([2H])c1 ; [2H]c1cc([2H])c(-c2cc([2H])c(-n3c4c([2H])cc([2H])c([2H])c4c4c([2H])c(-c5cc([2H])c6c(c5[2H])c5c([2H])c([2H])cc([2H])c5n6-c5c([2H])cc(-c6c([2H])cc([2H])cc6[2H])cc5[2H])cc([2H])c43)c([2H])c2)c([2H])c1]

Compound 2-2-a (10 g, 24.5 mmol) and Compound 2-2-b (11.2 g, 24.5 mmol) were added to 250 mL of tetrahydrofuran under a nitrogen atmosphere, and the mixture was stirred and refluxed. Then, potassium acetate (10.2 g, 73.5 mmol) was dissolved in 10 mL of water, added thereto, sufficiently stirred, and then bis(tri-butylphosphine)palladium (0.4 g, 0.7 mmol) was added. After the reaction for 7 hours, the reaction mixture was cooled to room temperature, and then the resulting solid was filtered. The solid was added to and dissolved in 1126 mL of tetrahydrofuran, and washed twice with water. The organic layer was then separated, anhydrous magnesium sulfate was added thereto, stirred, then filtered, and the filtrate was distilled under reduced pressure. The concentrated compound was recrystallized from tetrahydrofuran and ethyl acetate to prepare Compound 8 as a white solid (12.9 g, 80%, MS: [M+H]⁺=657.9).

### Preparation Example 9: Synthesis of Compound 9

### Step 1) Synthesis of Compound 2-4-a

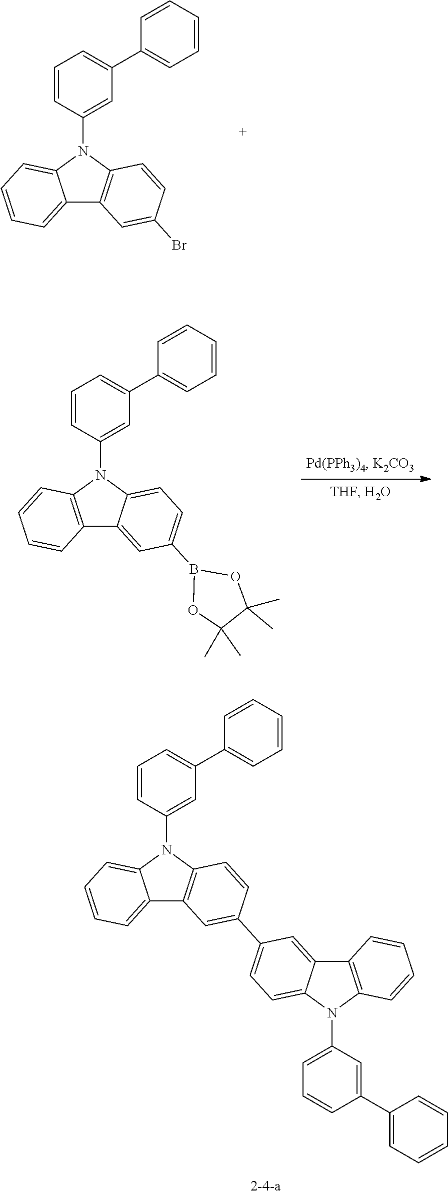

Compound 2-4-a (MS: [M+H]⁺=637) was synthesized in the same manner as in Synthesis Example 2-1, except that 9-([1,1′-biphenyl]-3-yl)-3-bromo-9H-carbazole and 9-([1,1′-biphenyl]-3-yl)-3-(4,4,5,5-tetramethyl-1,3,2-dioxabororan-2-yl)-9H-carbazole were used instead of 9-([1,1′-biphenyl]-4-yl)-3-bromo-9H-carbazole and 9-phenyl-3-(4,4,5,5-tetramethyl-1,3,2-dioxabororan-2-yl)-9H-carbazole.

### Step 2) Synthesis of Compound 9

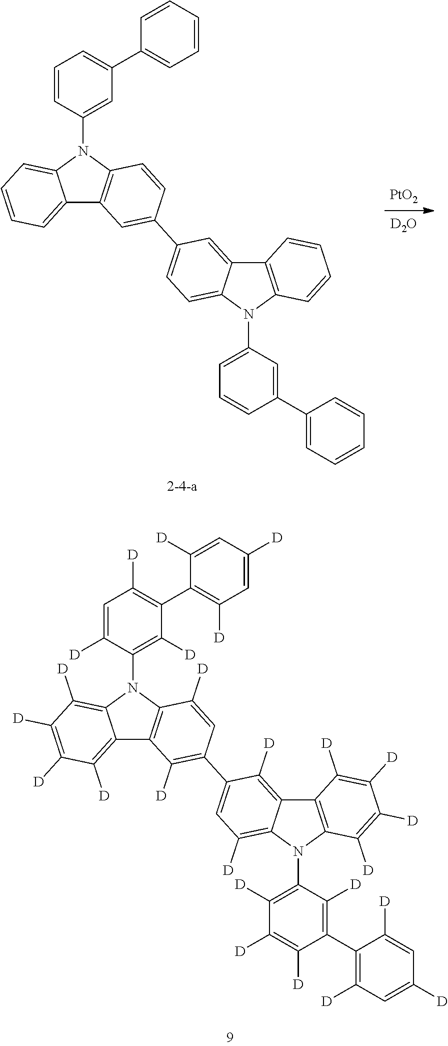 [SMILES: c1ccc(-c2cccc(-n3c4ccccc4c4cc(-c5ccc6c(c5)c5ccccc5n6-c5cccc(-c6ccccc6)c5)ccc43)c2)cc1 ; "PtO2" ; "D2O" ; [2H]c1cc([2H])c(-c2c([2H])cc([2H])c(-n3c4c([2H])cc(-c5cc([2H])c6c(c5[2H])c5c([2H])c([2H])c([2H])c([2H])c5n6-c5c([2H])c([2H])c([2H])c(-c6c([2H])cc([2H])cc6[2H])c5[2H])c([2H])c4c4c([2H])c([2H])c([2H])c([2H])c43)c2[2H])c([2H])c1]

Compound 9 (MS: [M+H]⁺=662) was synthesized in the same manner as in Preparation Example 7 (step 2), except that Compound 2-4-a was used instead of Compound 2-1-a.

### Experimental Example 1: Confirmation of Deuterium Substitution Rate

The deuterium substitution rate of the compound prepared in Preparation Example was calculated by determining the number of substituted deuterium in the compound through MALDI-TOF MS (Matrix-Assisted Laser Desorption/lonization Time-of-Flight Mass Spectrometer) analysis, and then calculating the ratio of the number of substituted deuterium to the total number of hydrogen atoms that can exist in the compound as a percentage, and is shown in Table 1 below.

TABLE 1

| | Number of | Deuterium |
|---|---|---|
| | substituted | substitution rate |
| Compound | deuterium | (%) |
| Compound 1 | 5 | 21.74 |
| Compound 2 | 5 | 20.00 |
| Compound 3 | 4 | 17.39 |
| Compound 4 | 4 | 16.00 |
| Compound 5 | 4 | 16.00 |
| Compound 6 | 4 | 13.79 |
| Compound 7 | 18 | 64.29 |
| Compound 8 | 20 | 62.50 |
| Compound 9 | 25 | 78.13 |

### EXAMPLES

### Example 1

A glass substrate on which ITO (indium tin oxide) was coated as a thin film to a thickness of 1400 Å was put into distilled water in which a detergent was dissolved, and ultrasonically cleaned. A product manufactured by Fischer Co. was used as the detergent, and as the distilled water, distilled water filtered twice using a filter manufactured by Millipore Co. was used. After the ITO was cleaned for 30 minutes, ultrasonic cleaning was repeated twice using distilled water for 10 minutes. After the cleaning with distilled water was completed, the substrate was ultrasonically cleaned with solvents of isopropyl alcohol, acetone, and methanol, dried, and then transferred to a plasma cleaner. In addition, the substrate was cleaned for 5 minutes using oxygen plasma and then transferred to a vacuum depositor.

On the ITO transparent electrode thus prepared, 95 wt. % of the following compound HT-A and 5 wt. % of the following compound PD were thermally vacuum-deposited to a thickness of 100 Å to form a hole injection layer, and then only the following compound HT-A was deposited to a thickness of 1150 Å to form a hole transport layer. The following compound HT-B was thermally vacuum-deposited thereon to a thickness of 450 Å to form an electron blocking layer.

Then, the compound 7 and compound 4 prepared in the previous Preparation Examples as a host material, and the following compound GD as a dopant material were co-deposited at a weight ratio of 65.8:28.2:6 on the electron blocking layer to form a light emitting layer with a thickness of 350 Å.

Then, the following compound ET-1 was vacuum-deposited to a thickness of 50 Å as a hole blocking layer. Then, the following compounds ET-B and Li were thermally vacuum-deposited at a weight ratio of 1:1 to a thickness of 300 Å as the electron transport layer, and then Yb was vacuum-deposited to a thickness of 10 Å as an electron injection layer.

Magnesium and silver were deposited at a weight ratio of 1:4 to a thickness of 150 Å on the electron injection layer to form a cathode, thereby completing the manufacture of an organic light emitting device.

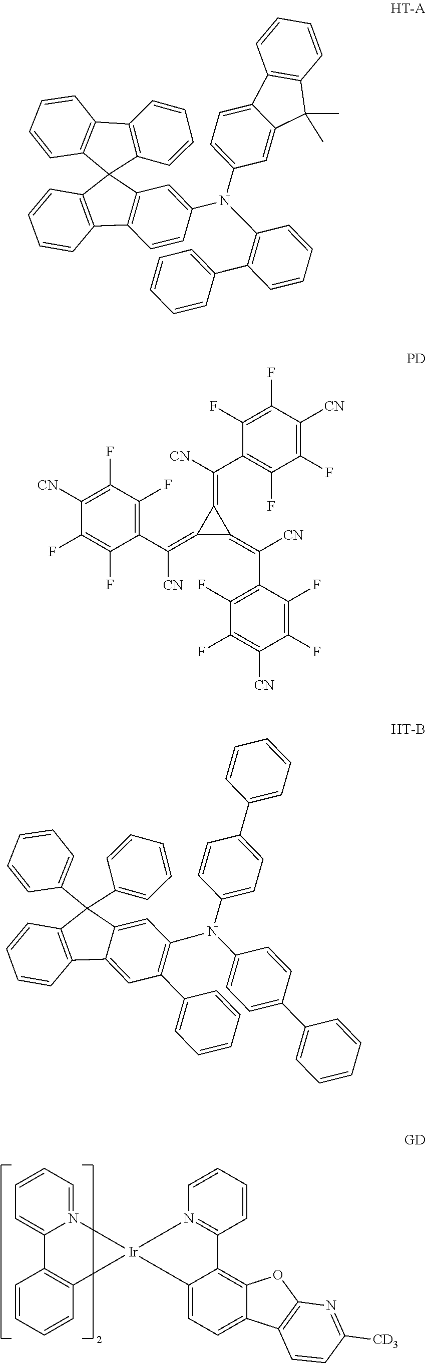

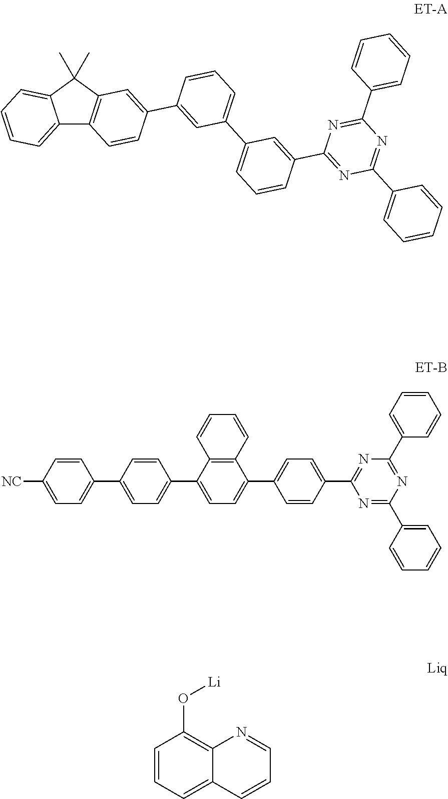

In the above-mentioned processes, the vapor deposition rate of the organic material was maintained at 0.4·0.7 Å/sec, the deposition rate of magnesium and silver was maintained at 2 Å/see, and the degree of vacuum during the deposition was maintained at 2*10⁻⁷˜5*10⁻⁶ torr, thereby manufacturing an organic light emitting device.

### Examples 2 to 6

The organic light emitting devices of Examples 2 to 6 were respectively manufactured in the same manner as in Example 1, except that the compounds listed in Table 1 were used instead of Compound 7 and Compound 4 as cohosts when forming a light emitting layer.

At this time, the structures of the host materials used in Examples 1 to 6 are summarized as follows.

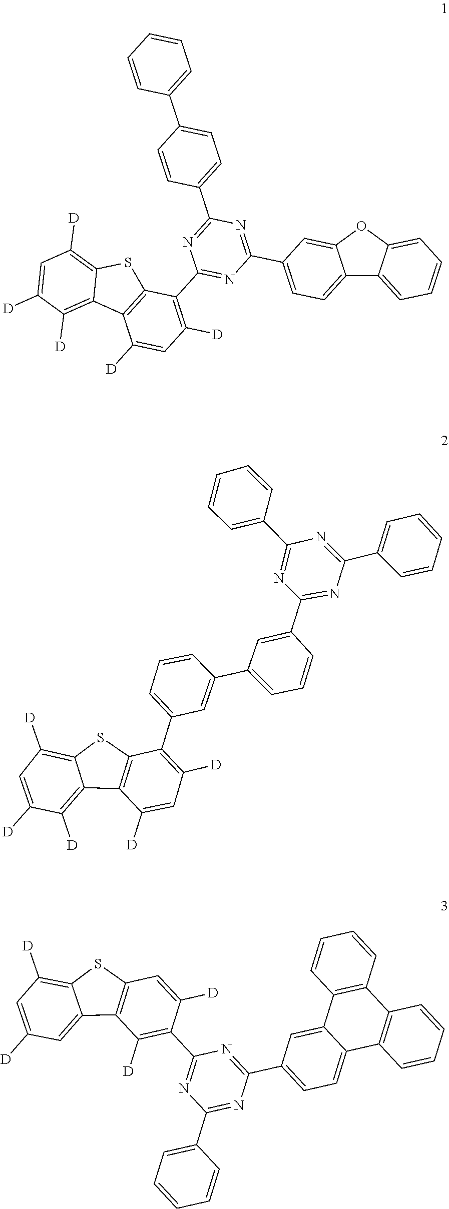 [SMILES: [2H]c1cc([2H])c2c(sc3c([2H])cc([2H])c([2H])c32)c1-c1nc(-c2ccc(-c3ccccc3)cc2)nc(-c2ccc3c(c2)oc2ccccc23)n1 ; [2H]c1cc([2H])c2c(sc3c([2H])cc([2H])c([2H])c32)c1-c1cccc(-c2cccc(-c3nc(-c4ccccc4)nc(-c4ccccc4)n3)c2)c1 ; [2H]c1cc([2H])c2sc3cc([2H])c(-c4nc(-c5ccccc5)nc(-c5ccc6c7ccccc7c7ccccc7c6c5)n4)c([2H])c3c2c1]

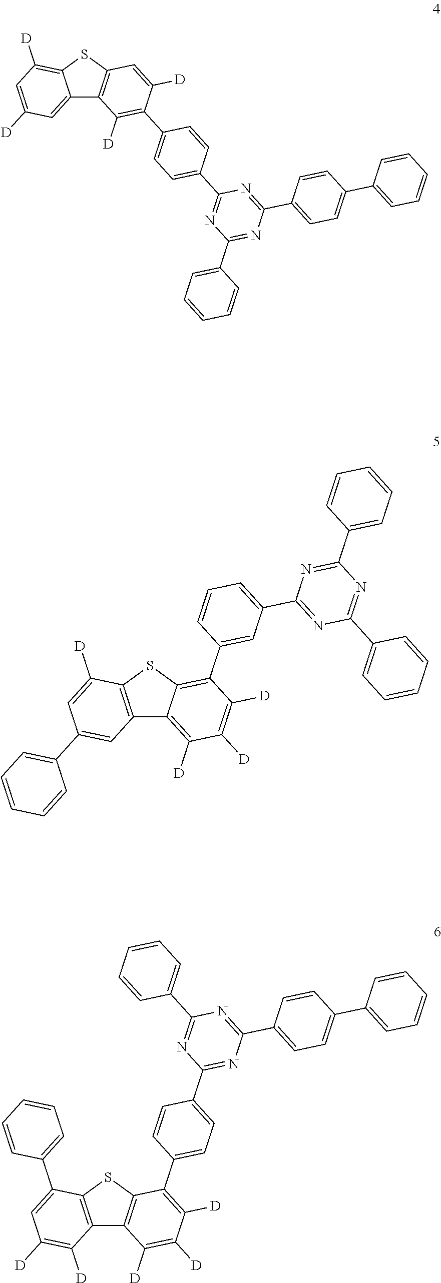

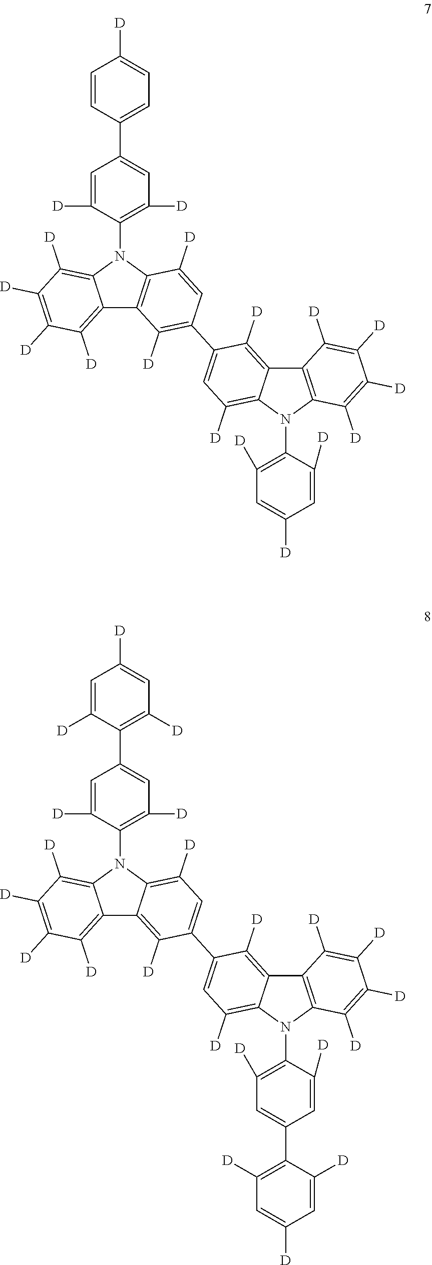 [SMILES: [2H]c1ccc(-c2cc([2H])c(-n3c4c([2H])cc(-c5cc([2H])c6c(c5[2H])c5c([2H])c([2H])c([2H])c([2H])c5n6-c5c([2H])cc([2H])cc5[2H])c([2H])c4c4c([2H])c([2H])c([2H])c([2H])c43)c([2H])c2)cc1 ; [2H]c1cc([2H])c(-c2cc([2H])c(-n3c4c([2H])cc(-c5cc([2H])c6c(c5[2H])c5c([2H])c([2H])c([2H])c([2H])c5n6-c5c([2H])cc(-c6c([2H])cc([2H])cc6[2H])cc5[2H])c([2H])c4c4c([2H])c([2H])c([2H])c([2H])c43)c([2H])c2)c([2H])c1]

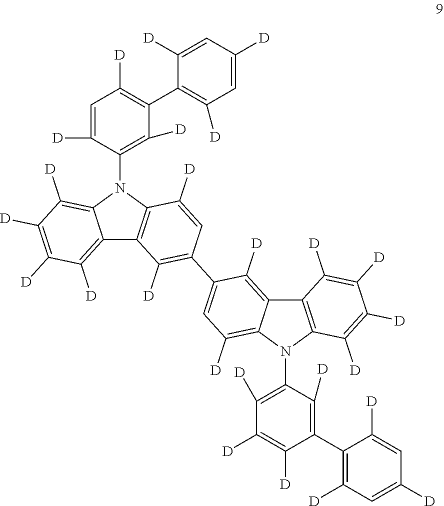 [SMILES: [2H]c1cc([2H])c(-c2c([2H])cc([2H])c(-n3c4c([2H])cc(-c5cc([2H])c6c(c5[2H])c5c([2H])c([2H])c([2H])c([2H])c5n6-c5c([2H])c([2H])c([2H])c(-c6c([2H])cc([2H])cc6[2H])c5[2H])c([2H])c4c4c([2H])c([2H])c([2H])c([2H])c43)c2[2H])c([2H])c1]

### Comparative Examples 1 to 9

The organic light emitting devices of Comparative Examples 1 to 9 were respectively manufactured in the same manner as in Preparation Example 1, except that the compounds listed in Table 1 were used instead of Compound 4 and Compound 7 as cohosts when forming a light emitting layer. The structures of H1 to H9 used here as comparative compounds are as follows.

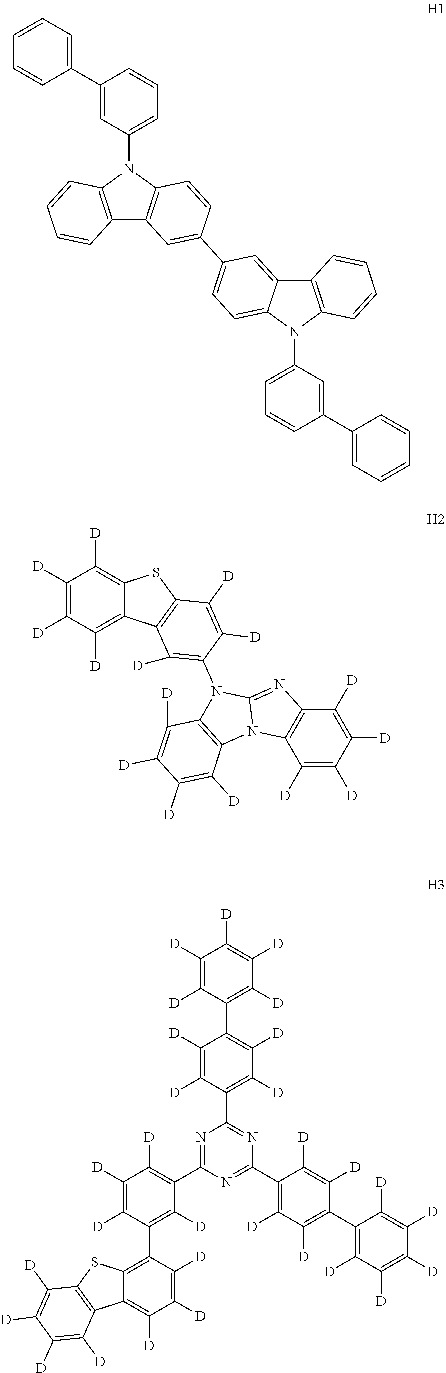 [SMILES: c1ccc(-c2cccc(-n3c4ccccc4c4cc(-c5ccc6c(c5)c5ccccc5n6-c5cccc(-c6ccccc6)c5)ccc43)c2)cc1 ; [2H]c1c([2H])c([2H])c2c(nc3n(-c4c([2H])c([2H])c5sc6c([2H])c([2H])c([2H])c([2H])c6c5c4[2H])c4c([2H])c([2H])c([2H])c([2H])c4n23)c1[2H] ; [2H]c1c([2H])c([2H])c(-c2c([2H])c([2H])c(-c3nc(-c4c([2H])c([2H])c(-c5c([2H])c([2H])c([2H])c([2H])c5[2H])c([2H])c4[2H])nc(-c4c([2H])c([2H])c([2H])c(-c5c([2H])c([2H])c([2H])c6c5sc5c([2H])c([2H])c([2H])c([2H])c56)c4[2H])n3)c([2H])c2[2H])c([2H])c1[2H]]

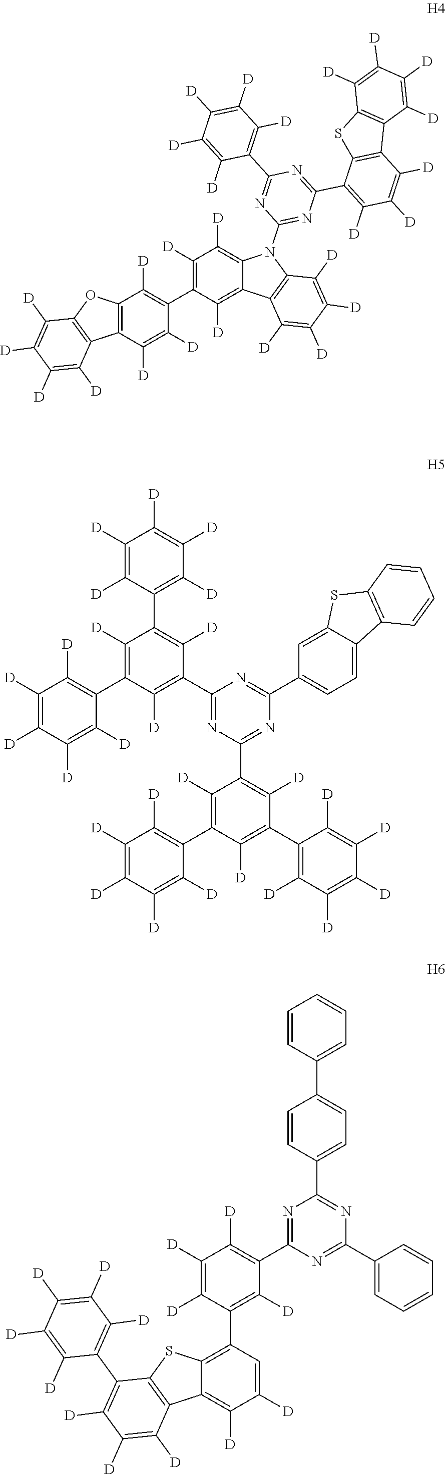

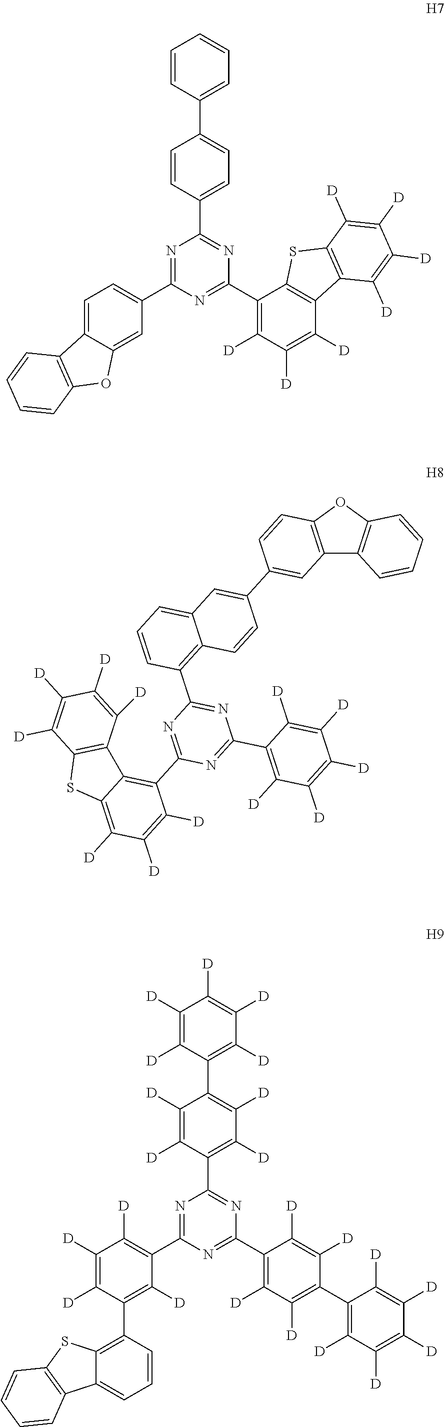 [SMILES: [2H]c1c([2H])c([2H])c2c(sc3c(-c4nc(-c5ccc(-c6ccccc6)cc5)nc(-c5ccc6c(c5)oc5ccccc56)n4)c([2H])c([2H])c([2H])c32)c1[2H] ; [2H]c1c([2H])c([2H])c(-c2nc(-c3cccc4cc(-c5ccc6oc7ccccc7c6c5)ccc34)nc(-c3c([2H])c([2H])c([2H])c4sc5c([2H])c([2H])c([2H])c([2H])c5c34)n2)c([2H])c1[2H] ; [2H]c1c([2H])c([2H])c(-c2c([2H])c([2H])c(-c3nc(-c4c([2H])c([2H])c(-c5c([2H])c([2H])c([2H])c([2H])c5[2H])c([2H])c4[2H])nc(-c4c([2H])c([2H])c([2H])c(-c5cccc6c5sc5ccccc56)c4[2H])n3)c([2H])c2[2H])c([2H])c1[2H]]

### Experimental Example 2: Manufacture of Organic Light Emitting Device

The driving voltage, efficiency and lifetime were measured by applying a current to the organic light emitting devices manufactured in the Examples 1 to 6 and Comparative Examples 1 top 6, and the results are shown in Table 1 below. T95 means the time required for the luminance to be reduced to 95% of the initial luminance.

TABLE 2

| | Host material of | | | Efficiency | Lifetime (h) |
|---|---|---|---|---|---|
| | light emitting layer | | Voltage (V) | (Cd/A) | (LT₉₅ at |
| | First host | Second host | (@10 mA/cm²) | (@10 mA/cm²) | 50 mA/cm²) |
| Example 1 | Compound 4 | Compound 7 | 4.3 | 63 | 153 |
| Example 2 | Compound 5 | Compound 7 | 4.2 | 75 | 162 |
| Example 3 | Compound 1 | Compound 8 | 4.2 | 71 | 156 |
| Example 4 | Compound 6 | Compound 8 | 4.2 | 73 | 160 |
| Example 5 | Compound 2 | Compound 9 | 4.2 | 70 | 155 |
| Example 6 | Compound 3 | Compound 9 | 4.3 | 67 | 151 |
| Comparative | Compound 2 | H1 | 4.2 | 69 | 95 |
| Example 1 | | | | | |
| Comparative | H2 | Compound 7 | 4.4 | 60 | 66 |
| Example 2 | | | | | |
| Comparative | H3 | Compound 7 | 4.5 | 57 | 112 |
| Example 3 | | | | | |
| Comparative | H4 | Compound 8 | 4.5 | 62 | 99 |
| Example 4 | | | | | |
| Comparative | H5 | Compound 8 | 4.3 | 66 | 100 |
| Example 5 | | | | | |
| Comparative | H6 | Compound 7 | 4.3 | 55 | 98 |
| Example 6 | | | | | |
| Comparative | H7 | Compound 7 | 4.4 | 61 | 95 |
| Example 7 | | | | | |
| Comparative | H8 | Compound 8 | 4.3 | 58 | 87 |
| Example 8 | | | | | |
| Comparative | H9 | Compound 8 | 4.5 | 60 | 93 |
| Example 9 | | | | | |

As shown in Table 2, it can be confirmed that in the case of the organic light emitting devices of Examples, which were manufactured by simultaneously using the first compound and the second compound according to the present disclosure as a host of the light emitting layer, they exhibited excellent performance in terms of voltage, efficiency, and lifetime as compared to the organic light emitting device of Comparative Examples.

Specifically, the organic light emitting devices of Examples were significantly improved in lifetime characteristics as compared to the organic light emitting device of Comparative Example 2 employing a comparative compound in which dibenzofuran was substituted with a substituent other than an N-containing 6-membered heterocycle, the organic light emitting device of Comparative Example 3 employing a comparative compound in which deuterium was substituted at all positions of dibenzofuran, the organic light emitting device of Comparative Example 4 employing a comparative compound having a substituent of an N-containing 6-membered heterocycle in which dibenzofuran is substituted with a carbazolyl group, and the organic light emitting device of Comparative Example 5 employing a comparative compound in which dibenzofuran is not substituted with deuterium. From this point, it can be seen that the first compound and the second compound had an appropriate charge balance between the hosts and contributed to stabilizing the excitons.

[Description of Symbols]

| | |
|---|---|
| 1: substrate | 2: anode |
| 3: light emitting layer | 4: cathode |
| 5: hole injection layer | 6: hole transport layer |
| 7: electron blocking layer | 8: hole blocking layer |
| 9: electron transport layer | 10: electron injection layer |

1. An organic light emitting device comprising:
an anode;
a cathode which is provided opposite to the anode; and
a light emitting layer which is interposed between the anode and the cathode,
wherein the light emitting layer includes a first compound represented by the following Chemical Formula 1, and a second compound represented by the following Chemical Formula 2: 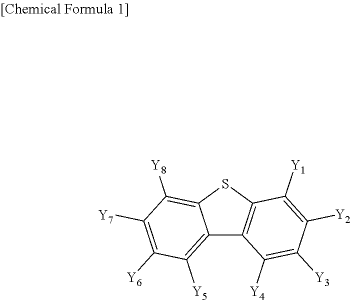
wherein, in Chemical Formula 1,
one of Y₁, Y₃, Y₆ and Y₈ is -(L)ₙ-A, wherein Y₁, Y₃, Y₆ and Y₈, which are not -(L)ₙ-A, are each independently hydrogen, deuterium, or a substituted or unsubstituted C₆₋₆₀ aryl, at least one of which is deuterium,
wherein L is a substituted or unsubstituted phenylene,
n is an integer from 0 to 3,
A is at least one N-containing 6-membered heteroaryl which is substituted or unsubstituted,
with the proviso that A is not substituted with carbazolyl or indolocarbazolyl, and
Y₂, Y₄, Y₈ and Y₇ are each independently hydrogen, deuterium, a substituted or unsubstituted C₆₋₆₀ aryl, wherein at least one of Y₂ and Y₇ is hydrogen,
with the proviso that when Y₁ is -(L)ₙ-A and Y₈ is phenyl substituted with deuterium, Y₂ is deuterium, 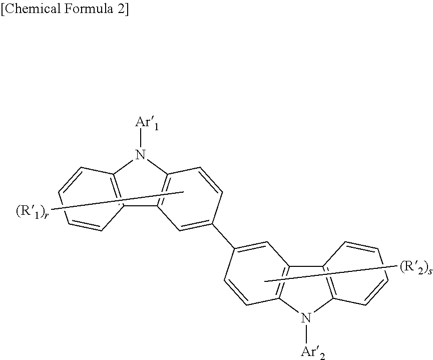
wherein, in Chemical Formula 2,
Ar′₁ and Ar′₂ are each independently a substituted or unsubstituted C₆₋₆₀ aryl; or a substituted or unsubstituted C₂₋₆₀ heteroaryl containing at least one heteroatom of N, O and S,
R′₁ and R′₂ are each independently deuterium; cyano; halogen; a substituted or unsubstituted C₁₋₆₀ alkyl; a substituted or unsubstituted C₆₋₆₀ aryl; or a substituted or unsubstituted C₂₋₆₀ heteroaryl containing at least one heteroatom of N, O and S, and r and s are each independently an integer from 0 to 7,
with the proviso that at least one of R′₁ and R′₂ is deuterium; or at least one of Ar′₁ and Ar′₂ is substituted with deuterium.

2. The organic light emitting device of claim 1, wherein:
Y₁ is -(L)ₙ-A, one of Y₃, Y₆ and Y₈ is deuterium, and the remainder are all hydrogen; or
Y₁ is -(L)ₙ-A, one of Y₃, Y₆ and Y₈ is deuterium, the other one is a substituted or unsubstituted C₆₋₆₀ aryl, and the remainder is hydrogen; or
Y₁ is -(L)ₙ-A, two of Y₃, Y₆ and Y₈ are deuterium, and the remainder is hydrogen; or
Y₁ is -(L)ₙ-A, two of Y₃, Y₆ and Y₈ are deuterium, and the remainder is a substituted or unsubstituted C₆₋₆₀ aryl; or
Y₁ is -(L)ₙ-A, and all of Y₃, Y₆ and Y₈ are deuterium; or
Y₃ is -(L)ₙ-A, one of Y₁, Y₆ and Y₈ is deuterium, and the remainder are all hydrogen; or
Y₃ is -(L)ₙ-A, one of Y₁, Y₆ and Y₈ is deuterium, the other one is a substituted or unsubstituted C₆₋₆₀ aryl, and the remainder is hydrogen; or
Y₃ is -(L)ₙ-A, two of Y₁, Y₆ and Y₈ are deuterium, and the remainder is hydrogen; or
Y₃ is -(L)ₙ-A, two of Y₁, Y₆ and Y₈ are deuterium, and the remainder is a substituted or unsubstituted C₆₋₆₀ aryl; or
Y₃ is -(L)ₙ-A, and all of Y₁, Y₆ and Y₈ are deuterium.

3. The organic light emitting device of claim 1, wherein:
Y₁, Y₃, Y₆ and Y₈, which are not -(L)ₙ-A and deuterium, are each independently hydrogen, phenyl, biphenylyl, phenanthryl, or triphenylenyl,
wherein the phenyl, biphenylyl, phenanthryl and triphenylenyl are unsubstituted or substituted with at least one deuterium.

4. The organic light emitting device of claim 1, wherein:
L is unsubstituted or substituted with 1 to 4 deuteriums.

5. The organic light emitting device of claim 1, wherein:
n is 0, 1, or 2.

6. The organic light emitting device of claim 1, wherein:
A is any one of substituents represented by the following Chemical Formulas 2a to 2j: 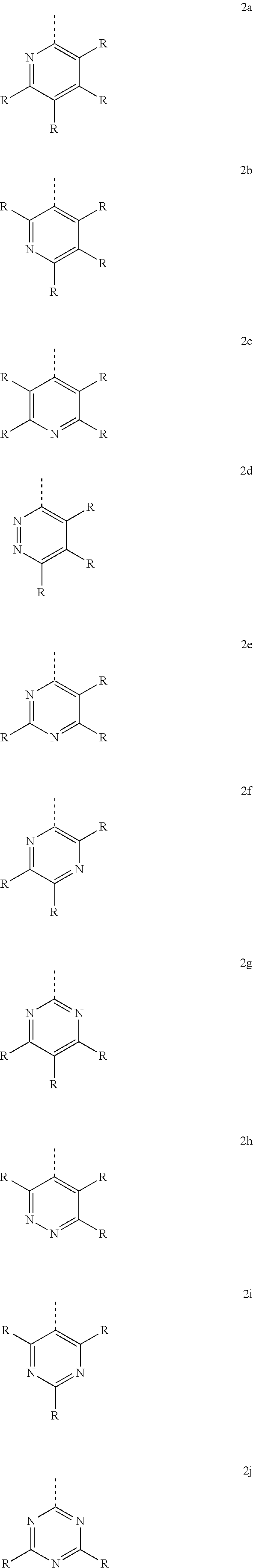
wherein, in Chemical Formulas 2a to 2j,
each R is independently hydrogen, deuterium, a substituted or unsubstituted C₆₋₂₀ aryl, or a substituted or unsubstituted C₂₋₂₀ heteroaryl containing O or S.

7. The organic light emitting device of claim 6, wherein:
A is represented by the Chemical Formula 2j,
wherein each R is independently phenyl, biphenylyl, terphenylyl, phenanthryl, triphenylenyl, dibenzofuranyl, or dibenzothiophenyl,
with the R being unsubstituted or substituted with at least one deuterium.

8. The organic light emitting device of claim 1, wherein:
Y₂ is hydrogen, and Y₇ is deuterium; or
Y₂ is deuterium, and Y₇ is hydrogen; or
both Y₂ and Y₇ are hydrogen.

9. The organic light emitting device of claim 1, wherein:
Y₄ and Y₈ are each independently hydrogen, deuterium, phenyl, biphenylyl, phenanthryl, or triphenylenyl,
wherein the phenyl, biphenylyl, phenanthryl and triphenylenyl are unsubstituted, or substituted with at least one deuterium.

10. The organic light emitting device of claim 9, wherein:
one of Y₄ and Y₈ is hydrogen or deuterium, and the other one is hydrogen, deuterium, phenyl, biphenylyl, phenanthryl, or triphenylenyl,
wherein the phenyl, biphenylyl, phenanthryl and triphenylenyl are unsubstituted, or substituted with at least one deuterium.

11. The organic light emitting device of claim 1, wherein:
three, four, or five of Y₁ to Y₈ are deuterium.

12. The organic light emitting device of claim 1, wherein:
all of Y₁ to Y₈ are not a substituted or unsubstituted C₆₋₆₀ aryl; or
one of Y₁ to Y₈ is a substituted or unsubstituted C₆₋₆₀ aryl.

13. The organic light emitting device of claim 1, wherein:
the first compound is represented by the following Chemical Formula 1-1 or 1-2: 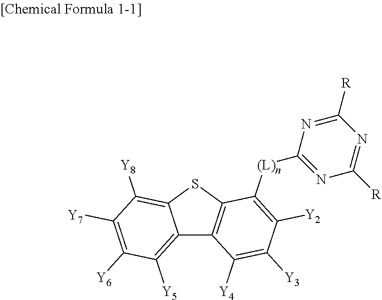
wherein, in Chemical Formula 1-1,
one, two or three of Y₃, Y₆ and Y₈ are deuterium, and the remainder, which is not deuterium, are each independently hydrogen or a substituted or unsubstituted C₆₋₆₀ aryl,
each R is independently hydrogen, deuterium, a substituted or unsubstituted C₆₋₂₀ aryl, or a substituted or unsubstituted C₂₋₂₀ heteroaryl containing O or S, and
Y₂, Y₄, Y₈ and Y₇, L and n are as defined in claim 1, 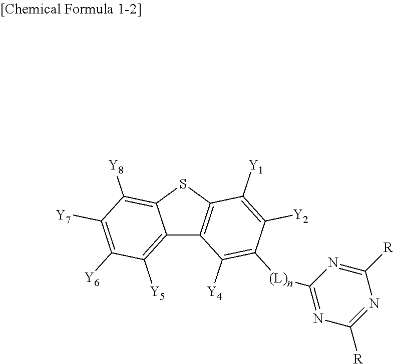
wherein, in Chemical Formula 1-2,
one, two or three of Y₁, Y₆ and Y₈ are deuterium, and the remainder, which is not deuterium, are each independently hydrogen or a substituted or unsubstituted C₆₋₆₀ aryl,
each R is independently hydrogen, deuterium, a substituted or unsubstituted C₆₋₂₀ aryl, or a substituted or unsubstituted C₂₋₂₀ heteroaryl containing O or S, and
Y₂, Y₄, Y₈ and Y₇, L and n are as defined in claim 1.

14. The organic light emitting device of claim 1, wherein:
the first compound is any one compound selected from among the following compounds:

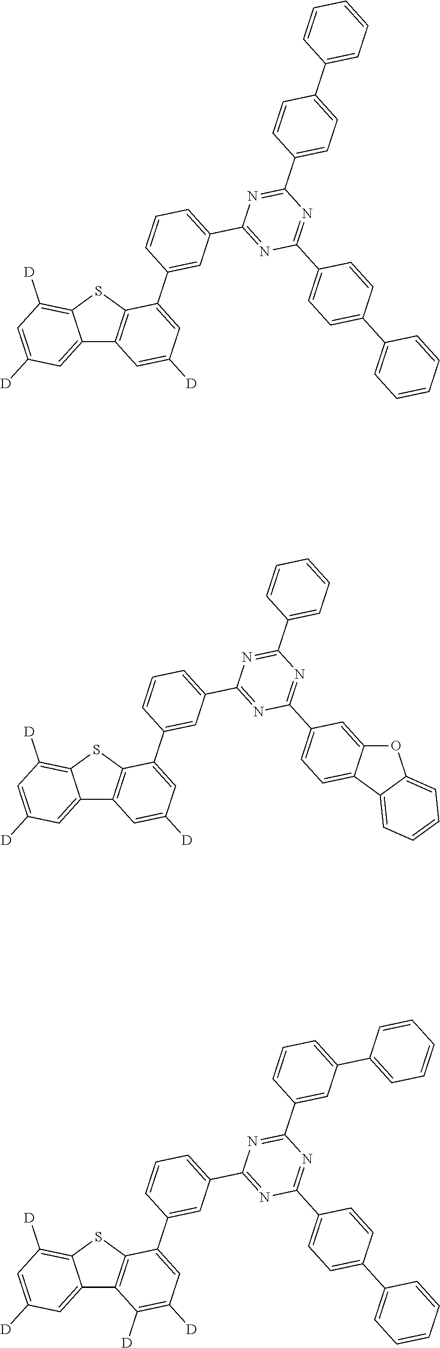 [SMILES: [2H]c1cc([2H])c2sc3c(-c4cccc(-c5nc(-c6ccc(-c7ccccc7)cc6)nc(-c6ccc(-c7ccccc7)cc6)n5)c4)cc([2H])cc3c2c1 ; [2H]c1cc([2H])c2sc3c(-c4cccc(-c5nc(-c6ccccc6)nc(-c6ccc7c(c6)oc6ccccc67)n5)c4)cc([2H])cc3c2c1 ; [2H]c1cc([2H])c2sc3c(-c4cccc(-c5nc(-c6ccc(-c7ccccc7)cc6)nc(-c6cccc(-c7ccccc7)c6)n5)c4)cc([2H])c([2H])c3c2c1]

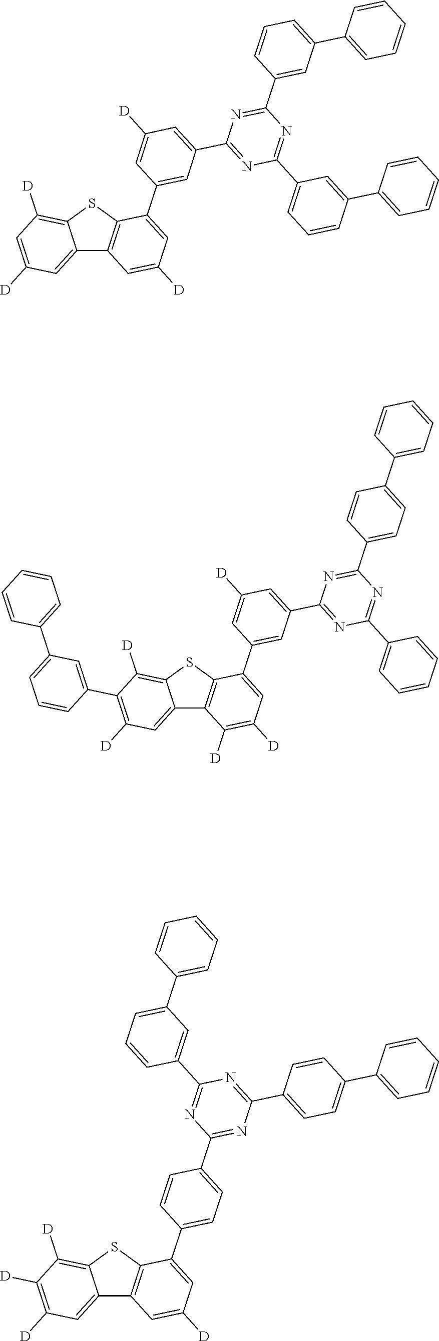 [SMILES: [2H]c1cc(-c2nc(-c3cccc(-c4ccccc4)c3)nc(-c3cccc(-c4ccccc4)c3)n2)cc(-c2cc([2H])cc3c2sc2c([2H])cc([2H])cc23)c1 ; [2H]c1cc(-c2nc(-c3ccccc3)nc(-c3ccc(-c4ccccc4)cc3)n2)cc(-c2cc([2H])c([2H])c3c2sc2c([2H])c(-c4cccc(-c5ccccc5)c4)c([2H])cc23)c1 ; [2H]c1cc(-c2ccc(-c3nc(-c4ccc(-c5ccccc5)cc4)nc(-c4cccc(-c5ccccc5)c4)n3)cc2)c2sc3c([2H])c([2H])c([2H])cc3c2c1]

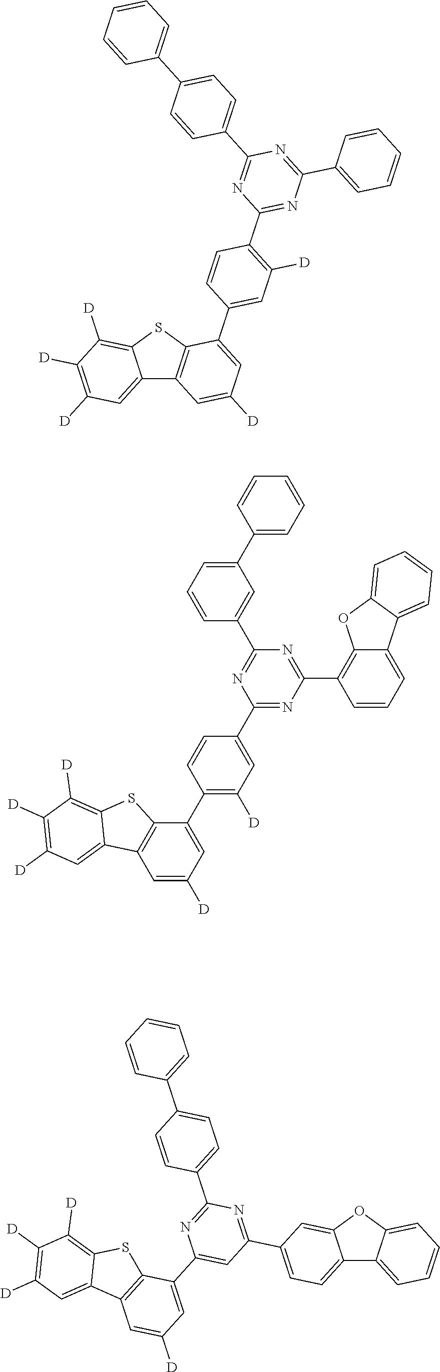 [SMILES: [2H]c1cc(-c2ccc(-c3nc(-c4ccccc4)nc(-c4ccc(-c5ccccc5)cc4)n3)c([2H])c2)c2sc3c([2H])c([2H])c([2H])cc3c2c1 ; [2H]c1cc(-c2ccc(-c3nc(-c4cccc(-c5ccccc5)c4)nc(-c4cccc5c4oc4ccccc45)n3)cc2[2H])c2sc3c([2H])c([2H])c([2H])cc3c2c1 ; [2H]c1cc(-c2cc(-c3ccc4c(c3)oc3ccccc34)nc(-c3ccc(-c4ccccc4)cc3)n2)c2sc3c([2H])c([2H])c([2H])cc3c2c1]

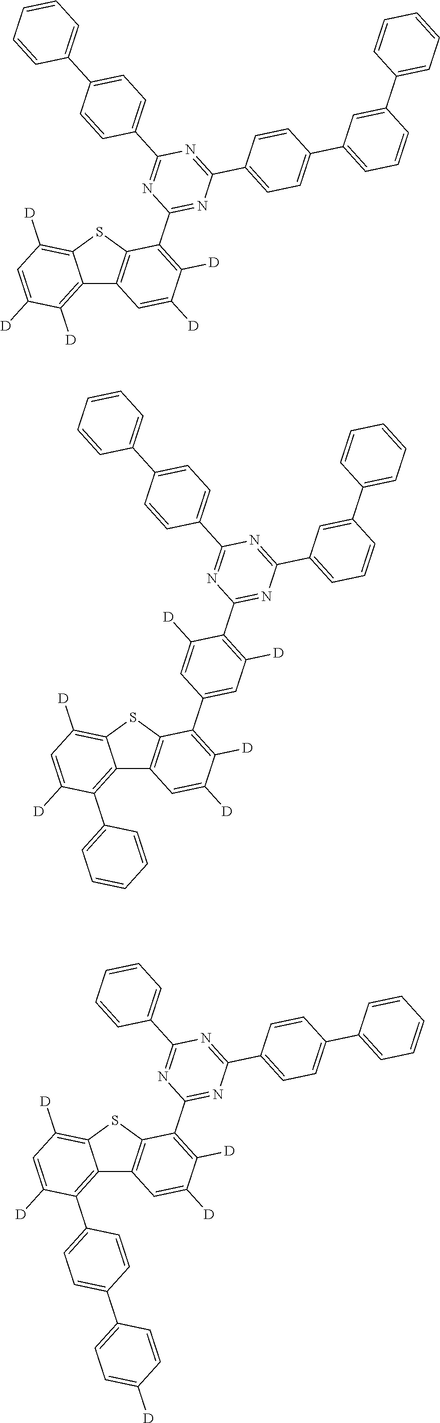 [SMILES: [2H]c1cc2c(sc3c([2H])cc([2H])c([2H])c32)c(-c2nc(-c3ccc(-c4ccccc4)cc3)nc(-c3ccc(-c4cccc(-c5ccccc5)c4)cc3)n2)c1[2H] ; [2H]c1cc2c(sc3c([2H])cc([2H])c(-c4ccccc4)c32)c(-c2cc([2H])c(-c3nc(-c4ccc(-c5ccccc5)cc4)nc(-c4cccc(-c5ccccc5)c4)n3)c([2H])c2)c1[2H] ; [2H]c1ccc(-c2ccc(-c3c([2H])cc([2H])c4sc5c(-c6nc(-c7ccccc7)nc(-c7ccc(-c8ccccc8)cc7)n6)c([2H])c([2H])cc5c34)cc2)cc1]

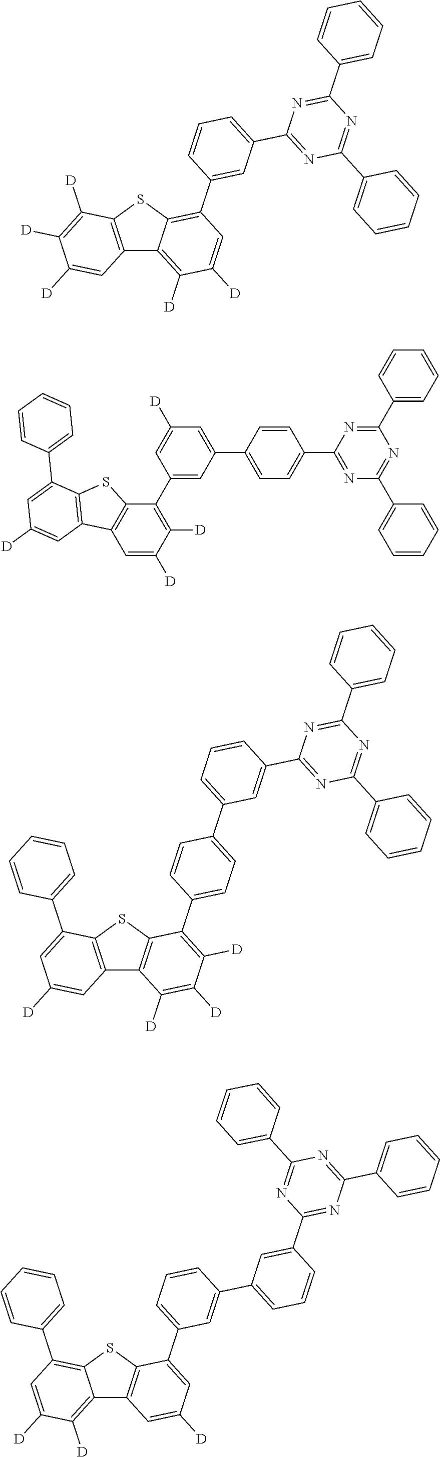 [SMILES: [2H]c1cc2c(sc3c(-c4cccc(-c5nc(-c6ccccc6)nc(-c6ccccc6)n5)c4)cc([2H])c([2H])c32)c([2H])c1[2H] ; [2H]c1cc(-c2ccc(-c3nc(-c4ccccc4)nc(-c4ccccc4)n3)cc2)cc(-c2c([2H])c([2H])cc3c2sc2c(-c4ccccc4)cc([2H])cc23)c1 ; [2H]c1cc(-c2ccccc2)c2sc3c(-c4ccc(-c5cccc(-c6nc(-c7ccccc7)nc(-c7ccccc7)n6)c5)cc4)c([2H])c([2H])c([2H])c3c2c1 ; [2H]c1cc(-c2cccc(-c3cccc(-c4nc(-c5ccccc5)nc(-c5ccccc5)n4)c3)c2)c2sc3c(-c4ccccc4)cc([2H])c([2H])c3c2c1]

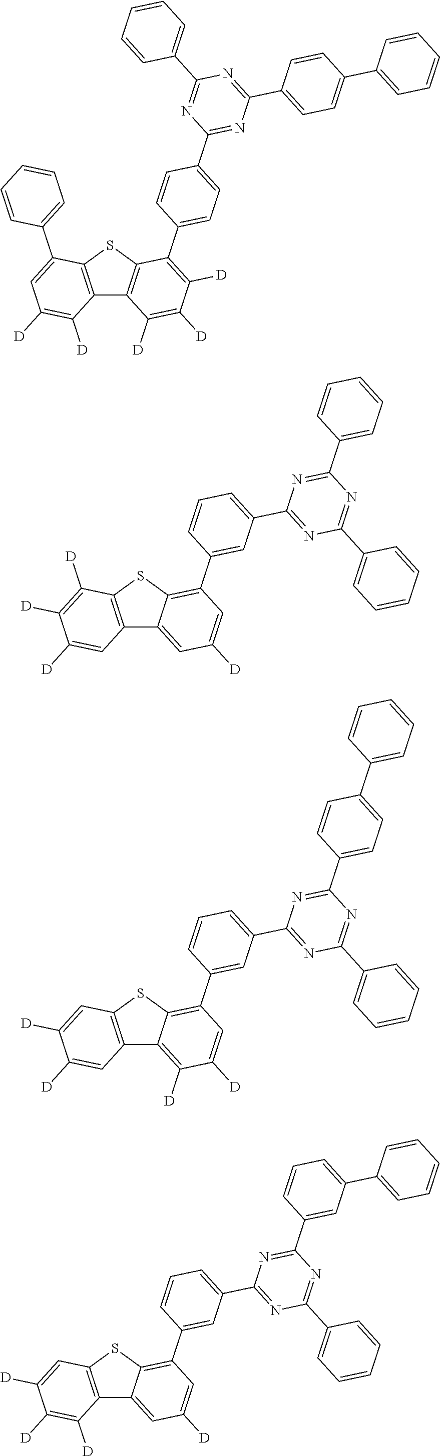 [SMILES: [2H]c1cc(-c2ccccc2)c2sc3c(-c4ccc(-c5nc(-c6ccccc6)nc(-c6ccc(-c7ccccc7)cc6)n5)cc4)c([2H])c([2H])c([2H])c3c2c1[2H] ; [2H]c1cc(-c2cccc(-c3nc(-c4ccccc4)nc(-c4ccccc4)n3)c2)c2sc3c([2H])c([2H])c([2H])cc3c2c1 ; [2H]c1cc2sc3c(-c4cccc(-c5nc(-c6ccccc6)nc(-c6ccc(-c7ccccc7)cc6)n5)c4)cc([2H])c([2H])c3c2cc1[2H] ; [2H]c1cc(-c2cccc(-c3nc(-c4ccccc4)nc(-c4cccc(-c5ccccc5)c4)n3)c2)c2sc3cc([2H])c([2H])c([2H])c3c2c1]

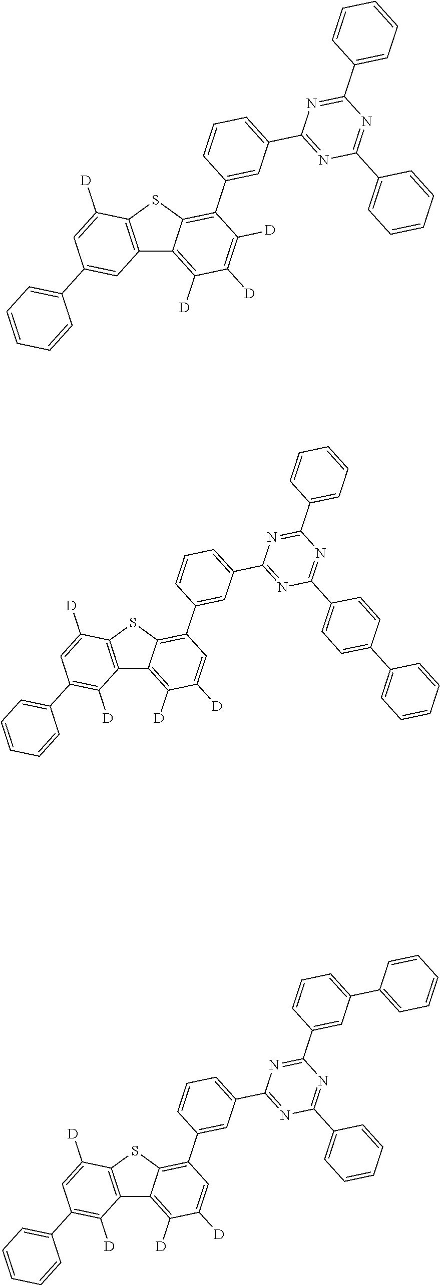 [SMILES: [2H]c1c([2H])c([2H])c2c(sc3c([2H])cc(-c4ccccc4)cc32)c1-c1cccc(-c2nc(-c3ccccc3)nc(-c3ccccc3)n2)c1 ; [2H]c1cc(-c2cccc(-c3nc(-c4ccccc4)nc(-c4ccc(-c5ccccc5)cc4)n3)c2)c2sc3c([2H])cc(-c4ccccc4)c([2H])c3c2c1[2H] ; [2H]c1cc(-c2cccc(-c3nc(-c4ccccc4)nc(-c4cccc(-c5ccccc5)c4)n3)c2)c2sc3c([2H])cc(-c4ccccc4)c([2H])c3c2c1[2H]]

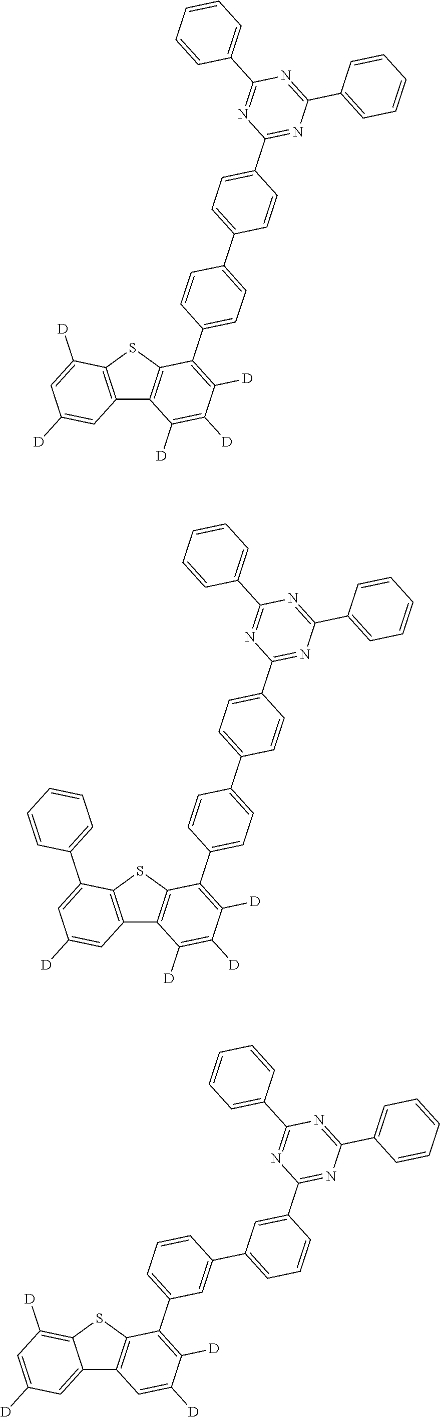 [SMILES: [2H]c1cc([2H])c2sc3c(-c4ccc(-c5ccc(-c6nc(-c7ccccc7)nc(-c7ccccc7)n6)cc5)cc4)c([2H])c([2H])c([2H])c3c2c1 ; [2H]c1cc(-c2ccccc2)c2sc3c(-c4ccc(-c5ccc(-c6nc(-c7ccccc7)nc(-c7ccccc7)n6)cc5)cc4)c([2H])c([2H])c([2H])c3c2c1 ; [2H]c1cc([2H])c2sc3c(-c4cccc(-c5cccc(-c6nc(-c7ccccc7)nc(-c7ccccc7)n6)c5)c4)c([2H])c([2H])cc3c2c1]

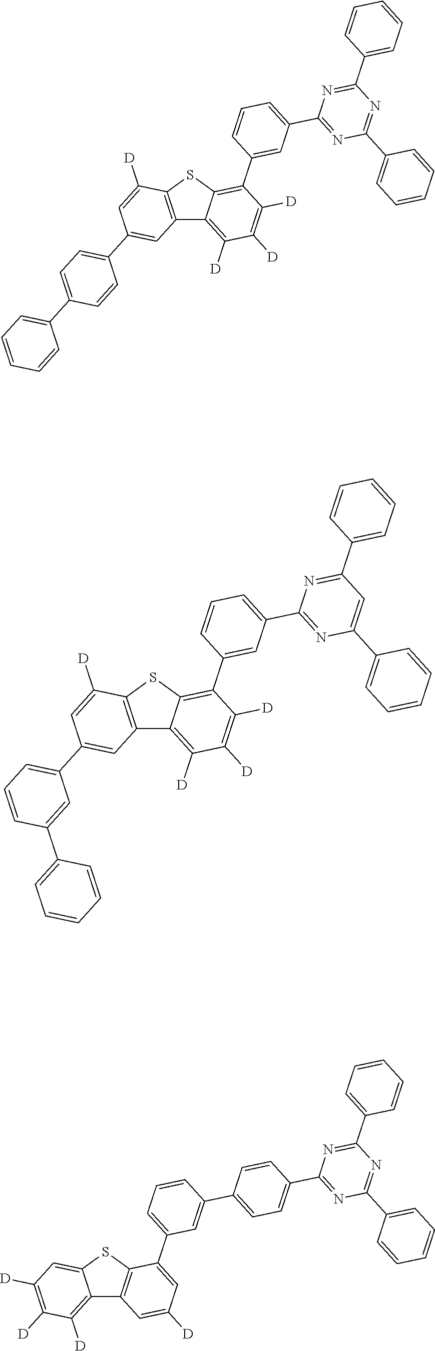 [SMILES: [2H]c1c([2H])c([2H])c2c(sc3c([2H])cc(-c4ccc(-c5ccccc5)cc4)cc32)c1-c1cccc(-c2nc(-c3ccccc3)nc(-c3ccccc3)n2)c1 ; [2H]c1c([2H])c([2H])c2c(sc3c([2H])cc(-c4cccc(-c5ccccc5)c4)cc32)c1-c1cccc(-c2nc(-c3ccccc3)cc(-c3ccccc3)n2)c1 ; [2H]c1cc(-c2cccc(-c3ccc(-c4nc(-c5ccccc5)nc(-c5ccccc5)n4)cc3)c2)c2sc3cc([2H])c([2H])c([2H])c3c2c1]

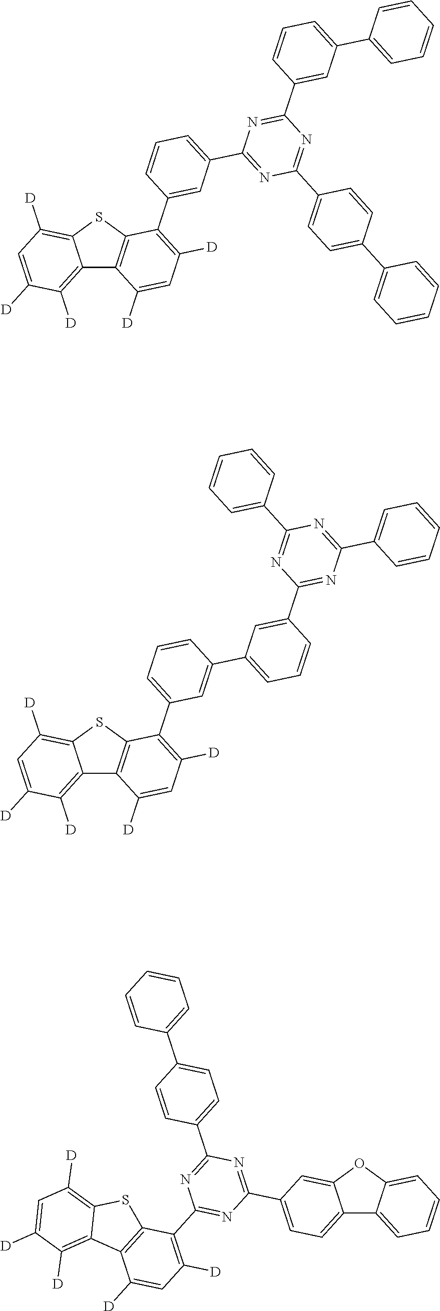 [SMILES: [2H]c1cc([2H])c2c(sc3c([2H])cc([2H])c([2H])c32)c1-c1cccc(-c2nc(-c3ccc(-c4ccccc4)cc3)nc(-c3cccc(-c4ccccc4)c3)n2)c1 ; [2H]c1cc([2H])c2c(sc3c([2H])cc([2H])c([2H])c32)c1-c1cccc(-c2cccc(-c3nc(-c4ccccc4)nc(-c4ccccc4)n3)c2)c1 ; [2H]c1cc([2H])c2c(sc3c([2H])cc([2H])c([2H])c32)c1-c1nc(-c2ccc(-c3ccccc3)cc2)nc(-c2ccc3c(c2)oc2ccccc23)n1]

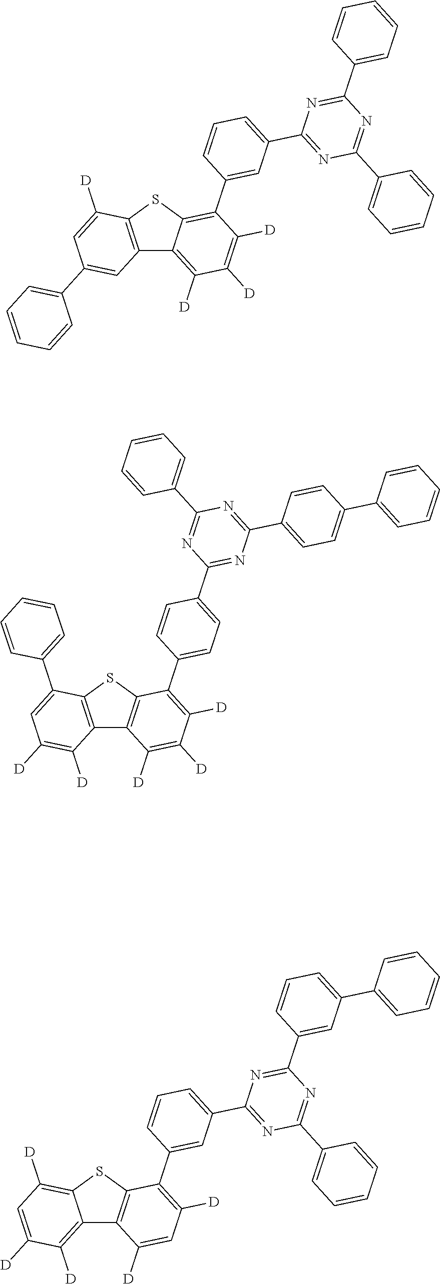 [SMILES: [2H]c1c([2H])c([2H])c2c(sc3c([2H])cc(-c4ccccc4)cc32)c1-c1cccc(-c2nc(-c3ccccc3)nc(-c3ccccc3)n2)c1 ; [2H]c1cc(-c2ccccc2)c2sc3c(-c4ccc(-c5nc(-c6ccccc6)nc(-c6ccc(-c7ccccc7)cc6)n5)cc4)c([2H])c([2H])c([2H])c3c2c1[2H] ; [2H]c1cc([2H])c2c(sc3c([2H])cc([2H])c([2H])c32)c1-c1cccc(-c2nc(-c3ccccc3)nc(-c3cccc(-c4ccccc4)c3)n2)c1]

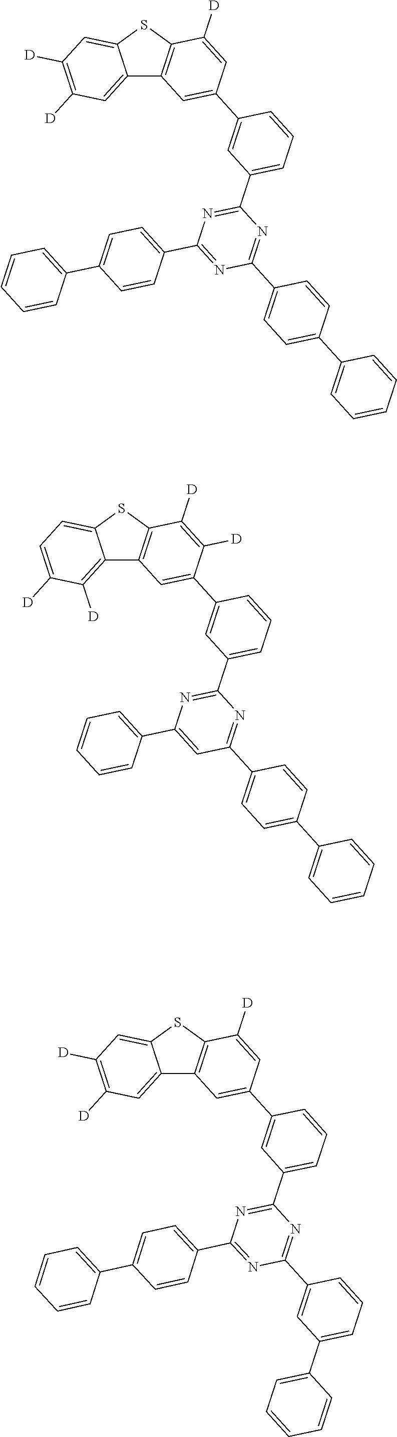 [SMILES: [2H]c1cc2sc3c([2H])cc(-c4cccc(-c5nc(-c6ccc(-c7ccccc7)cc6)nc(-c6ccc(-c7ccccc7)cc6)n5)c4)cc3c2cc1[2H] ; [2H]c1ccc2sc3c([2H])c([2H])c(-c4cccc(-c5nc(-c6ccccc6)cc(-c6ccc(-c7ccccc7)cc6)n5)c4)cc3c2c1[2H] ; [2H]c1cc2sc3c([2H])cc(-c4cccc(-c5nc(-c6ccc(-c7ccccc7)cc6)nc(-c6cccc(-c7ccccc7)c6)n5)c4)cc3c2cc1[2H]]

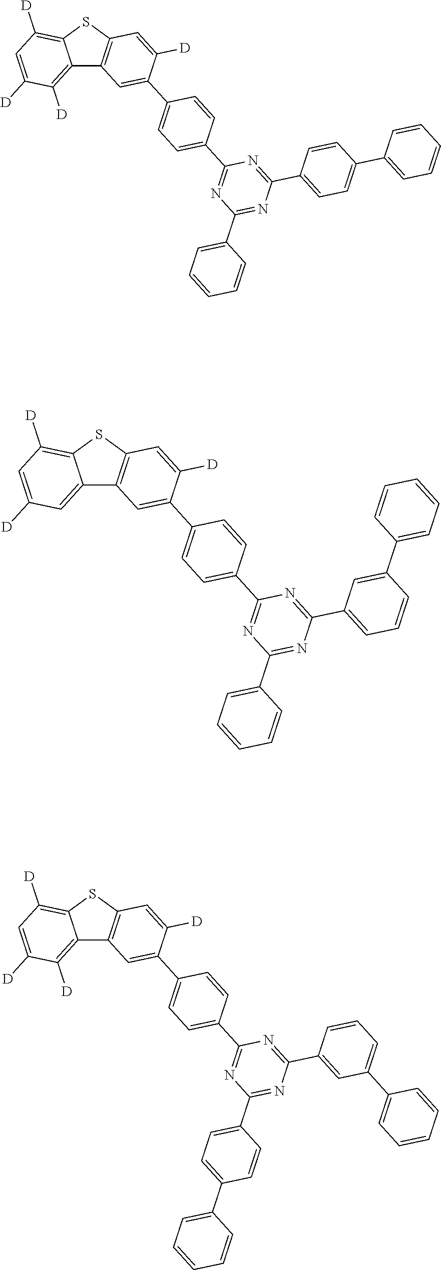 [SMILES: [2H]c1cc2sc3c([2H])cc([2H])c([2H])c3c2cc1-c1ccc(-c2nc(-c3ccccc3)nc(-c3ccc(-c4ccccc4)cc3)n2)cc1 ; [2H]c1cc([2H])c2sc3cc([2H])c(-c4ccc(-c5nc(-c6ccccc6)nc(-c6cccc(-c7ccccc7)c6)n5)cc4)cc3c2c1 ; [2H]c1cc2sc3c([2H])cc([2H])c([2H])c3c2cc1-c1ccc(-c2nc(-c3ccc(-c4ccccc4)cc3)nc(-c3cccc(-c4ccccc4)c3)n2)cc1]

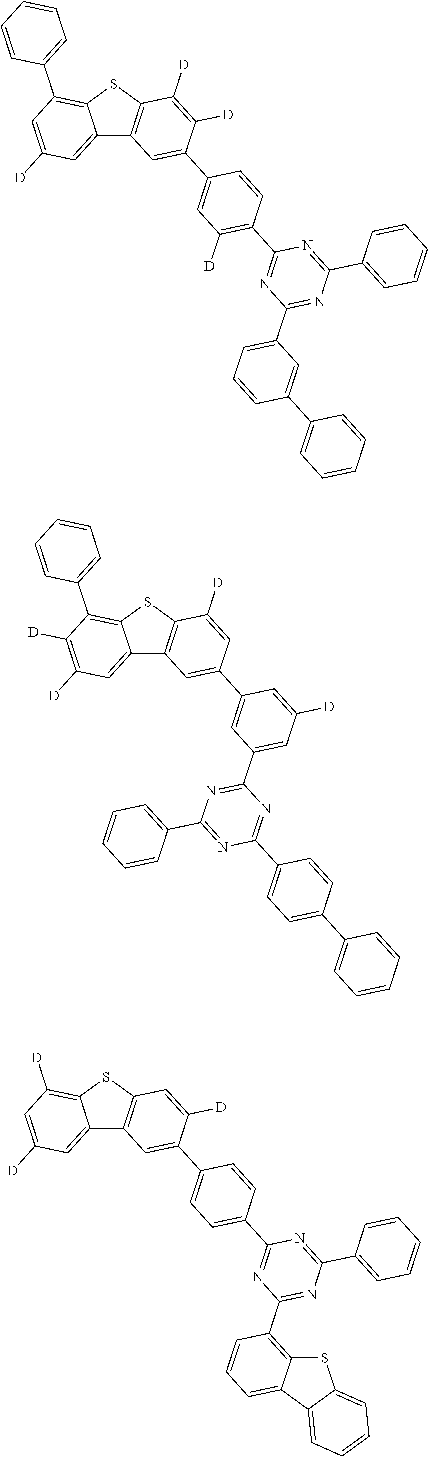 [SMILES: [2H]c1cc(-c2ccccc2)c2sc3c([2H])c([2H])c(-c4ccc(-c5nc(-c6ccccc6)nc(-c6cccc(-c7ccccc7)c6)n5)c([2H])c4)cc3c2c1 ; [2H]c1cc(-c2cc([2H])c3sc4c(-c5ccccc5)c([2H])c([2H])cc4c3c2)cc(-c2nc(-c3ccccc3)nc(-c3ccc(-c4ccccc4)cc3)n2)c1 ; [2H]c1cc([2H])c2sc3cc([2H])c(-c4ccc(-c5nc(-c6ccccc6)nc(-c6cccc7c6sc6ccccc67)n5)cc4)cc3c2c1]

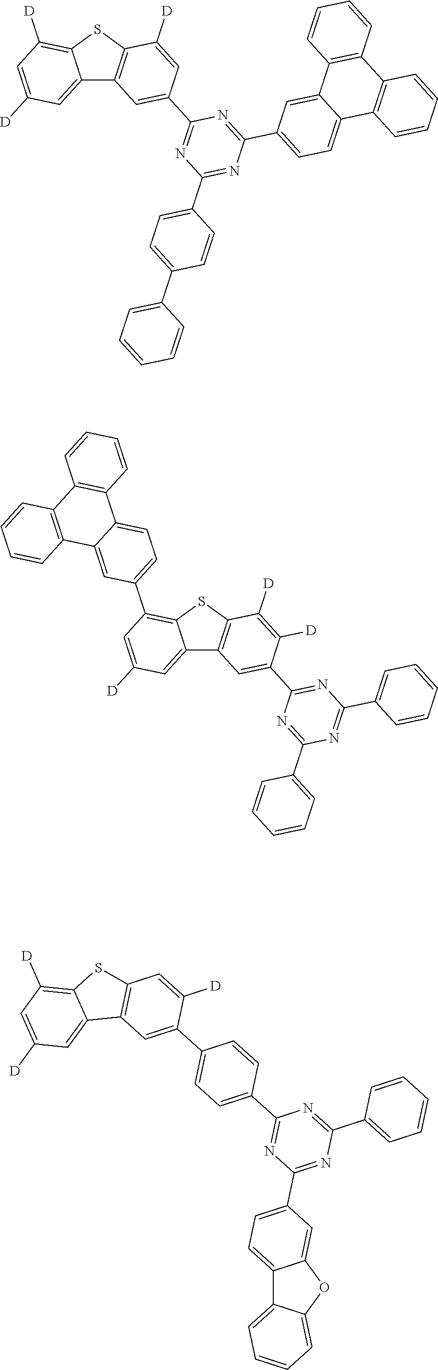 [SMILES: [2H]c1cc([2H])c2sc3c([2H])cc(-c4nc(-c5ccc(-c6ccccc6)cc5)nc(-c5ccc6c7ccccc7c7ccccc7c6c5)n4)cc3c2c1 ; [2H]c1cc(-c2ccc3c4ccccc4c4ccccc4c3c2)c2sc3c([2H])c([2H])c(-c4nc(-c5ccccc5)nc(-c5ccccc5)n4)cc3c2c1 ; [2H]c1cc([2H])c2sc3cc([2H])c(-c4ccc(-c5nc(-c6ccccc6)nc(-c6ccc7c(c6)oc6ccccc67)n5)cc4)cc3c2c1]

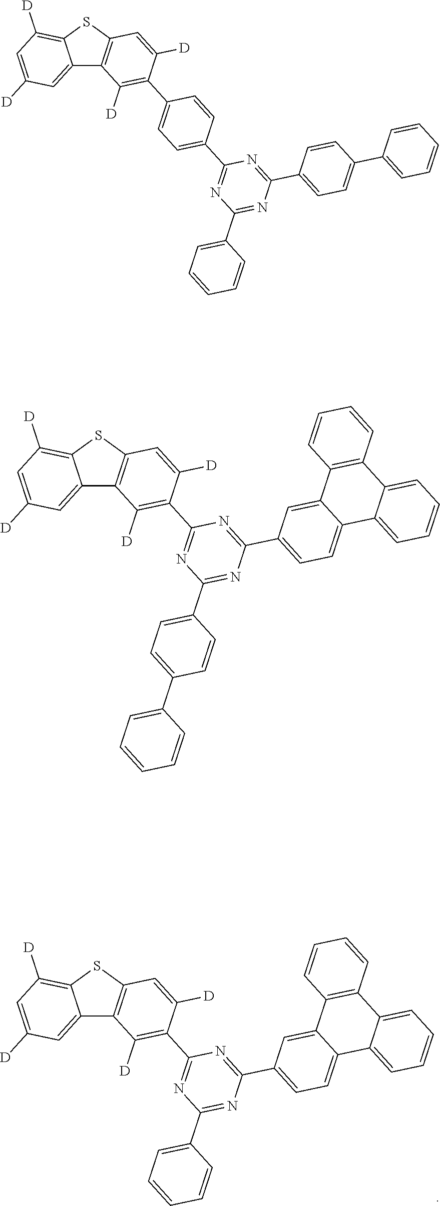 [SMILES: [2H]c1cc([2H])c2sc3cc([2H])c(-c4ccc(-c5nc(-c6ccccc6)nc(-c6ccc(-c7ccccc7)cc6)n5)cc4)c([2H])c3c2c1 ; [2H]c1cc([2H])c2sc3cc([2H])c(-c4nc(-c5ccc(-c6ccccc6)cc5)nc(-c5ccc6c7ccccc7c7ccccc7c6c5)n4)c([2H])c3c2c1 ; [2H]c1cc([2H])c2sc3cc([2H])c(-c4nc(-c5ccccc5)nc(-c5ccc6c7ccccc7c7ccccc7c6c5)n4)c([2H])c3c2c1]

15. The organic light emitting device of claim 1, wherein:
the second compound is represented by the following Chemical Formula 2-1: 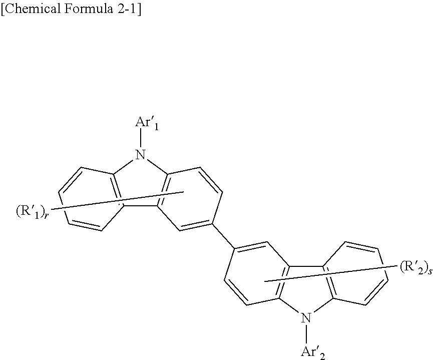
wherein, in Chemical Formula 2-1,
Ar′₁, Ar′₂, R′₁, R′₂, r and s are as defined in claim 1.

16. The organic light emitting device of claim 1, wherein:
Ar′₁ and Ar′₂ are each independently phenyl, biphenylyl, terphenylyl, naphthyl, dimethylfluorenyl, dibenzofuranyl, or dibenzothiophenyl,
wherein the Ar′₁ is unsubstituted, or substituted with one or more substituents selected from the group consisting of deuterium and a C₆₋₂₀ aryl substituted or unsubstituted with deuterium.

17. The organic light emitting device of claim 1, wherein:
R′₁ and R′₂ are each independently deuterium, or a substituted or unsubstituted C₆₋₂₀ aryl.

18. The organic light emitting device of claim 1, wherein:
the second compound is any one compound selected from among the following compounds:

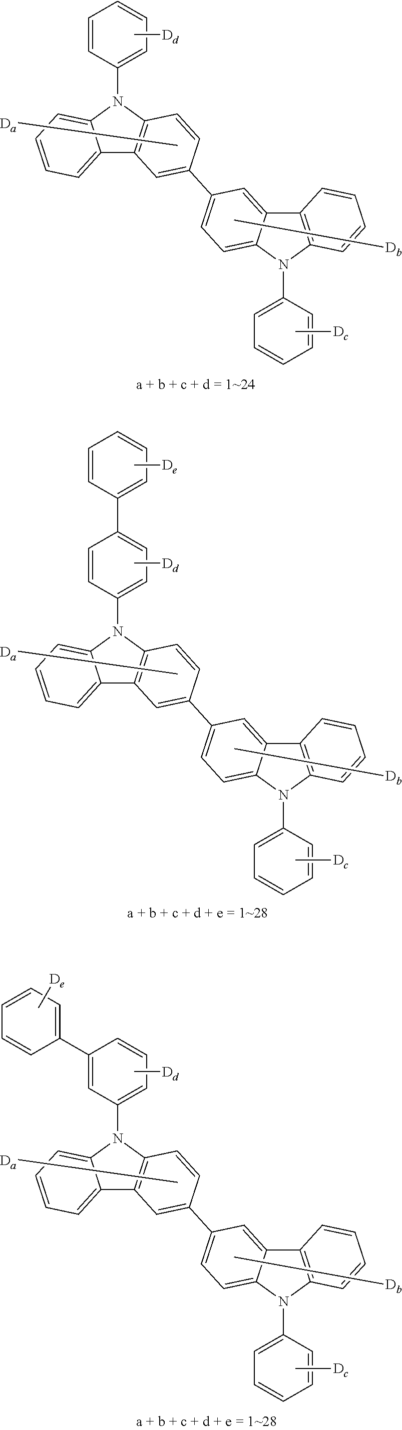

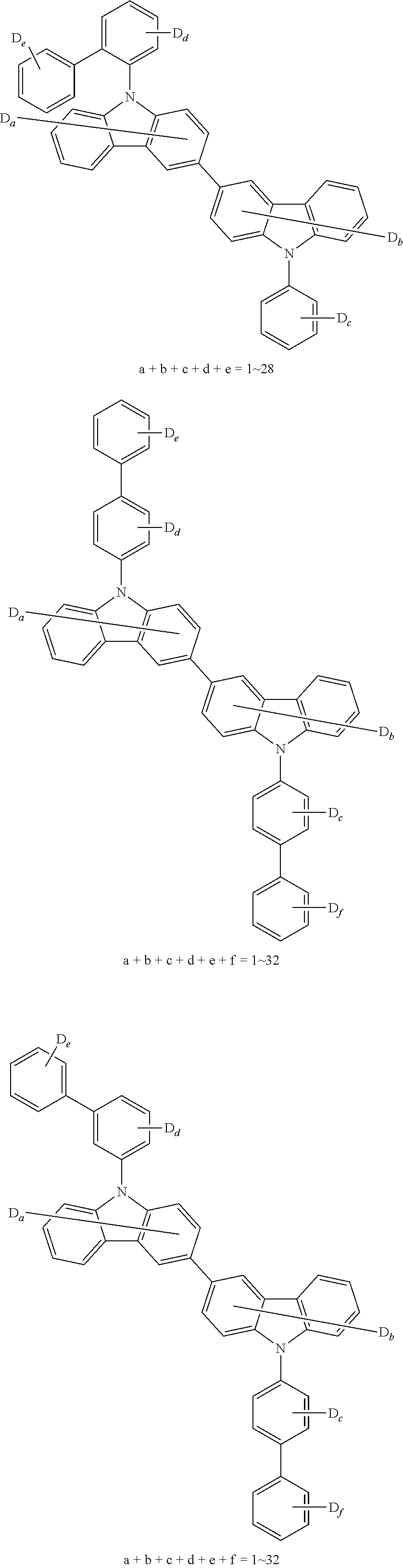

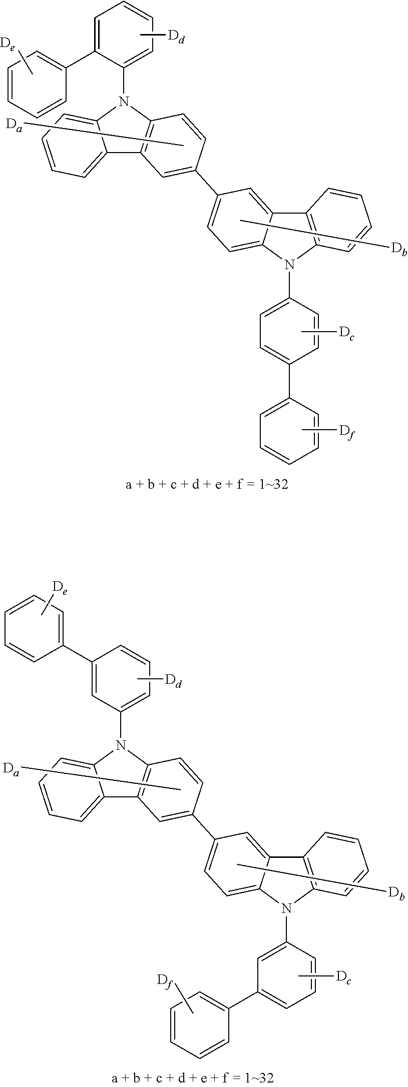

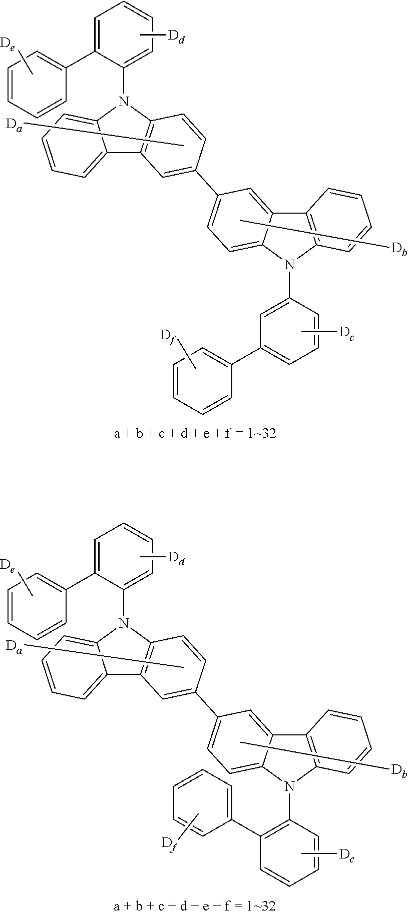

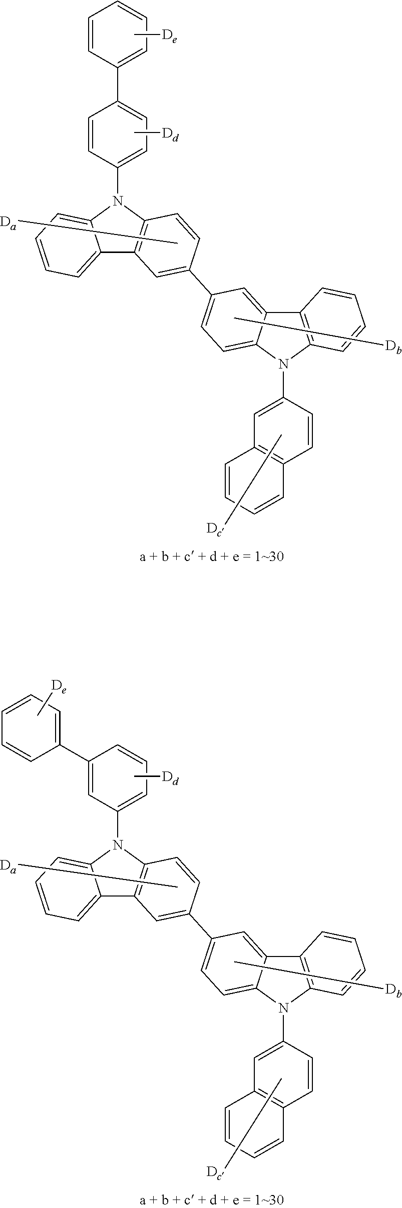

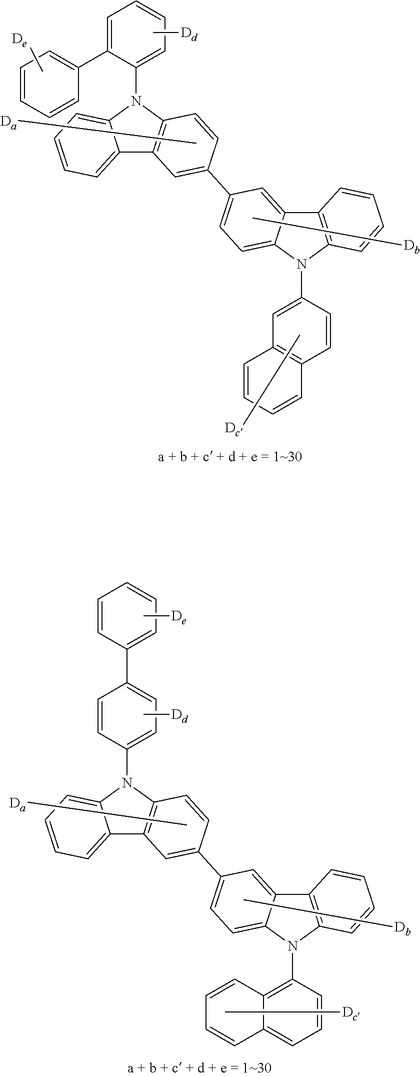

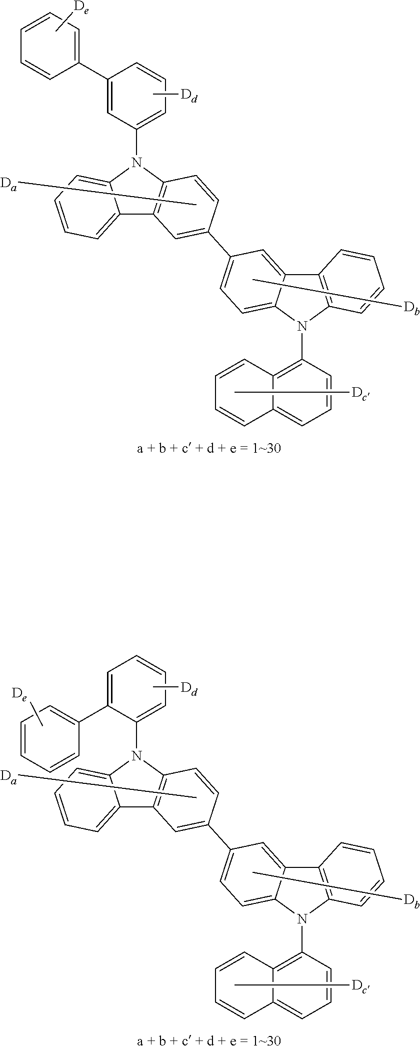

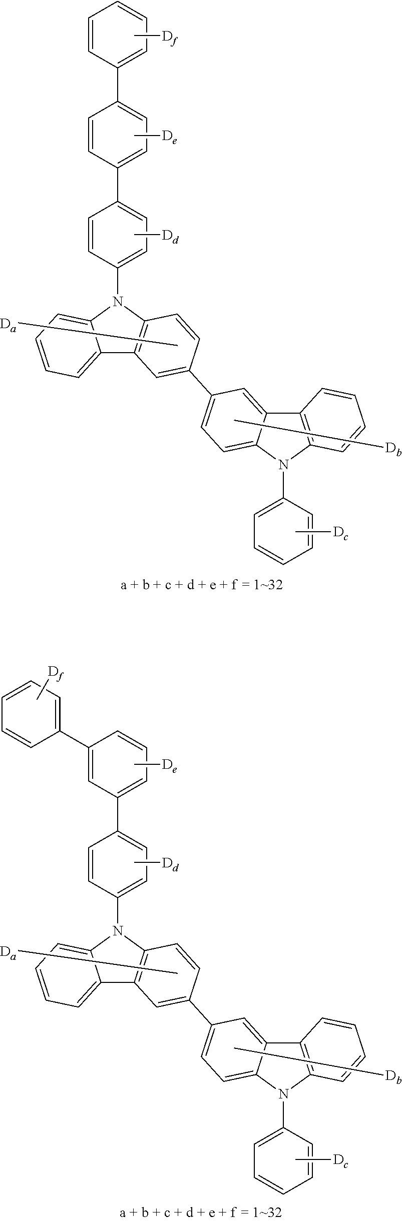

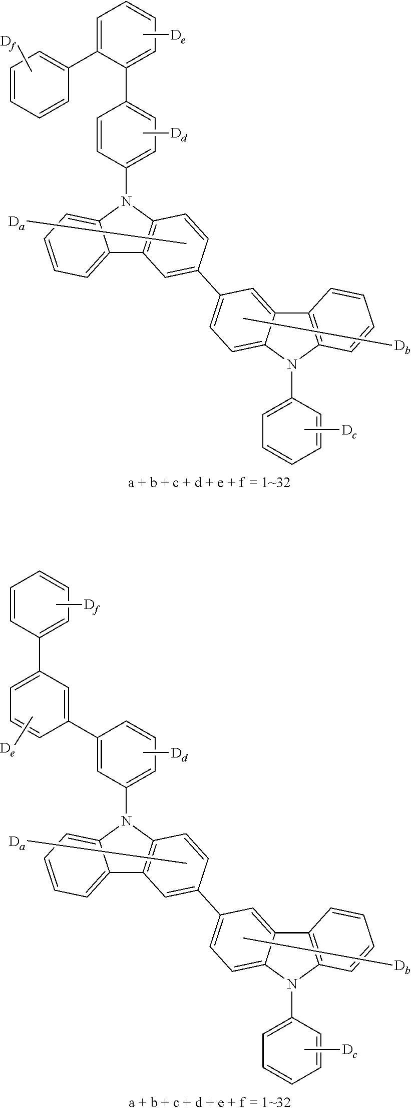

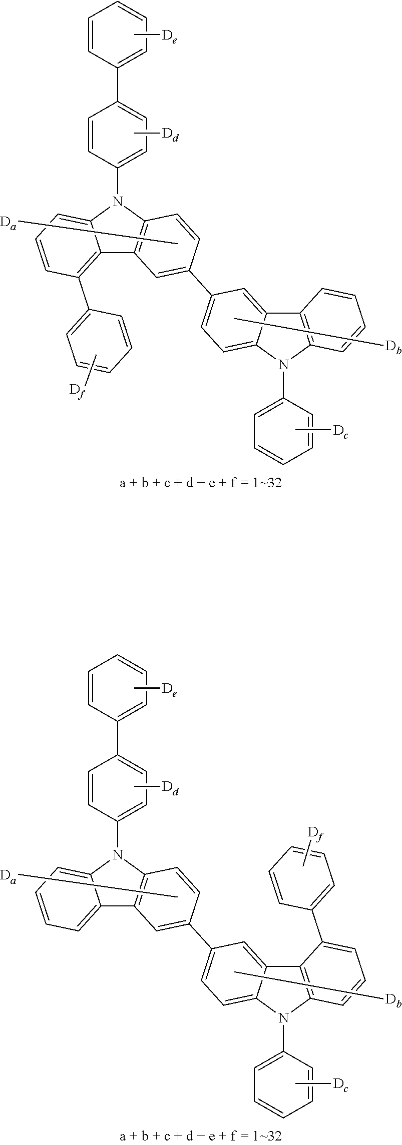

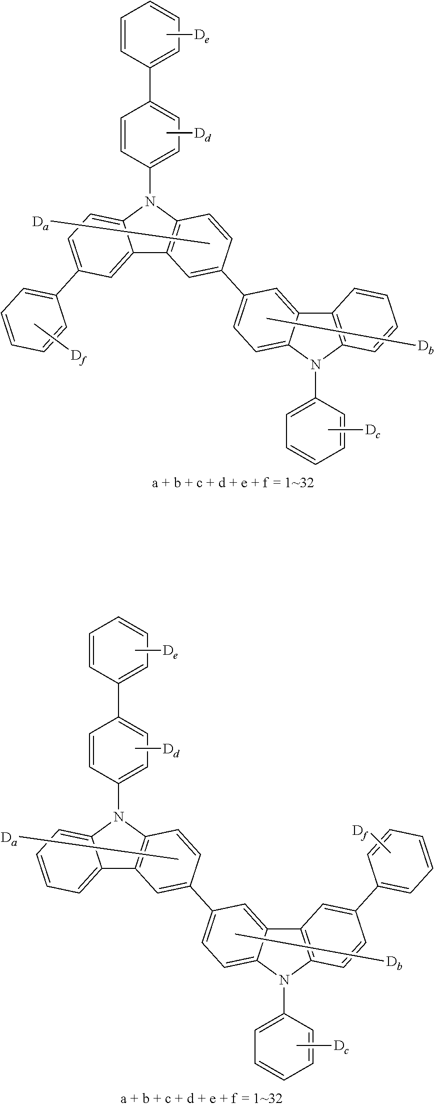

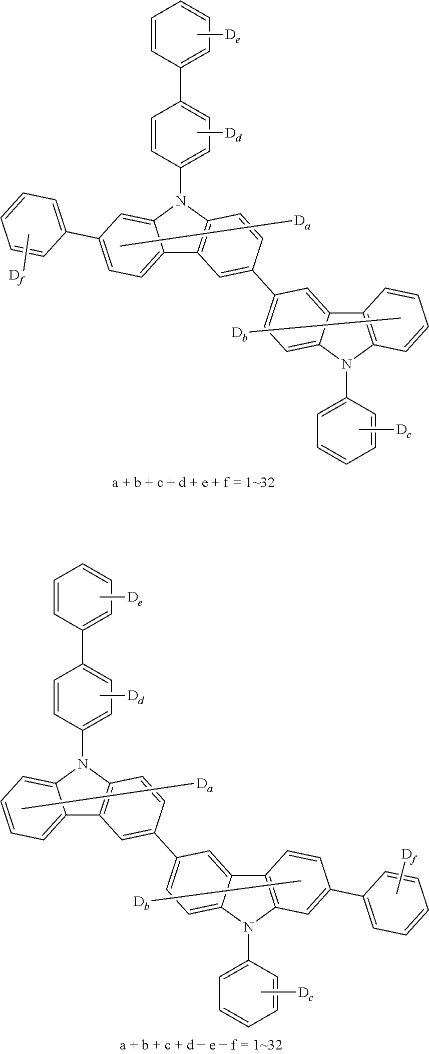

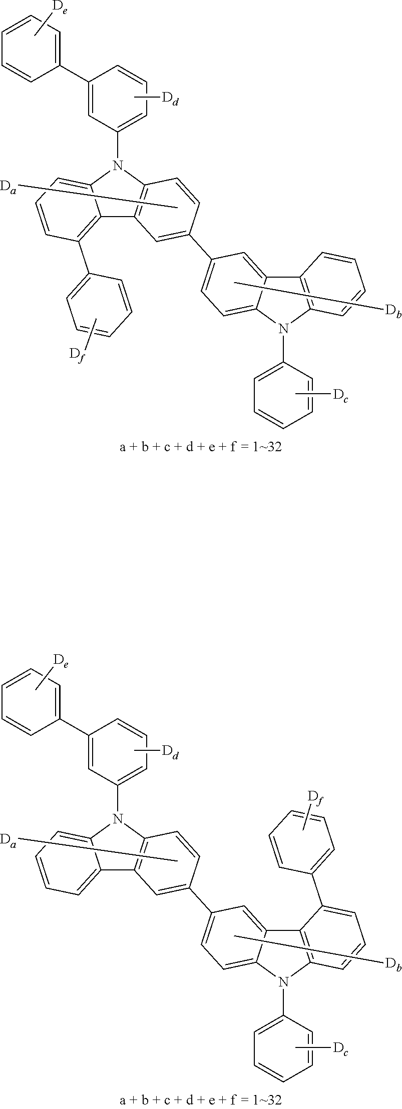

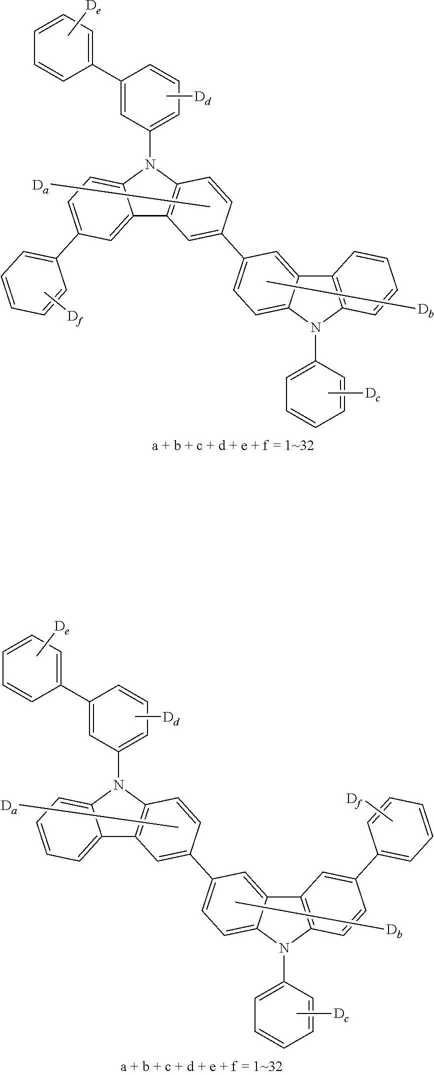

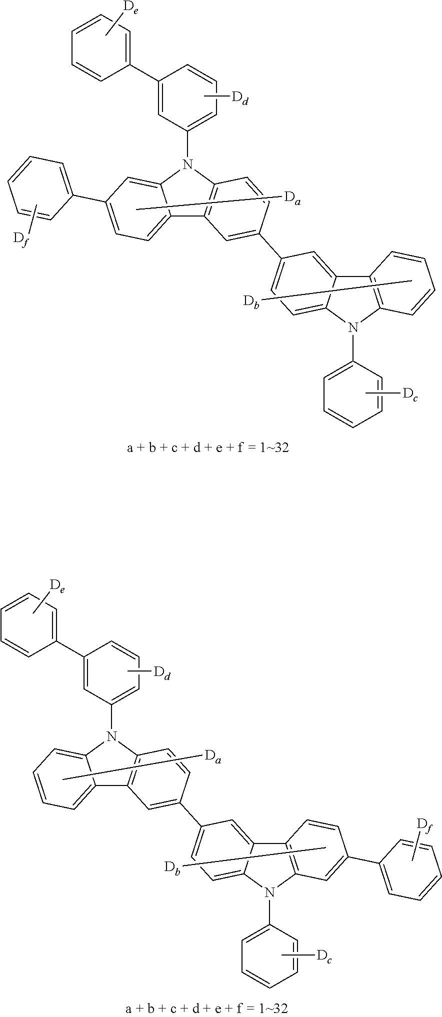

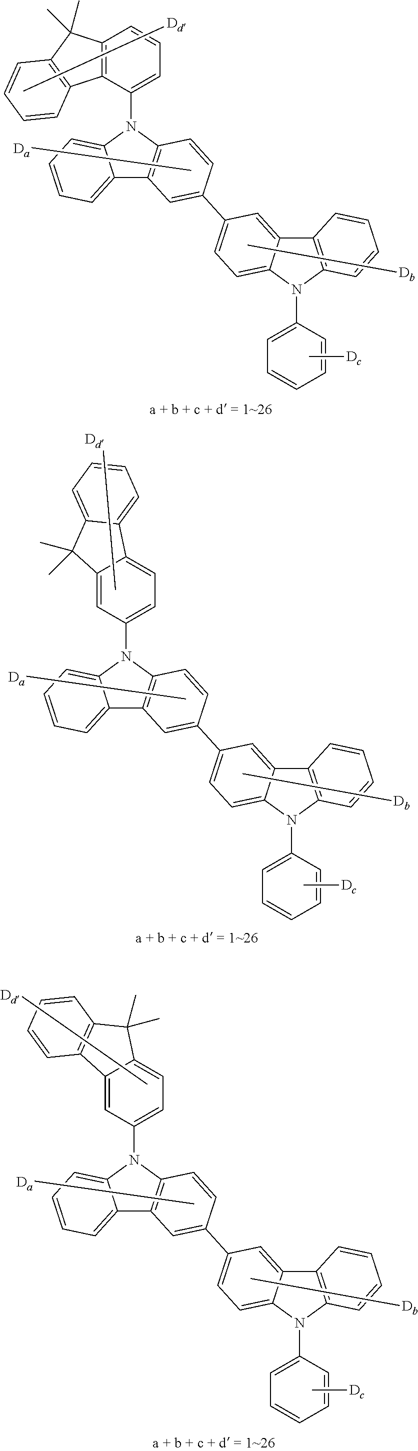

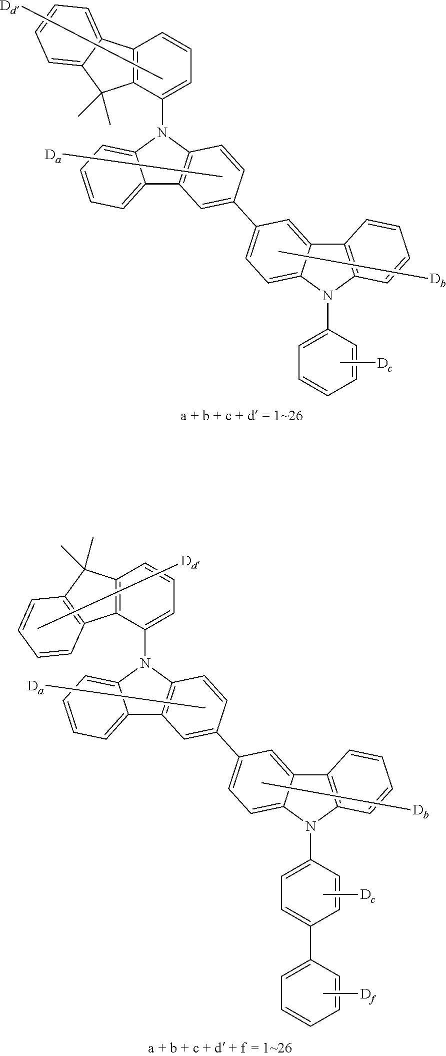

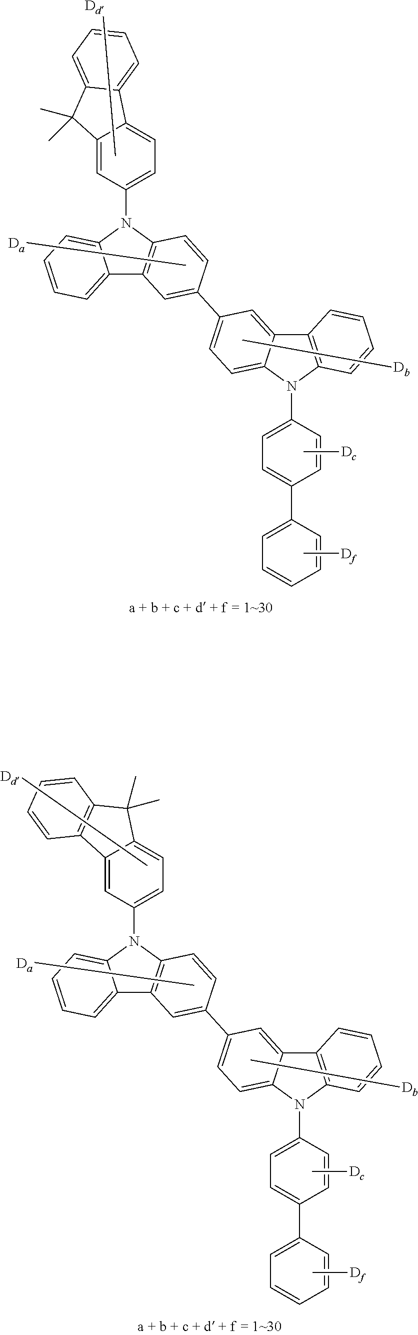

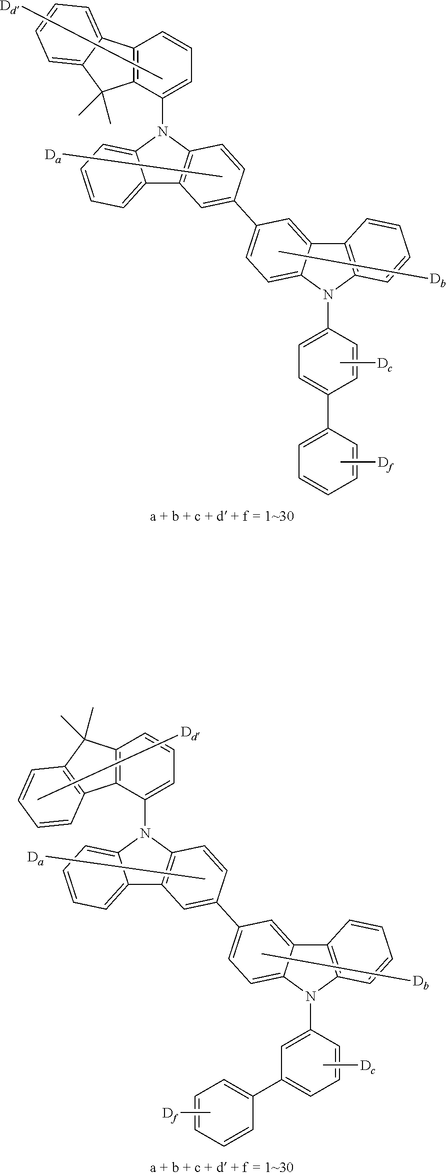

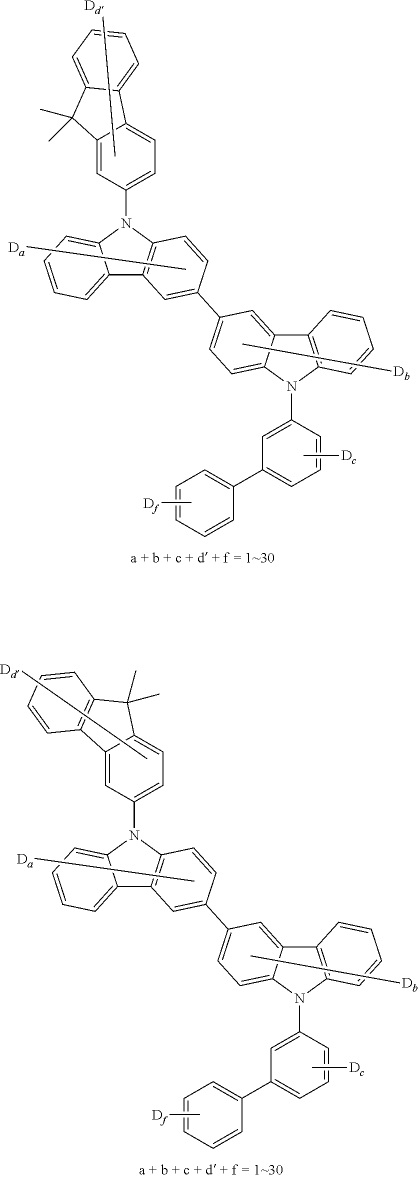

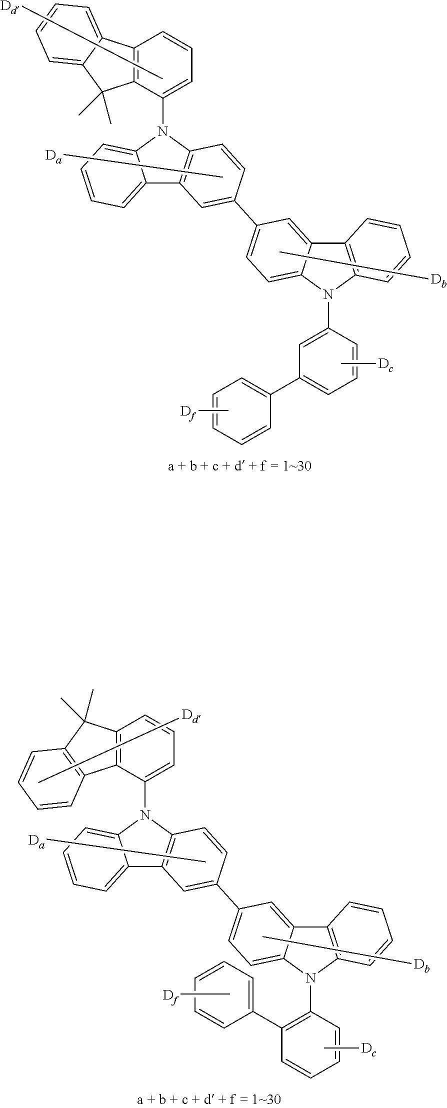

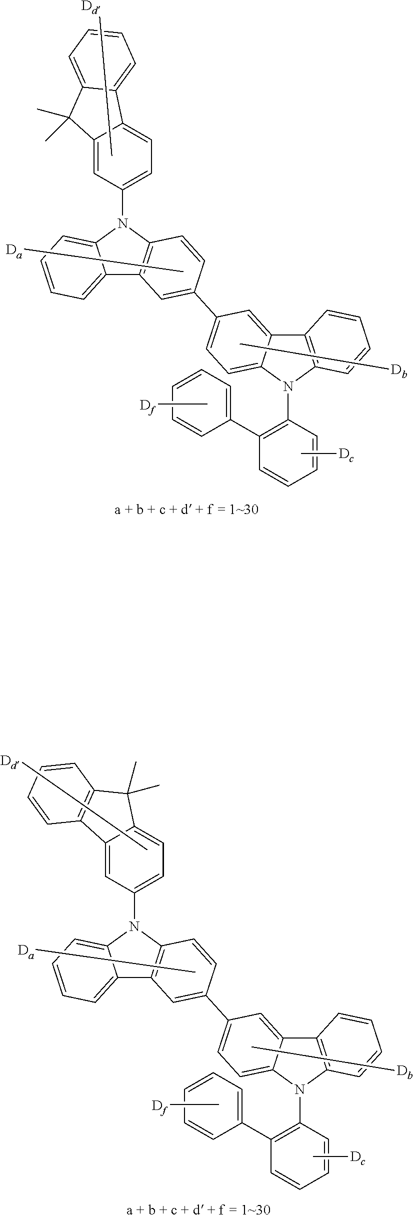

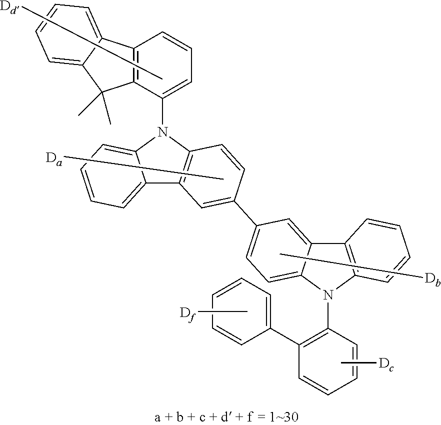

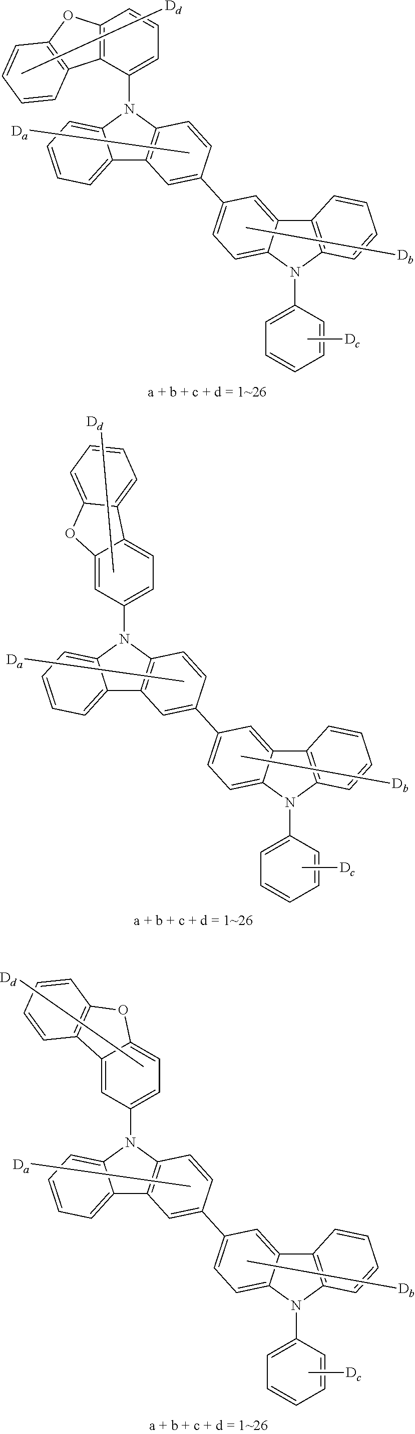

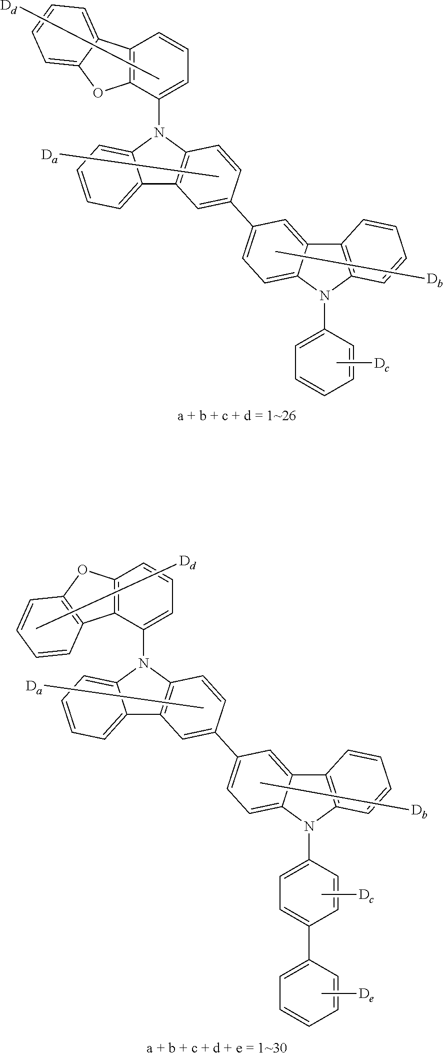

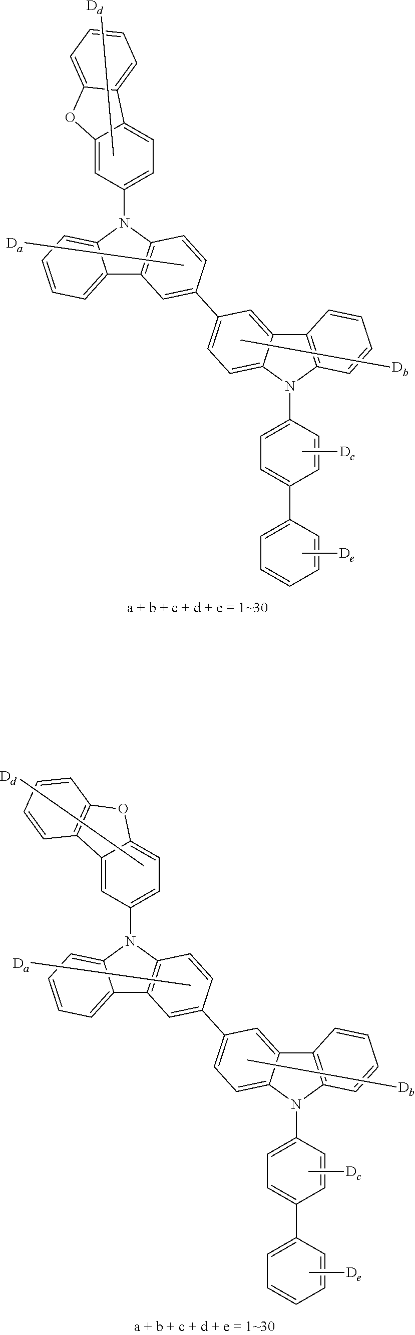

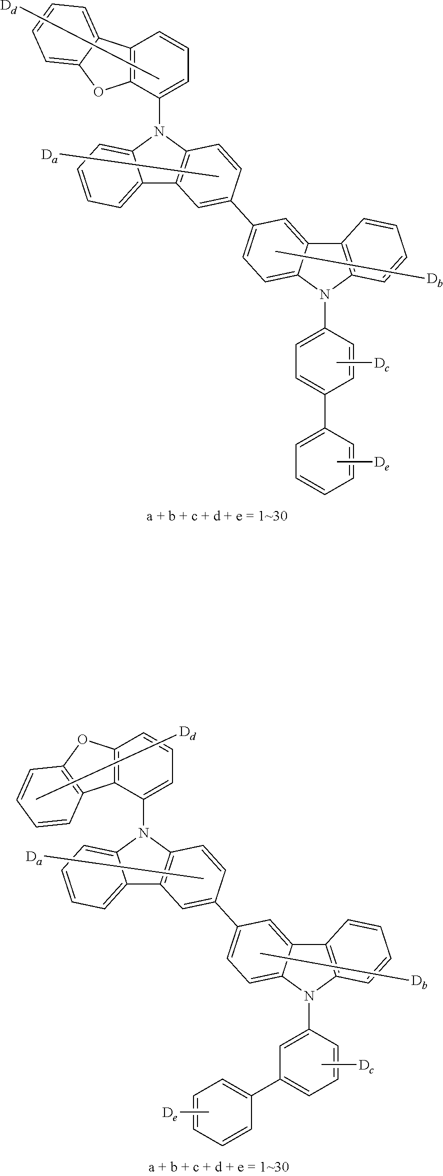

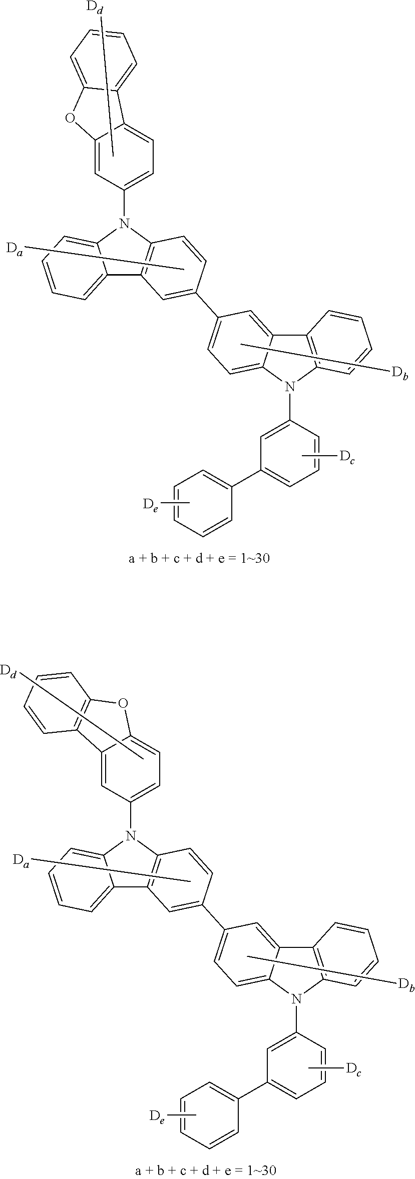

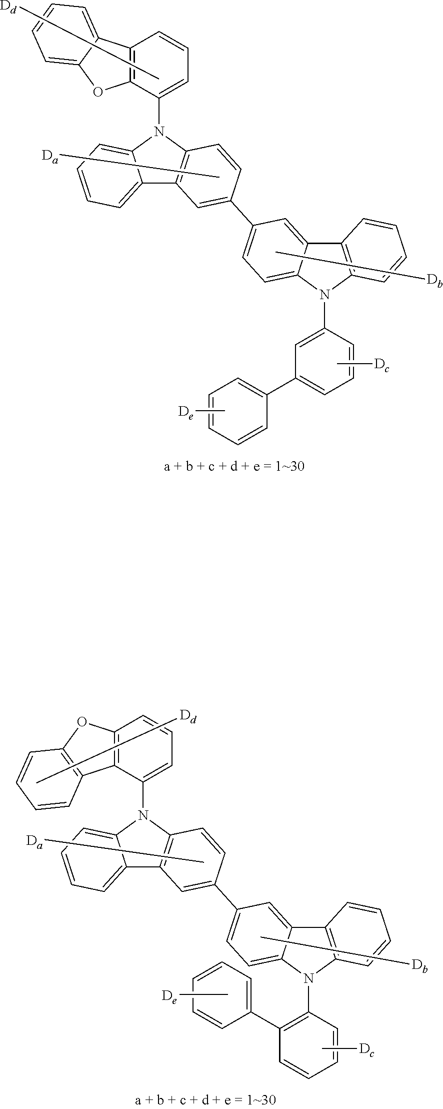

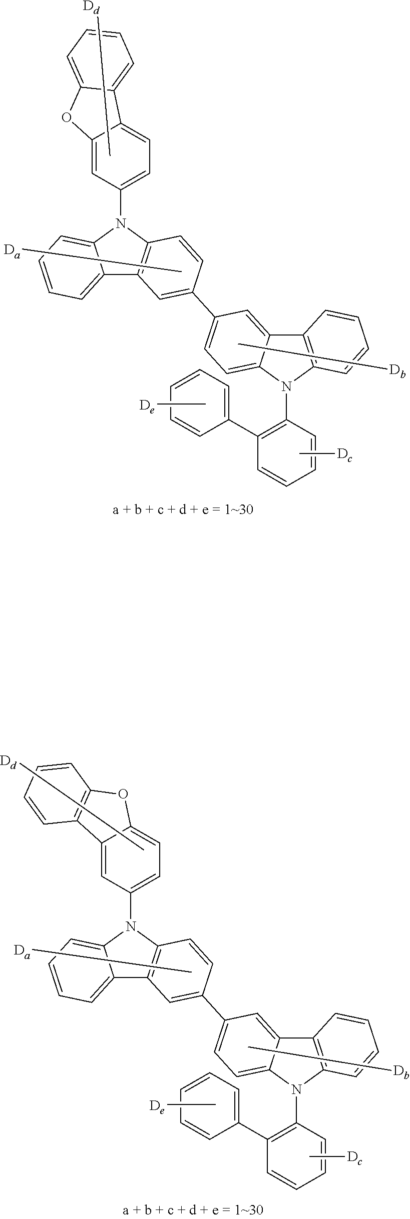

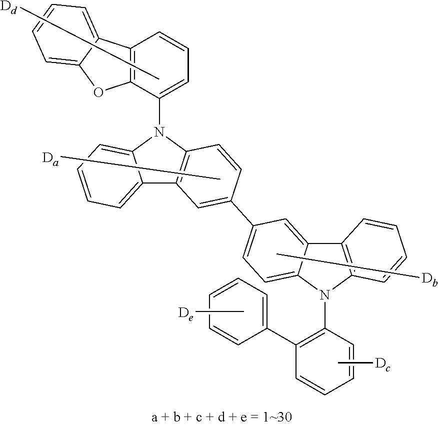

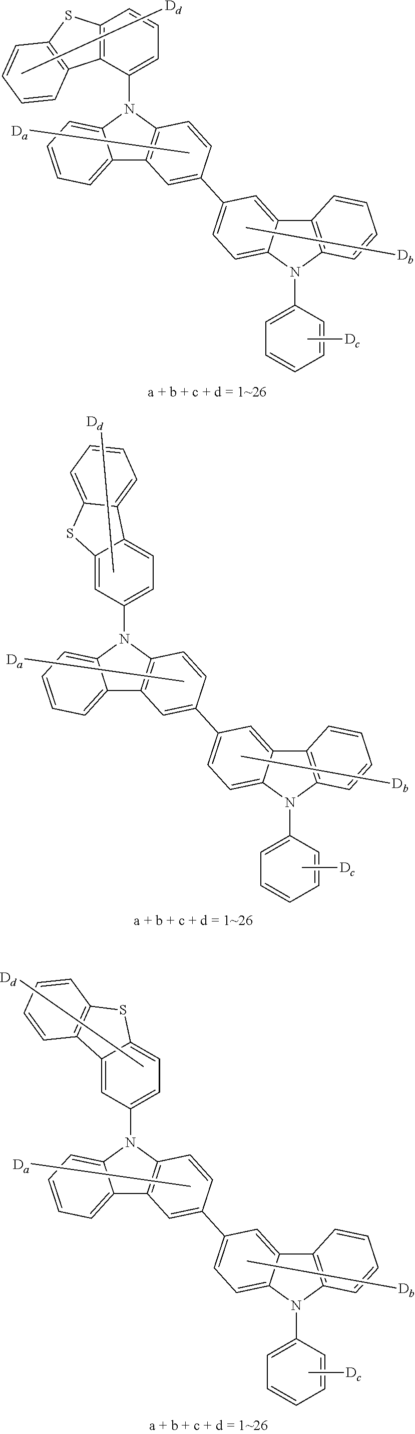

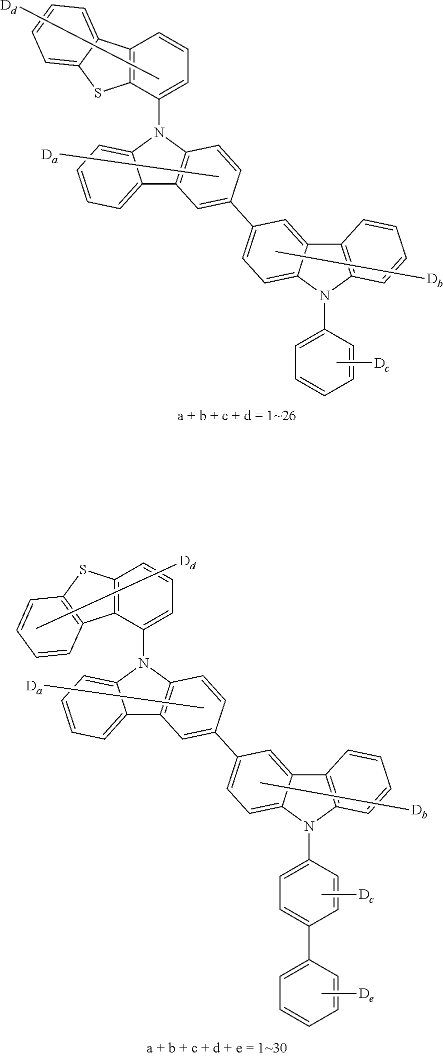

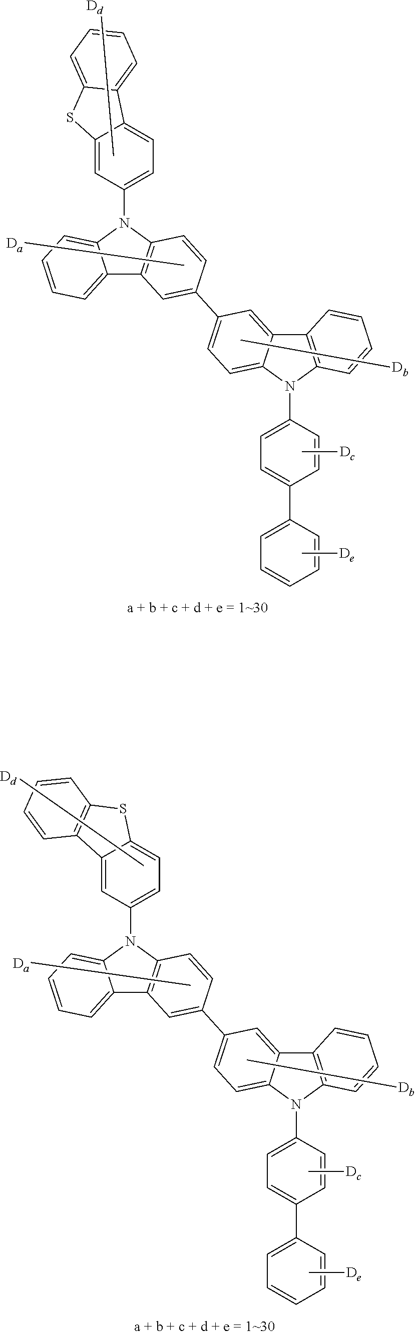

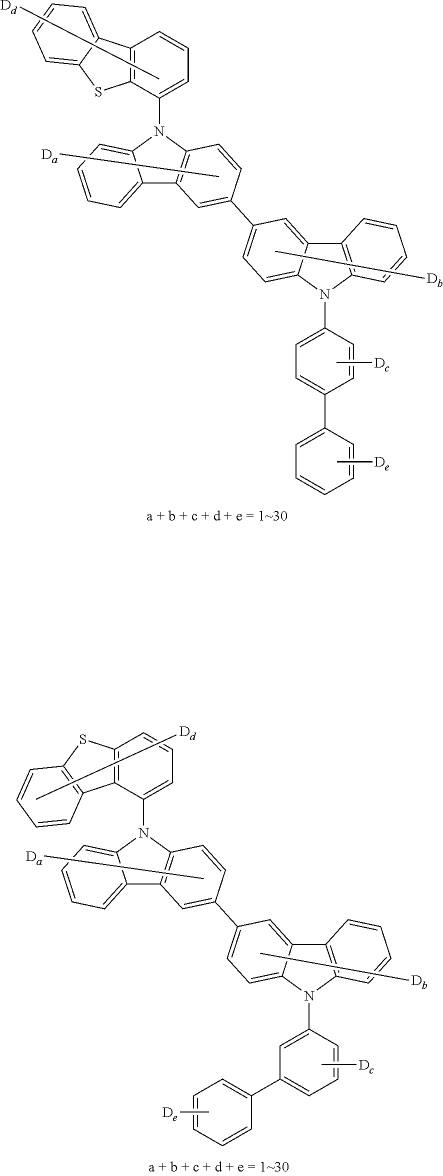

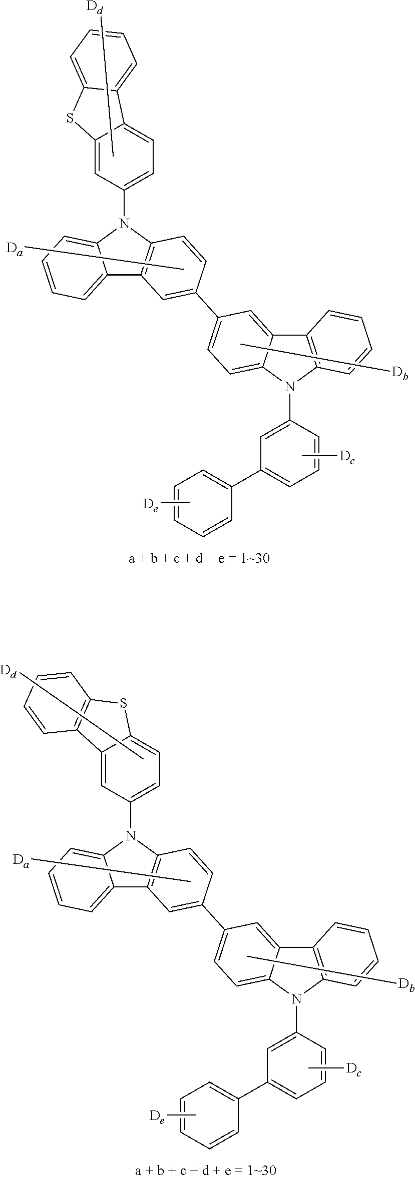

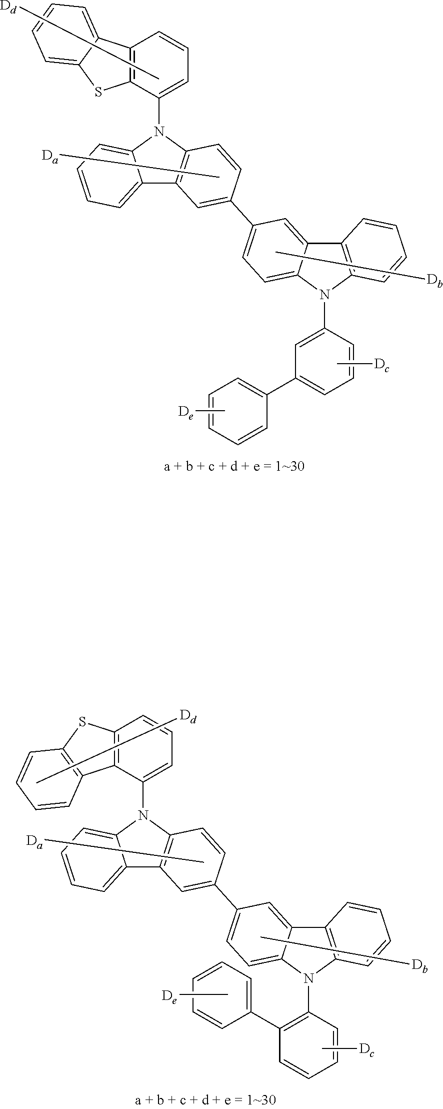

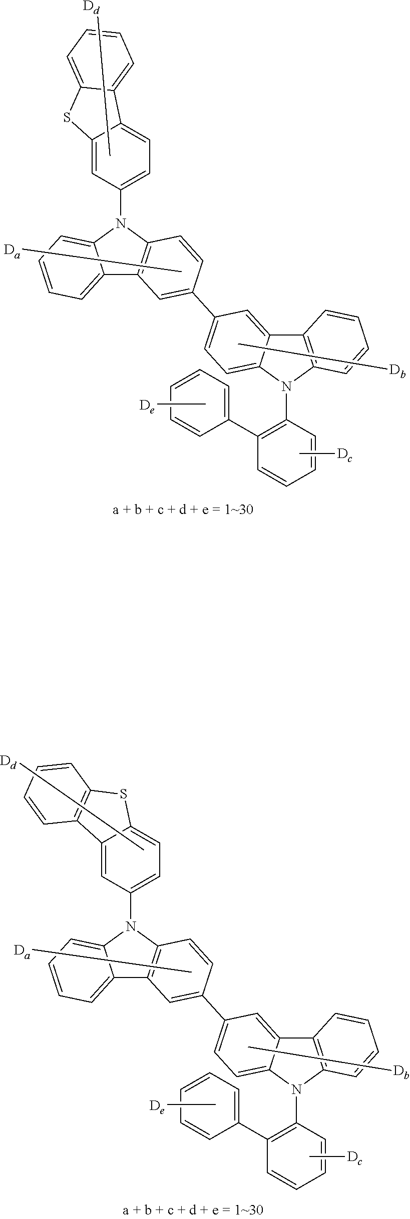

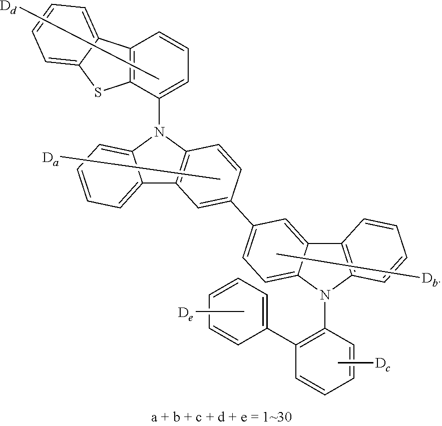

19. The organic light emitting device of claim 1, wherein:
the deuterium substitution rate of the second compound is higher than the deuterium substitution rate of the first compound.

20. The organic light emitting device of claim 1, wherein:
the second compound has 5 or more deuterium substitutions than the first compound.
